(19) United States
(12) Patent Application Publication
(10) Pub. No.: US 2007/0158700 A1
(43) Pub. Date: Jul. 12, 2007

(54) Field effect transistor and method for producing the same

(75) Inventors: Risho Koh, Tokyo (JP); Katsuhiko Tanaka, Tokyo (JP); Kiyoshi Takeuchi, Tokyo (JP)

Correspondence Address: FOLEY AND LARDNER LLP;SUITE 500, 3000 K STREET NW, WASHINGTON, DC, 20007, US

(73) Assignee: NEC CORPORATION

(21) Appl. No.: 10/587,845

(22) PCT Filed: Jan. 28, 2005
(86) PCT No.: PCT/JP05/01207

§ 371 Date: Jul. 28, 2006

(30) Foreign Application Priority Data
Jan. 30, 2004 (JP) 2004-024722

(51) Int. Cl. H01L 29/76

(52) U.S. Cl. 257/288

(57) ABSTRACT

A field effect transistor comprising: a semiconductor layer projecting from the plane of a base; a gate electrode provided on opposite side surfaces of the semiconductor layer; a gate insulating film interposed between the gate electrode and the side surface of the semiconductor layer; and source/drain regions where a first conductivity type impurity is introduced, wherein the semiconductor layer has a channel forming region in a portion sandwiched between the source/drain regions, and has in the upper part of the semiconductor layer in the channel forming region a channel impurity concentration adjusting region of which the concentration of a second conductivity type impurity is higher than that in the lower part of the semiconductor layer, and in the channel impurity concentration adjusting region, a channel is formed in a side surface portion facing the gate insulating film of the semiconductor layer in the channel impurity concentration adjusting region in a state of operation in which a signal voltage is applied to the gate electrode.

### TECHNICAL FIELD

The present invention relates to a field effect transistor and a method for producing the same.

### BACKGROUND ART

[Structure]

First, the feature of a general FinFET will be described. A field effect transistor called a FinFET characterized in that for the purpose of improving the performance of a field effect transistor, a gate electrode is provided on opposite side surfaces of a projecting semiconductor region and channels are formed on opposite side surfaces of the semiconductor region has been proposed. A typical structure of the transistor is shown in FIG. 31 and FIGS. 32(a) and 32(b). FIG. 31 is a plan view, FIG. 32(a) is a sectional view in the section A-A′ in FIG. 31, and FIG. 32(b) is a sectional view in the section B-B′ in FIG. 31. A buried insulating film 2 is provided on a support substrate 1, and a semiconductor layer 3 is provided thereon. A gate electrode 5 is provided on the side surface of the semiconductor layer 3 via a gate insulating film 4 (FIG. 32(a)). In a portion of the semiconductor layer 3 which is not covered with a gate electrode, a high-concentration impurity of first conductivity type is introduced to form source/drain regions 6. The semiconductor layer 3 covered with the gate electrode 5 forms a channel forming region 7, and by applying an appropriate voltage to the gate electrode, a first conductivity type carrier is induced to form a channel on the surface. In the channel forming region, generally, a low-concentration second conductivity type impurity or no impurity is introduced.

In the FinFET, a structure in which a channel is also formed on the upper part of the semiconductor layer (FIGS. 32(a) and 32(b)) is called a tri gate structure. A transistor having the tri gate structure is characterized in that the thickness of the insulating film on the upper part of the semiconductor layer and the thickness of the insulating film on the semiconductor side surface are comparable. A structure in which no channel is formed on the upper part of the semiconductor layer (FIGS. 33(a) and 33(b)) is called a double gate structure. The transistor having the double gate structure is characterized in that a cap insulating film 8 consisting of an insulating film thicker than the insulating film (gate insulating film 4) on the semiconductor side surface is provided on the upper part of the semiconductor layer. Usually, the cap insulating film 8 is formed in a step different from a step of forming the gate insulating film 4. In the conventional configuration, the structure in the section B-B′ and the structure in the section C-C′ in FIG. 31 are the same in any of the tri gate structure and the double gate structure. Symbols 34 and 35 denote an upper corner portion and a lower corner portion, respectively.

The technique disclosed in Japanese Patent Laid-Open No. 6-302817 (hereinafter referred to as Patent Document 1) will now be described with reference to FIG. 37 and FIGS. 38(a) and 38(b). FIG. 37 is a perspective view described in Patent Document 1. FIG. 38(a) depicts the section structure at a position corresponding to the section A-A′ in the structure in FIG. 31 and FIG. 38(b) depicts the section structure at a position corresponding to the section B-B′ in the structure in FIG. 31, based on Patent Document 1.

In the structure in Patent Document 1, a source region 42 and a drain region 43 are formed on the semiconductor layer 3 projecting from a substrate and the channel forming region 7 is formed on a region sandwiched between the source region 42 and the drain region 43 in an n-channel FinFET formed on a p type bulk silicon substrate. A p⁺ conductive layer 20 is formed on an upper end portion of the channel forming region 7. Therefore, the upper end portion of the channel forming region 7 does not operate as a channel, and can reduce an influence of a gate voltage above the region. As a result, a parasitic transistor having a low threshold voltage is prevented from being formed on the upper end portion of the semiconductor layer. In Patent Document 1, the “upper end portion of the semiconductor layer” refers to a region extending from the upper end surface (“upper end surface” will be described as “upper end” in embodiments of the present invention below) of the semiconductor layer to a certain depth, and is used as a term indicating a portion in which the p⁺ conductive layer 20 is formed.

[Problems of Conventional Technique]

Problems in the conventional FinFET will be described taking an n-channel transistor as an example. The n-channel transistor will be described here, but in a p-channel transistor, the same holds true if the polarity is reversed (for example, an increase in electric potential in the n-channel transistor is reversely read as a decrease in electric potential in the p-channel transistor, and a decrease in threshold voltage in the n-channel transistor is reversely read as an increase in threshold voltage in the p-channel transistor).

(First Problem)

The results of simulating an electric potential distribution on the upper end portion of the semiconductor layer 3 in the section A-A′ in FIG. 31 are shown in FIGS. 34(a) and 34(b). FIG. 34(a) shows the result for the tri gate structure and corresponds to the section in FIG. 32(a), and FIG. 34(b) shows the result for the double gate structure and corresponds to the section in FIG. 33(a). Contour lines in the figures are isopotential lines on the basis of intrinsic semiconductor silicon, where electric potentials are −0.4 V, −0.2 V, 0.0 V, 0.2 V and 0.4 V as going outward from the center of the semiconductor layer. The concentration of the impurity in the channel region is 8×10¹⁸ cm⁻³, the gate voltage is zero volt, and the thickness of a gate oxide film is 2 nm. Since the electric potential is on the basis of intrinsic semiconductor silicon, the electric potential of zero-biased n⁺ type silicon is 0.56 V and the electric potential of the zero-biased gate is 0.56 V.

In any of the double gate structure and the tri gate structure, the isopotential line is curved at an upper corner portion of the semiconductor layer.

This indicates that in the upper corner portion, electric fields traveling toward impurity ions from the gate electrode are concentrated, and therefore the electric potential increases compared to other portions of the semiconductor layer. When the electric potential of the upper corner portion increases, a parasitic transistor having a low threshold voltage is formed in the upper corner portion. Formation of the parasitic transistor causes a problem of increasing a subthreshold current and increasing an off current as in FIG. 36. This problem becomes more noticeable as the concentration of the second conductivity type impurity in the channel forming region increases, and becomes serious especially when the concentration of the second conductivity type impurity is 1×10¹⁸ cm⁻³ or more.

Thus, a technique for inhibiting an increase in electric potential in the semiconductor layer upper corner portion and reducing an influence of the parasitic transistor is desired.

(Second Problem)

In the transistor having the tri gate structure, a channel is formed on each of a semiconductor layer upper surface 23, a semiconductor layer upper side surface 24 and a semiconductor layer side surface 25 (see FIG. 39 for each), thus providing a path for a drain current. However, in the technique in Patent Document 1, the p⁺ conductive layer 20 is formed on the upper end portion of the channel forming region 7 and the upper end portion of the channel forming region 7 does not operate as a channel, and therefore according to the classification of regions shown in FIG. 39, no channels are formed on the semiconductor layer upper surface 23 and the semiconductor layer upper side surface 24. Therefore, the area on which the channel is formed decreases, thus causing a problem of reducing the drain current.

In the transistor having the double gate structure, a channel is formed on each of the semiconductor layer upper side surface 24 and the semiconductor layer side surface 25 (see FIG. 40 for each), thus providing a path for a drain current. Patent Document 1 does not describe a configuration in which the p⁺ type conductive layer 20 is formed on the upper end portion of the channel forming region 7 in the transistor having the double gate structure, but if the p⁺ type conductive layer 20 is formed on the upper end portion of the channel forming region 7 in the transistor having the double gate structure, the semiconductor layer upper side surface 24 does not operate as a channel, and therefore the area on which the channel is formed decreases as in the case of the tri gate structure, thus causing a problem of reducing the drain current.

Thus, a technique for inhibiting the parasitic transistor on the upper corner portion of the semiconductor layer and inhibiting a reduction in drain current associated with the inhibition of the parasitic transistor.

### DISCLOSURE OF THE INVENTION

It is an object of the present invention to provide a FinFET in which formation of a parasitic transistor in an upper corner portion of a semiconductor layer projecting from the plane of a base of the FinFET is inhibited while sufficiently securing a drain current to improve element characteristics.

According to the present invention, field effect transistors described in the following items and methods for producing the same can be provided.
(1) A field effect transistor comprising:
   a semiconductor layer projecting upward from the plane of a base;
   a gate electrode provided on opposite side surfaces of the semiconductor layer;
   a gate insulating film interposed between the gate electrode and the side surface of said semiconductor layer; and
   source/drain regions where a first conductivity type impurity is introduced in said semiconductor layer,
   wherein said semiconductor layer has a channel forming region in a portion sandwiched between said source/drain regions, and has on the upper part of the semiconductor layer in the channel forming region a channel impurity concentration adjusting region of which the concentration of a second conductivity type impurity is higher than that of the lower part of the semiconductor layer, and
   in the channel impurity concentration adjusting region, a channel is formed on a side surface portion of the semiconductor layer in the channel impurity concentration adjusting region, which faces said gate insulating film, in a state of operation in which a signal voltage is applied to said gate electrode.
(2) A field effect transistor comprising:
   a semiconductor layer projecting upward from the plane of a base;
   a gate electrode extending from the upper part of the semiconductor layer to facing opposite side surfaces so as to straddle the semiconductor layer;
   a gate insulating film interposed between the gate electrode and said semiconductor layer; and
   source/drain regions where a first conductivity type impurity is introduced in said semiconductor layer,
   wherein said semiconductor layer has a channel forming region in a portion sandwiched between said source/drain regions, and has on the upper part of the semiconductor layer in the channel forming region a channel impurity concentration adjusting region of which the concentration of a second conductivity type impurity is higher than that of the lower part of the semiconductor layer, and
   in the channel impurity concentration adjusting region, a channel is formed on upper surface and side surface portions of the semiconductor layer in the channel impurity concentration adjusting region, which face said gate insulating film, in a state of operation in which a signal voltage is applied to said gate electrode.
(3) The field effect transistor according to item 1 or 2, wherein when having in the upper part of the semiconductor layer a concentration of the second conductivity type impurity which is same as that in the lower part of the semiconductor layer, said channel impurity concentration adjusting region has an impurity concentration with which
   an electric potential increasing in a corner portion of the upper part of the semiconductor layer can be reduced for an n-channel transistor; and
   a reduction in electric potential in the corner portion of the upper part of the semiconductor layer can be downscaled for a p-channel transistor.
(4) The field effect transistor according to item 1, 2 or 3, wherein the filed effect transistor has an impurity concentration with which
   an electric potential increasing in the corner portion of the upper part of the semiconductor layer can be reduced by 60 mV or more for the n-channel transistor; and
   a reduction in electric potential in the corner portion of the upper part of the semiconductor layer can be downscaled by 60 mV or more for the p-channel transistor.
(5) The field effect transistor according to any one of items 1 to 4, wherein the average value of the net concentration of the second conductivity type impurity in said channel impurity concentration adjusting region is in a range from 1.3 times or more to 4 times or less as large as the average value of the net concentration of the second conductivity type impurity in other regions below the channel impurity concentration adjusting region.
(6) The field effect transistor according to any one of items 1 to 4, wherein the average value of the net concentration of the second conductivity type impurity in said channel impurity concentration adjusting region is in a range from 1.5 times or more to 3 times or less as large as the average value of the net concentration of the second conductivity type impurity in other regions below the channel impurity concentration adjusting region.
(7) The field effect transistor according to any one of items 1 to 6, wherein in said channel impurity concentration adjusting region, a depth Htop extending downward from the upper end of said semiconductor layer is 0.7 times or less as large as a width Wfin of the semiconductor layer parallel to the plane of the base and vertical to the longitudinal direction of the channel.
(8) The field effect transistor according to any one of items 1 to 7, wherein in said channel impurity concentration adjusting region, a depth Htop extending downward from the upper end of said semiconductor layer is 7/40 times or more as large as a width Wfin of the semiconductor layer parallel to the plane of the base and vertical to the longitudinal direction of the channel.
(9) The field effect transistor according to any one of items 1 to 8, wherein in said channel impurity concentration adjusting region, the depth Htop extending downward from the upper end of said semiconductor layer is in a range from 5 to 24.5 nm.
(10) The field effect transistor according to any one of items 1 to 9, wherein the average value of the net concentration of the second conductivity type impurity in said channel forming region excepting said channel impurity concentration adjusting region is 1×10¹⁸ cm⁻³ or more.
(11) The field effect transistor according to any one of items 1 to 10, wherein said channel impurity concentration adjusting region is provided along an entire in-plane direction parallel to the plane of the base in the upper part of the semiconductor layer in said channel forming region.
(12) The field effect transistor according to any one of items 1 to 10, wherein the field effect transistor has as said channel impurity concentration adjusting region the channel impurity concentration adjusting region so as to include at least a part of the corner portion of the semiconductor layer, in the upper part of the semiconductor layer in said channel forming region, and further has a portion which does not have the channel impurity concentration adjusting region in a section parallel to the plane of the base, which includes the channel impurity concentration adjusting region.
(13) The field effect transistor according to item 12, wherein the field effect transistor has a first channel impurity concentration adjusting region provided seamlessly along the longitudinal direction of the channel so as to include one corner portion and establish a link between a pair of source/drain regions and a second channel impurity concentration adjusting region provided seamlessly along the longitudinal direction of the channel so as to include the other corner portion and establish a link between a pair of source/drain regions, in the upper part of the semiconductor layer in said channel forming region, and further has between the first channel impurity concentration adjusting region and the second channel impurity concentration adjusting region a portion which does not have these channel impurity concentration adjusting regions over an area between a pair of source/drain regions so that these channel impurity concentration adjusting regions are mutually separated.
(14) The field effect transistor according to item 12, wherein the field effect transistor has a first channel impurity concentration adjusting region provided seamlessly from one corner portion to the other corner portion so as to contact one source/drain region and a second channel impurity concentration adjusting region provided seamlessly from one corner to the other corner so as to contact the other source/drain region, in the upper part of the semiconductor layer in said channel forming region, and further has between the first channel impurity concentration adjusting region and the second channel impurity concentration adjusting region a portion which does not have these channel impurity concentration adjusting regions over an area between a pair of corner portions so that these channel impurity concentration adjusting regions are mutually separated.
(15) The field effect transistor according to item 12, wherein the field effect transistor has a channel impurity concentration adjusting region provided seamlessly from one corner portion to the other corner portion so as to contact one source/drain region, in the upper part of the semiconductor layer in said channel forming region, and has no channel impurity concentration adjusting region between said channel impurity concentration adjusting region and the other source/drain region.
(16) The field effect transistor according to item 12, wherein the field effect transistor has a first channel impurity concentration adjusting region contacting one source/drain region and including a part of a first corner portion, a second impurity concentration adjusting region contacting the other source/drain region and including a part of the first corner portion, a third channel impurity concentration adjusting region contacting one source/drain region and including a part of a second corner portion facing the first corner portion, and a fourth channel impurity concentration adjusting region contacting the other source/drain region and including a part of the second corner portion facing the first corner portion, in the upper part of the semiconductor layer in said channel forming region, and further has a portion which does not have these channel impurity concentration adjusting regions over an area between a pair of source/drain regions and an area between a pair of first/second corner portions so that these channel impurity concentration adjusting regions are mutually separated.
(17) The field effect transistor according to item 12, wherein the field effect transistor has a first channel impurity concentration adjusting region contacting a first source/drain region and including a part of a first corner portion and a second channel impurity concentration adjusting region contacting said first source/drain region and including a part of a second corner portion facing the first corner portion, in the upper part of the semiconductor layer in said channel forming region,
   has a portion having no channel impurity concentration adjusting region between said first channel impurity concentration adjusting region and said second channel impurity concentration adjusting region, and
   has no channel impurity concentration adjusting region in the vicinity of a second source/drain region facing the first source/drain region.
(18) A field effect transistor having an impurity concentration comprising:
   a semiconductor layer projecting upward from the plane of a base;
   a gate electrode provided on opposite side surfaces of the semiconductor layer;
   a gate insulating film interposed between the gate electrode and the side surface of said semiconductor layer; and
   source/drain regions where a first conductivity type impurity is introduced in said semiconductor layer,
   wherein said semiconductor layer has a channel forming region in a portion sandwiched between said source/drain regions, has in the upper part of the semiconductor layer in the portion sandwiched between the source/drain regions a channel impurity concentration adjusting region of which the concentration of a second conductivity type impurity is higher than that in the lower part of the semiconductor layer, so as to include at least a part of a corner portion of the semiconductor layer, and further has a portion which does not have the channel impurity concentration adjusting region in a section parallel to the plane of the base, which includes the channel impurity concentration adjusting region.
(19) A field effect transistor having an impurity concentration comprising: a semiconductor layer projecting upward from the plane of a base;
   a gate electrode extending from the upper part of the semiconductor layer to facing opposite side surfaces so as to straddle the semiconductor layer;
   a gate insulating film interposed between the gate electrode and said semiconductor layer; and
   source/drain regions where a first conductivity type impurity in said semiconductor layer,
   wherein said semiconductor layer has a channel forming region in a portion sandwiched between said source/drain regions, has in the upper part of the semiconductor layer in the portion sandwiched between the source/drain regions a channel impurity concentration adjusting region of which the concentration of a second conductivity type impurity is higher than that in the lower part of the semiconductor layer, so as to include at least a part of a corner portion of the semiconductor layer, and further has a portion which does not have the channel impurity concentration adjusting region in a section parallel to the plane of the base, which includes the channel impurity concentration adjusting region.
(20) The field effect transistor according to item 18 or 19, wherein the field effect transistor has a first channel impurity concentration adjusting region provided seamlessly along the longitudinal direction of a channel so as to include one corner portion and establish a link between a pair of source/drain regions and a second channel impurity concentration adjusting region provided seamlessly along the longitudinal direction of the channel so as to include the other corner portion and establish a link between a pair of source/drain regions, in the upper part of the semiconductor layer in the portion sandwiched between said source/drain regions, and further has between the first channel impurity concentration adjusting region and the second channel impurity concentration adjusting region a portion which does not have these channel impurity concentration adjusting regions over an area between a pair of source/drain regions so that these channel impurity concentration adjusting regions are mutually separated.
(21) The field effect transistor according to item 18 or 19, wherein the field effect transistor has a first channel impurity concentration adjusting region provided seamlessly from one corner portion to the other corner portion so as to contact one source/drain region and second channel impurity concentration adjusting region provided seamlessly from one corner portion to the other corner portion so as to contact the other source/drain region, in the upper part of the semiconductor layer in the portion sandwiched between said source/drain regions, and further has between the first channel impurity concentration adjusting region and the second channel impurity concentration adjusting region a portion which does not have these channel impurity concentration adjusting regions over an area between a pair of corner portions so that these channel impurity concentration adjusting regions are mutually separated.
(22) The field effect transistor according to item 18 or 19, wherein the field effect transistor has a channel impurity concentration adjusting region provided seamlessly from one corner portion to the other corner portion so as to contact one source/drain region in the upper part of the semiconductor layer in the portion sandwiched between said source/drain regions, and
   has no channel impurity concentration adjusting region between said channel impurity concentration adjusting region and the other source/drain region.
(23) The field effect transistor according to item 18 or 19, wherein the field effect transistor has a first channel impurity concentration adjusting region contacting one source/drain region and including a part of a first corner portion, a second impurity concentration adjusting region contacting the other source/drain region and including a part of the first corner portion, a third channel impurity concentration adjusting region contacting one source/drain region and including a part of a second corner portion facing the first corner portion, and a fourth channel impurity concentration adjusting region contacting the other source/drain region and including a part of the second corner portion facing the first corner portion, in the upper part of the semiconductor layer in the portion sandwiched between said source/drain regions, and further has a portion which does not have these channel impurity concentration adjusting regions over an area between a pair of source/drain regions and an area between a pair of first/second corner portions so that these channel impurity concentration adjusting regions are mutually separated.
(24) The field effect transistor according to item 18 or 19, wherein the field effect transistor has a first channel impurity concentration adjusting region contacting a first source/drain region and including a part of a first corner portion and a second channel impurity concentration adjusting region contacting said first source/drain region and including a part of a second corner portion facing the first corner portion, in the upper part of the semiconductor layer in the portion sandwiched between said source/drain regions,
   has a portion having no channel impurity concentration adjusting region between said first channel impurity concentration adjusting region and said second channel impurity concentration adjusting region, and
   has no channel impurity concentration adjusting region in the vicinity of a second source/drain region facing the first source/drain region.
(25) The field effect transistor according to item 18 or 19, wherein in said channel impurity concentration adjusting region, the average value of the net concentration of the second conductivity type impurity in the channel impurity concentration adjusting region is in a range from 1.3 times or more to 4 times or less as large as the average value of the net concentration of the second conductivity type impurity in other regions below the channel impurity concentration adjusting region, in a section vertical to the plane of the base, which includes the channel impurity concentration adjusting region.
(26) The field effect transistor according to item 18 or 19, wherein in said channel impurity concentration adjusting region, the average value of the net concentration of the second conductivity type impurity in the channel impurity concentration adjusting region is in a range from 1.5 times or more to 3 times or less as large as the average value of the net concentration of the second conductivity type impurity in other regions below the channel impurity concentration adjusting region, in a section vertical to the plane of the base, which includes the channel impurity concentration adjusting region.
(27) The field effect transistor according to item 18 or 19, wherein said channel impurity concentration adjusting region has a concentration distribution in which the average value of the net concentration of the second conductivity type impurity in the channel impurity concentration adjusting region is in a range from 1.3 times or more to 4 times or less as large as the average value of the net concentration of the second conductivity type impurity in other regions below the channel impurity concentration adjusting region, on a line vertical to the plane of the base in the semiconductor layer in the portion sandwiched between said source/drain regions.
(28) The field effect transistor according to item 18 or 19, wherein said channel impurity concentration adjusting region has a concentration distribution in which the average value of the net concentration of the second conductivity type impurity in the channel impurity concentration adjusting region is in a range from 1.5 times or more to 3 times or less as large as the average value of the net concentration of the second conductivity type impurity in other regions below the channel impurity concentration adjusting region, on a line vertical to the plane of the base in the semiconductor layer in the portion sandwiched between said source/drain regions.
(29) The field effect transistor according to any one of items 18 to 28, wherein in said channel impurity concentration adjusting region, a depth Htop extending downward from the upper end of said semiconductor layer is 0.7 times or less as large as a width Wfin of the semiconductor layer parallel to the plane of the base and vertical to the longitudinal direction of the channel.
(30) The field effect transistor according to any one of items 18 to 28, wherein in said channel impurity concentration adjusting region, a depth Htop extending downward from the upper end of said semiconductor layer is 7/40 times or more as large as a width Wfin of the semiconductor layer parallel to the plane of the base and vertical to the longitudinal direction of the channel.
(31) The field effect transistor according to any one of items 18 to 28, wherein in said channel impurity concentration adjusting region, the depth Htop extending downward from the upper end of said semiconductor layer is in a range from 5 to 24.5 nm.
(32) The field effect transistor according to any one of items 18 to 31, wherein the average value of the net concentration of the second conductivity type impurity in said channel forming region excepting said channel impurity concentration adjusting region is 1×10¹⁸ cm⁻³ or more.
(33) The field effect transistor according to item 1, 2, 18 or 19, wherein said semiconductor layer has an upper channel impurity concentration adjusting region which is said channel impurity concentration adjusting region provided in the upper part of the semiconductor layer, a middle channel forming region which is provided below the upper channel impurity concentration adjusting region and of which the concentration of the second conductivity type impurity is lower than that in the upper channel impurity concentration adjusting region, and a lower channel impurity concentration adjusting region which is provided in the lower part of the semiconductor layer below the middle channel forming region and of which the concentration of the second conductivity type impurity is higher than that in the middle channel forming region.
(34). The field effect transistor according to item 33, wherein said lower channel impurity concentration adjusting region has a channel formed in a side surface portion of the semiconductor layer in the lower channel impurity concentration adjusting region, which faces said gate insulating film, in a state of operation in which a signal voltage is applied to said gate electrode.
(35) The field effect transistor according to item 33 or 34, wherein said lower channel impurity concentration adjusting region has an impurity concentration with which an electric potential increasing in the corner portion of the lower part of the semiconductor layer can be reduced when said lower channel impurity concentration adjusting region has a concentration of the second conductivity type impurity which is same as that in said middle channel forming region.
(36) The field effect transistor according to item 33, 34 or 35, wherein the average value of the net concentration of the second conductivity type impurity in said lower channel impurity concentration adjusting region is 1.3 times or more and 4 times or less as large as the average value of the net concentration of the second conductivity type impurity in said middle channel forming region.
(37) The field effect transistor according to item 36, wherein the average value of the net concentration of the second conductivity type impurity in said upper channel impurity concentration adjusting region is 1.3 times or more and 4 times or less as large as the average value of the net concentration of the second conductivity type impurity in said middle channel forming region.
(38) The field effect transistor according to item 33, 34 or 35, wherein the average value of the net concentration of the second conductivity type impurity in said lower channel impurity concentration adjusting region is 1.5 times or more and 3 times or less as large as the average value of the net concentration of the second conductivity type impurity in said middle channel region.
(39) The field effect transistor according to item 38, wherein the average value of the net concentration of the second conductivity type impurity in said upper channel impurity concentration adjusting region is 1.5 times or more and 3 times or less as large as the average value of the net concentration of the second conductivity type impurity in said middle channel forming region.
(40) The field effect transistor according to any one of items 33 to 39, wherein in said lower channel impurity concentration adjusting region, a height Htop2 extending upward from the lower end of said semiconductor layer is 0.7 times or less as large as a width Wfin of said semiconductor layer parallel to the plane of the base and vertical to the longitudinal direction of the channel.
(41) The field effect transistor according to item 40, wherein in said upper channel impurity concentration adjusting region, the height Htop2 extending upward from the lower end of said semiconductor layer is 0.7 times or less as large as the width Wfin of said semiconductor layer parallel to the plane of the base and vertical to the longitudinal direction of the channel.
(42) The field effect transistor according to any one of items 33 to 40, wherein in said lower channel impurity concentration adjusting region, the height Htop2 extending upward from the lower end of said semiconductor layer is 7/40 times or more as large as the width Wfin of the semiconductor layer parallel to the plane of the base and vertical to the longitudinal direction of the channel.
(43) The field effect transistor according to item 42, wherein in said upper channel impurity concentration adjusting region, the height Htop2 extending upward from the lower end of said semiconductor layer is 7/40 times or more as large as a width Wfin of the semiconductor layer parallel to the plane of the base and vertical to the longitudinal direction of the channel.
(44) The field effect transistor according to any of items 33 to 43, wherein in said lower channel impurity concentration adjusting region, the height Htop2 extending upward from the lower end of said semiconductor layer is in a range from 5 to 24.5 nm.
(45) The field effect transistor according to item 44, wherein in said upper channel impurity concentration adjusting region, the height Htop2 extending upward from the lower end of said semiconductor layer is in a range from 5 to 24.5 nm.
(46) The field effect transistor according to any one of items 33 to 45, wherein said lower channel impurity concentration adjusting region is provided along an entire in-plane direction parallel to the plane of the base in the lower part of the semiconductor layer in the portion sandwiched between source/drain regions.
(47) The field effect transistor according to any one of items 33 to 45, wherein the field effect transistor has as said lower channel impurity concentration adjusting region the channel impurity concentration adjusting region so as to include at least a part of the corner portion of the semiconductor layer in the lower part of the semiconductor layer in the portion sandwiched between said source/drain regions, and further has a portion which does not have the lower channel impurity concentration adjusting region in a section parallel to the plane of the base, which includes the lower channel impurity concentration adjusting region.
(48) The field effect transistor according to any one of items 33 to 47, wherein the average value of the net concentration of the second conductivity type impurity in said channel forming region excepting said upper channel impurity concentration adjusting region and said lower channel impurity concentration adjusting region is 1×10¹⁸ cm⁻³ or more.
(49) The field effect transistor according to item 1 or 18, wherein a cap insulating film thicker than said gate insulating film is provided between the upper part of said semiconductor layer and said gate electrode so that no channel is formed on the upper surface of the semiconductor layer.
(50) The field effect transistor according to any one of items 1 to 49, wherein the field effect transistor has a support substrate under said projecting semiconductor layer, and the semiconductor layer is connected integrally to the support substrate.
(51) The field effect transistor according to any one of items 1 to 49, wherein the field effect transistor has a support substrate under said projecting semiconductor layer, and the semiconductor layer is provided on the support substrate via a buried insulating film.
(52) The field effect transistor according to any one of items 1 to 51, wherein in said channel forming region excepting said channel impurity concentration adjusting region, an electric potential on the side surface of the semiconductor layer increases by 120 mV or more for the n-channel transistor and decreases by 120 mV or more for the p-channel transistor with respect to an electric potential at the central portion of the semiconductor layer.
(53) A method for producing the field effect transistor of item 1 or 2, comprising the steps of:
   patterning a semiconductor layer to form a semiconductor layer projecting from the plane of a base;

forming a gate electrode via an insulating film so as to straddle the projecting semiconductor layer; and
ion-implanting a second conductivity type impurity slantingly to the plane of the base from opposite sides of the gate electrode using the gate electrode as a mask to form a channel impurity concentration adjusting region on the upper part of the semiconductor layer under the gate electrode.
(54) The method for producing the field effect transistor according to item 53, wherein in the step of ion-implanting a second conductivity type impurity slantingly to the plane of the base from opposite sides of the gate electrode using the gate electrode as a mask, said ion implantation is carried out at an angle of 10 degrees or less to a plane vertical to the plane of the base and parallel to the longitudinal direction of a channel.
(55) The method for producing the field effect transistor according to item 53, wherein in the step of ion-implanting a second conductivity type impurity slantingly to the plane of the base from opposite sides of the gate electrode using the gate electrode as a mask, said ion implantation is carried out parallel to a plane vertical to the plane of the base and parallel to the longitudinal direction of a channel.
(56) A method for producing the field effect transistor of item 1 or 2, comprising:
   a step of patterning a semiconductor layer to form a semiconductor layer projecting from the surface of a base;
   a step of forming a gate electrode via an insulating film so as to straddle the projecting semiconductor layer;
   a first slanting ion implantation step of ion-implanting a second conductivity type impurity slantingly to the plane of the base from opposite sides of the gate electrode using said gate electrode as a mask; and
   a second slanting ion implantation step of ion-implanting the second conductivity type impurity slantingly to the plane of the base from opposite sides of the gate electrode, and at an angle greater than that in said first slanting ion implantation step to a plane vertical to the plane of the base and parallel to the longitudinal direction of a channel, for each of opposite side surfaces of the semiconductor layer, using said gate electrode as a mask.
(57) The method for producing the field effect transistor according to item 56, wherein said first slanting ion implantation step is carried out at an angle of 10 degrees or less to a plane vertical to the plane of the base and parallel to the longitudinal direction of the channel.
(58) The method for producing the field effect transistor according to item 56, wherein said first slanting ion implantation step is carried out parallel to a plane vertical to the plane of the base and parallel to the longitudinal direction of the channel.
(59) A method for producing the field effect transistor of item 1 or 2, comprising the steps of:
   patterning a semiconductor layer to form a semiconductor layer projecting from the plane of a base;
   forming a dummy gate electrode so as to straddle the semiconductor layer;
   ion-implanting a second conductivity type impurity slantingly to the plane of the base from opposite sides of the dummy gate electrode using said dummy gate electrode as a mask to form a channel impurity concentration adjusting region on the upper part of the semiconductor layer under the dummy gate electrode;
   introducing a first conductivity type impurity into the semiconductor layer using said dummy gate electrode as a mask to form source/drain regions;
   forming a thick insulating film so as to bury said dummy electrode; and
   removing said dummy gate electrode and burying a conductive material in a formed air gap via a gate insulating film to form a gate electrode.
(60) A method for producing the field effect transistor of item 1 or 2, comprising the steps of:
   patterning a semiconductor layer to form a semiconductor layer projecting from the plane of a base;
   introducing a second conductivity type impurity into the upper part of the projecting semiconductor layer to form said channel impurity concentration adjusting region; and
   forming a gate electrode on the side surface of the projecting semiconductor layer via a gate insulating film.
(61) A method for producing the field effect transistor of item 1 or 2, comprising the steps of:
   introducing a second conductivity type impurity into a semiconductor layer to form on the upper part of the semiconductor layer a channel impurity concentration adjusting region of which the concentration of the second conductivity type impurity is higher than that in the lower part of the semiconductor layer;
   patterning said semiconductor layer to form a semiconductor layer projecting from the plane of a base and having said channel impurity concentration adjusting region for the second conductivity type impurity in the upper part; and
   forming a gate electrode on the side surface of the projecting semiconductor layer via a gate insulating film.
(62) A method for producing the field effect transistor of item 20, comprising the steps of:
   forming a mask pattern on a semiconductor layer;
   ion-implanting a second conductivity type impurity slantingly to the plane of a base from opposite sides of the mask pattern using said mask pattern as a mask to introduce the second conductivity type impurity into the part of the semiconductor layer under the mask pattern in the vicinity of peripheral edge of the mask pattern;
   patterning the semiconductor layer using said mask pattern as a mask to form a semiconductor layer projecting from the plane of a base, and having in the upper part first and second channel impurity concentration adjusting regions which are respectively composed of a region of said second conductivity type impurity; and
   forming a gate electrode on the side surface of the projecting semiconductor layer via a gate insulating film.
(63) A method for producing the field effect transistor of item 21, comprising the steps of:
   patterning a semiconductor layer to form a semiconductor layer projecting from the plane of a base;
   forming a gate electrode via an insulating film so as to straddle the projecting semiconductor layer; and
   ion-implanting a second conductivity type impurity slantingly to the plane of the base from opposite sides of the gate electrode using said gate electrode as a mask to form first and second channel impurity concentration adjusting regions mutually separated along a pair of sides of the gate electrode on the upper part of the semiconductor layer under the gate electrode.
(64) The method for producing the field effect transistor according to item 63, wherein in the step of ion-implanting a second conductivity type impurity slantingly to the plane of the base from opposite sides of the gate electrode using the gate electrode as a mask, said ion implantation is carried out at an angle of 10 degrees or less to a plane vertical to the plane of the base and parallel to the longitudinal direction of a channel.
(65) The method for producing the field effect transistor according to item 63, wherein in the step of ion-implanting a second conductivity type impurity slantingly to the plane of the base from opposite sides of the gate electrode using the gate electrode as a mask, said ion implantation is carried out parallel to a plane vertical to the plane of the base and parallel to the longitudinal direction of a channel.
(66) A method for producing the field effect transistor of item 23, comprising:
   a step of patterning a semiconductor layer to form a semiconductor layer projecting from the plane of a base;
   a step of forming a gate electrode via an insulating film so as to straddle the projecting semiconductor layer;
   a first slanting ion implantation step of ion-implanting a second conductivity type impurity slantingly to the plane of the base from opposite sides of the gate electrode using said gate electrode as a mask; and
   a second slanting ion implantation step of ion-implanting the second conductivity type impurity slantingly to the plane of the base from opposite sides of the gate electrode, and at an angle greater than that in said first slanting ion implantation step to a plane vertical to the plane of the base and parallel to the longitudinal direction of a channel, for each of opposite side surfaces of the semiconductor layer, using said gate electrode as a mask.
(67) The method for producing the field effect transistor according to item 66, wherein said first slanting ion implantation step is carried out at an angle of 10 degrees or less to a plane vertical to the plane of the base and parallel to the longitudinal direction of the channel.
(68) The method for producing the field effect transistor according to item 66, wherein said first slanting ion implantation step is carried out parallel to a plane vertical to the plane of the base and parallel to the longitudinal direction of the channel.
(69) A method for producing the field effect transistor of item 33, comprising the steps of:
   introducing a second conductivity type impurity into a semiconductor layer to form a second conductivity type impurity layer;
   epitaxially growing a semiconductor layer having a second conductivity type impurity concentration lower than that of said second conductivity type impurity layer on said semiconductor layer; and
   patterning the epitaxially grown semiconductor layer and said second conductivity type impurity layer to form a semiconductor layer projecting from the plane of a base, and having a lower channel impurity concentration adjusting region composed of the second conductivity type impurity layer.

In the present invention, the “plane of a base” or “plane of a substrate” means any plane parallel to a substrate (horizontal).

The substrate refers to a structure supporting a projecting semiconductor layer, and is normally a semiconductor substrate such as an SOI substrate or a bulk semiconductor substrate. In the SOI substrate after the entire semiconductor layer is processed into a projective form, a structure consisting of a buried insulating film and a support substrate forms the substrate.

The direction parallel to the substrate refers to a direction parallel to a direction along which the substrate extends. In embodiments described in the specification, the direction is consistent with a direction parallel to the surface of a semiconductor layer before the step of forming a projecting semiconductor layer, or a direction parallel to the surface of a bulk semiconductor substrate before the step of forming a projecting semiconductor layer. The direction is normally a direction parallel to a wafer surface, since a FinFET is normally formed on a semiconductor wafer such as an SOI substrate or a bulk semiconductor substrate.

The longitudinal direction of channel is a direction in which two source/drain regions are linked.

According to the present invention, in a field effect transistor in which a channel is formed on the side surface of a semiconductor layer projecting on a substrate, a parasitic transistor formed at the upper corner of the semiconductor layer can be inhibited.

According to the present invention, the parasitic transistor formed at the upper corner of the semiconductor layer can be inhibited, and at the same time, by forming a channel on the side surface of the upper part of the semiconductor layer, and further on the upper surface of the semiconductor layer for the tri gate structure, the upper part of the semiconductor layer can be used as a channel, the area of region on which the channel is formed increases, the amount of current passing into a drain increases, and therefore the amount of on-current increases.

According to the present invention, the parasitic transistor formed at the upper corner of the semiconductor layer can be inhibited, and at the same time, the semiconductor layer can be fully depleted.

According to the present invention, the impurity concentration is increased only in a part of the upper corner required for inhibition of the parasitic transistor, at the upper end of the semiconductor layer, whereby formation of a channel on the upper end portion of the semiconductor layer excepting a region having a high impurity concentration is facilitated, and the channel resistance is reduced, so that the amount of current passing into a drain increases, and therefore the amount of on-current increases.

According to the present invention, regions having an appropriately high impurity concentration are provided at both of the upper and the lower end of the semiconductor layer, and therefore both of the parasitic transistor formed at the upper corner of the semiconductor layer and the parasitic transistor formed at the lower corner of the semiconductor layer can be inhibited.

According to the present invention, a method for producing a field effect transistor having the effects described above can be provided.

### BRIEF DESCRIPTION OF THE DRAWINGS

FIG. 1 is a sectional view for explaining the first embodiment;

FIGS. 2(a), 2(b) and 2(c) are sectional and plan views for explaining the first embodiment;

FIGS. 3(a), 3(b) and 3(c) are sectional and plan views for explaining the first embodiment;

FIGS. 4(a) and 4(b) are sectional views for explaining the first embodiment;

FIG. 5 is a plan view for explaining the first embodiment;

FIGS. 6(a), 6(b) and 6(c) are sectional and plan views for explaining the first embodiment;

FIGS. 7(a), 7(b) and 7(c) are sectional and plan views for explaining the first embodiment;

FIGS. 8(a), 8(b) and 8(c) are sectional and plan views for explaining the first embodiment;

FIG. 9 is a view for explaining the effect of the invention;

FIG. 10 is a view for explaining the effect of the invention;

FIG. 11 is a plan view for explaining the second embodiment;

FIGS. 12(a) and 12(b) are plan views for explaining the second embodiment;

FIG. 13 is a plan view for explaining the second embodiment;

FIGS. 14(a), 14(b) and 14(c) are sectional and plan views for explaining the second embodiment;

FIGS. 15(a), 15(b) and 15(c) are sectional and plan views for explaining the second embodiment;

FIGS. 16(a), 16(b) and 16(c) are sectional and plan views for explaining the second embodiment;

FIGS. 17(a) and 17(b) are sectional views for explaining the second embodiment;

FIGS. 18(a), 18(b) and 18(c) are sectional and plan views for explaining the second embodiment;

FIGS. 19(a) and 19(b) are sectional views for explaining the second embodiment;

FIGS. 20(a), 20(b) and 20(c) are sectional and plan views for explaining the second embodiment;

FIGS. 21(a) and 21(b) are sectional views for explaining the second embodiment;

FIGS. 22(a), 22(b) and 22(c) are sectional views for explaining the third embodiment;

FIG. 23 is a sectional view for explaining the third embodiment;

FIGS. 24(a), 24(b) and 24(c) are sectional and plan views for explaining the third embodiment;

FIGS. 25(a), 25(b) and 25(c) are sectional and plan views for explaining the third embodiment;

FIGS. 26(a) and 26(b) are sectional views for explaining the third embodiment;

FIG. 27 is a plan view for explaining the third embodiment;

FIGS. 28(a) and 28(b) are plan views for explaining the third embodiment;

FIGS. 29(a) and 29(b) are plan views for explaining the third embodiment;

FIGS. 30(a) and 30(b) are plan views for explaining the third embodiment;

FIG. 31 is a plan view for explaining a conventional technique;

FIGS. 32(a) and 32(b) are sectional views for explaining the conventional technique;

FIGS. 33(a) and 33(b) are sectional views for explaining the conventional technique;

FIGS. 34(a) and 34(b) are views for explaining a problem in the conventional technique;

FIG. 35 is a sectional view for explaining the conventional technique;

FIG. 36 is a view for explaining a problem in the conventional technique;

FIG. 37 is a perspective view for explaining the conventional technique;

FIGS. 38(a) and 38(b) are sectional views for explaining the conventional technique;

FIG. 39 is a sectional view for explaining a problem in the conventional technique;

FIG. 40 is a sectional view for explaining a problem in the conventional technique;

FIGS. 41(a), 41(b) and 41(c) are sectional views for explaining the fourth embodiment;

FIGS. 42(a), 42(b) and 42(c) are sectional and plan views for explaining the fourth embodiment;

FIGS. 43(a), 43(b) and 43(c) are sectional and plan views for explaining the fourth embodiment;

FIGS. 44(a) and 44(b) are sectional views for explaining the fourth embodiment;

FIGS. 45(a), 45(b) and 45(c) are sectional and plan views for explaining the fourth embodiment;

FIGS. 46(a), 46(b) and 46(c) are sectional and plan views for explaining the fourth embodiment;

FIGS. 47(a), 47(b) and 47(c) are sectional and plan views for explaining the fourth embodiment;

FIGS. 48(a), 48(b) and 48(c) are sectional and plan views for explaining the fourth embodiment;

FIGS. 49(a), 49(b) and 49(c) are sectional and plan views for explaining the fourth embodiment;

FIGS. 50(a), 50(b) and 50(c) are sectional and plan views for explaining the fourth embodiment;

FIGS. 51(a) and 51(b) are sectional views for explaining the fourth embodiment;

FIGS. 52(a), 52(b) and 52(c) are sectional and plan views for explaining the fourth embodiment;

FIGS. 53(a) and 53(b) are sectional views for explaining the fourth embodiment;

FIGS. 54(a), 54(b) and 54(c) are sectional and plan views for explaining the fourth embodiment;

FIGS. 55(a) and 55(b) are sectional views for explaining the fourth embodiment;

FIGS. 56(a) and 56(b) are sectional views for explaining the fourth embodiment;

FIGS. 57(a), 57(b) and 57(c) are sectional and plan views for explaining the fourth embodiment;

FIGS. 58(a), 58(b) and 58(c) are sectional and plan views for explaining the fourth embodiment;

FIGS. 59(a) and 59(b) are sectional views for explaining the fourth embodiment;

FIG. 60 is a view showing a relationship between a width Wfin of a projecting semiconductor layer and a depth Hcorner of the semiconductor layer where electric field concentration occurs;

FIG. 61 is a view for explaining the definition of a depth Htop of a channel impurity concentration adjusting region in the projecting semiconductor layer;

FIG. 62 is a view for explaining the definition of the depth Htop of the channel impurity concentration adjusting region in the projecting semiconductor layer;

FIG. 63 is a view for explaining the definition of the depth Htop of the channel impurity concentration adjusting region in the projecting semiconductor layer;

FIG. 64 is a view for explaining the definition of the depth Htop of the channel impurity concentration adjusting region in the projecting semiconductor layer;

FIG. 65 is a view for explaining the definition of the depth Htop of the channel impurity concentration adjusting region in the projecting semiconductor layer;

FIG. 66 is a view for explaining the definition of the depth Htop of the channel impurity concentration adjusting region in the projecting semiconductor layer;

FIG. 67 is a view for explaining the definition of the depth Htop of the channel impurity concentration adjusting region in the projecting semiconductor layer;

FIG. 68 is a view for explaining the definition of the depth Htop of the channel impurity concentration adjusting region in the projecting semiconductor layer;

FIG. 69 is a view for explaining a preferred embodiment of the present invention;

FIG. 70 is a view for explaining a preferred embodiment of the present invention;

FIG. 71 is a view for explaining the effect of the second embodiment;

FIG. 72 is a view for explaining the effect of the second embodiment;

FIGS. 73(a) and 73(b) are plan views for explaining an embodiment of the present invention.

FIGS. 74(a) and 74(b) are sectional views for explaining the fifth embodiment.

FIGS. 75(a) and 75(b) are sectional views for explaining the fifth embodiment.

FIGS. 76(a) and 76(b) are sectional views for explaining the fifth embodiment.

FIGS. 77(a) and 77(b) are sectional views for explaining the fifth embodiment.

FIGS. 78(a), 78(b) and 78(c) are sectional and plan views for explaining the first embodiment;

FIGS. 79(a) and 79(b) are sectional views for explaining an embodiment of the present invention;

FIG. 80 is a sectional view for explaining the fifth embodiment;

FIGS. 81(a) and 81(b) are plan views for explaining the second embodiment;

FIGS. 82(a) and 82(b) are plan views for explaining the second embodiment; and

FIGS. 83(a) and 83(b) are views for explaining the effect of the invention.

### BEST MODE FOR CARRYING OUT THE INVENTION

### First Embodiment

[Structure]

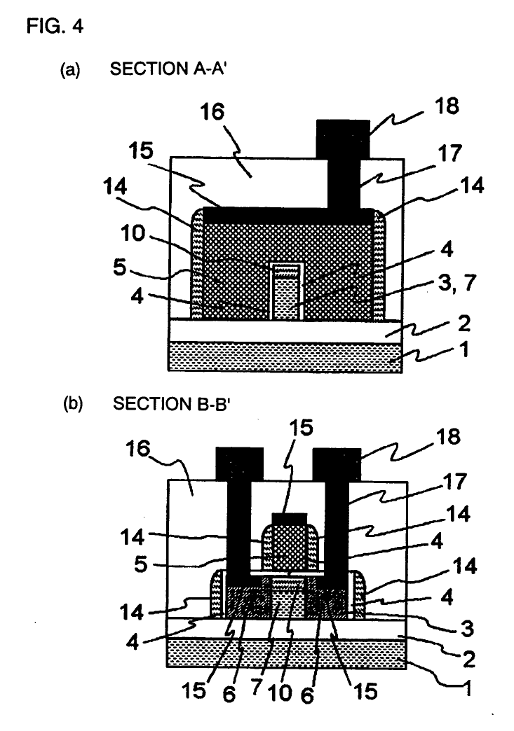

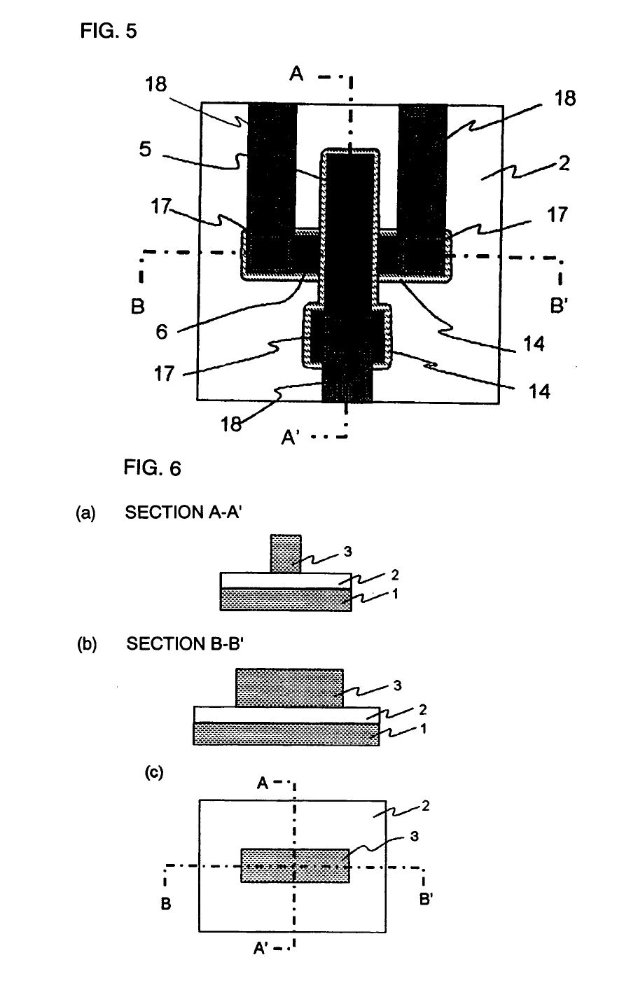

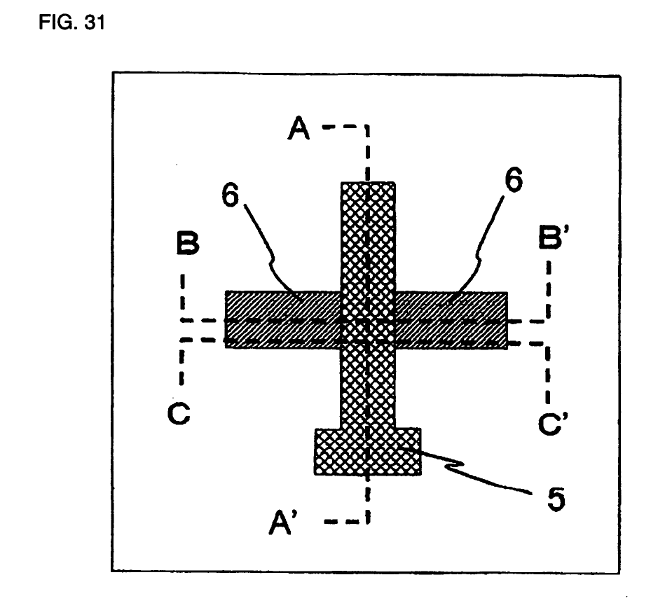

The first embodiment will be described with reference to FIGS. 4(a) and 4(b) and FIG. 5. FIG. 4(a) is a sectional view in the section A-A′ in FIG. 5, and is a sectional view in a position corresponding to the section A-A′ in FIG. 31 showing an example of a conventional technique. FIG. 4(b) is a sectional view in the section B-B′ in FIG. 5, and is a sectional view in a position corresponding to the section B-B′ in FIG. 31 showing the example of the conventional technique.

In this embodiment, a semiconductor layer 3 projecting upward from a substrate is provided, and a gate electrode 5 is provided on the side surface of the semiconductor layer via a gate insulating film 4. The gate electrode 5 is patterned in an appropriate size, and source/drain regions 6 where a first conductivity type impurity is introduced in a high concentration are formed on the semiconductor layer 3 at a position where the semiconductor layer 3 is not covered with the gate electrode 5. A low-concentration second conductivity type impurity is introduced into a channel forming region 7 corresponding to the semiconductor layer covered with the gate electrode 5, and an appropriate voltage is applied to the gate electrode 5, whereby a channel consisting of a first conductivity type carrier is formed. An interconnect 18 is connected to the gate electrode 5 or the source/drain region 6 via a contact 17.

A second conductivity type impurity of which the concentration is higher than the concentration in the semiconductor layer 3 excepting a channel impurity concentration adjusting region 10 is introduced into the channel impurity concentration adjusting region 10 provided over a certain area from the upper end of the semiconductor layer 3 forming the channel forming region 7. However, the concentration of the impurity introduced into this channel impurity concentration adjusting region 10 is lower than the concentration of an impurity introduced into high-concentration regions such as source/drain regions. The impurity concentration in the channel impurity concentration adjusting region is adjusted to be a level of concentration with which an increase in electric potential in an upper corner portion of the semiconductor layer is inhibited and channels are formed on the upper surface and the side surface of the channel impurity concentration adjusting region with application of a gate voltage.

The average value Ntop of the net concentration of the second conductivity type impurity in an area extending from the upper end of the semiconductor layer 3 to the depth Htop in the channel forming region of a second conductivity type is typically in a range from 1.3 times to 4 times as large as the average value N of the net concentration of the second conductivity type impurity in the semiconductor layer excepting the area extending from the upper end of the semiconductor layer 3 to the depth Htop. More typically, the average value Ntop is in a range from 1.5 times to 3 times as large as the average value N of the net concentration of the second conductivity type impurity in the semiconductor layer excepting the area extending from the upper end of the semiconductor layer 3 to the depth Htop.

Alternatively, the average value of the net concentration of the second conductivity type impurity in the area extending from the upper end of the semiconductor layer 3 to the depth Htop, which is determined excepting an area of 1 nm from the boundary of the upper part and the side face of the semiconductor layer is in a range of 1.5 times to 3 times as large as the average the average value of the net concentration of the second conductivity type impurity in the semiconductor layer excepting the area extending from the upper end of the semiconductor layer 3 to the depth Htop, which is determined in the same way excepting the area of 1 nm from the boundary of the upper part and the side surface of the semiconductor layer. The reason for excepting the area of 1 nm from the boundary of the upper part and the side surface of the semiconductor layer is that the area of 1 nm representing a typical width of a region where the impurity concentration is extremely steeply changed is excluded in consideration of the fact that the impurity concentration is extremely steeply changed around the boundary of the upper part and the side surface of the semiconductor layer, and a region where the concentration is thus steeply changed is so narrow that its influence on an electric characteristic is insignificant.

The impurity concentration in the channel impurity concentration adjusting region is set to satisfy a relationship between Ntop and N in which an increase in electric potential in the corner portion of the upper part of the semiconductor layer can be reduced as compared to a case where no channel impurity concentration adjusting region is provided (i.e. as compared to a case where the impurity concentration in the channel impurity concentration adjusting region is replaced by the N described above). At this time, the amount of reduction of an increase in electric potential in the corner portion of the upper part of the semiconductor layer is preferably 60 mV or more (reduction of 60 mV corresponds to a condition in which a leak current by a parasitic transistor decreases by an order of magnitude) in at least a part of the upper part of the semiconductor layer.

The present invention typically reduces an increase in electric potential due to electric field concentration by 60 mV or more in at least a part of the upper corner portion of the semiconductor layer, and therefore the present invention is typically applied for improving a characteristic of a transistor in which the electric potential increases by 60 mV or more in at least a part of the upper corner of the semiconductor layer when no channel impurity concentration adjusting region is provided.

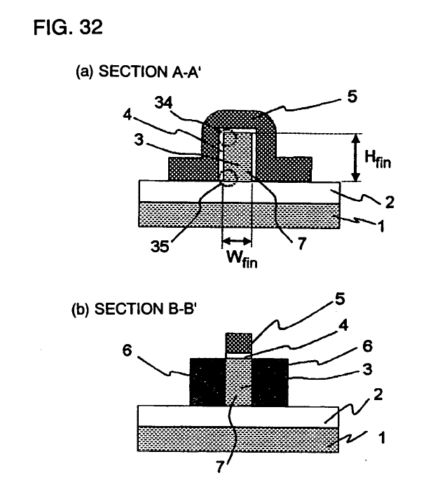

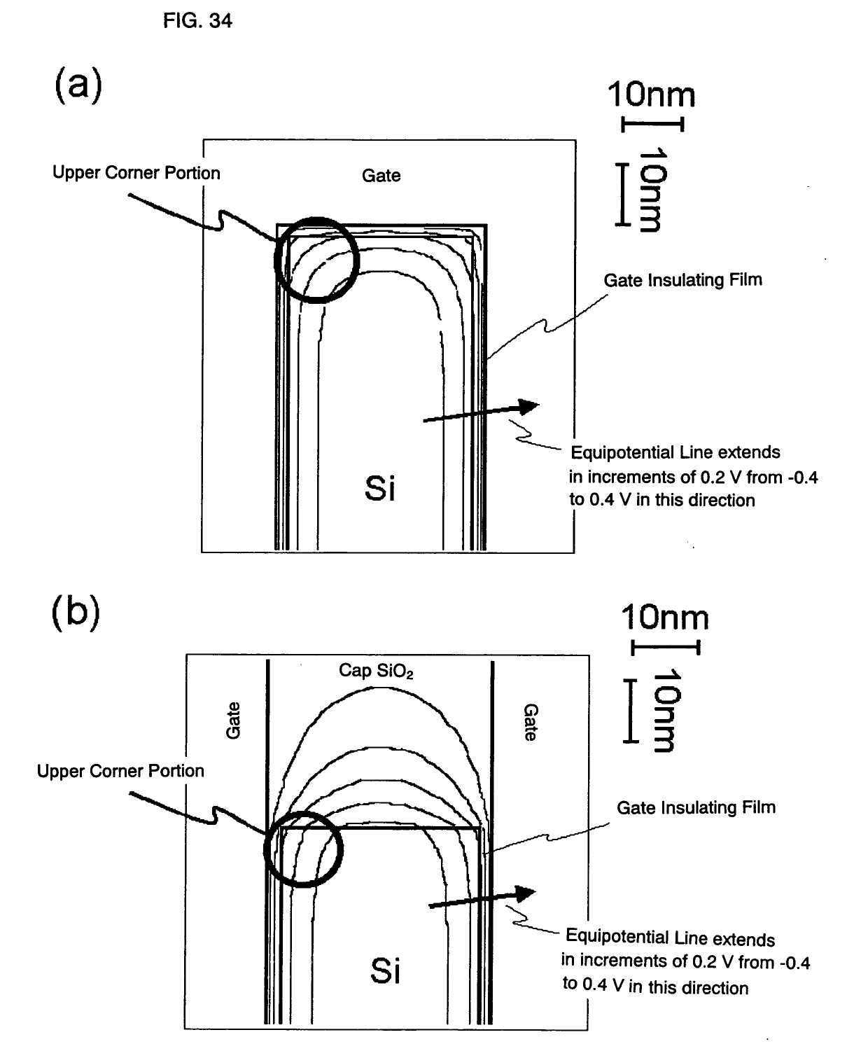

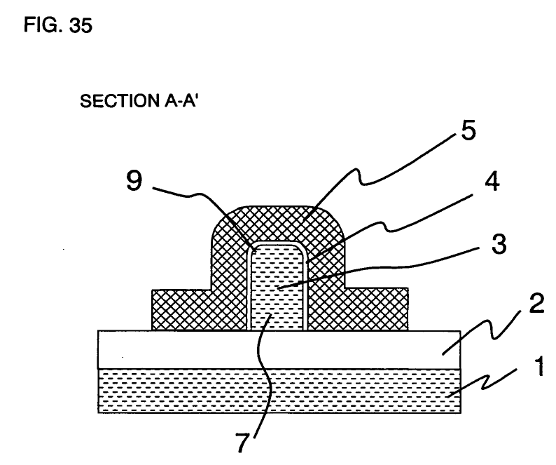

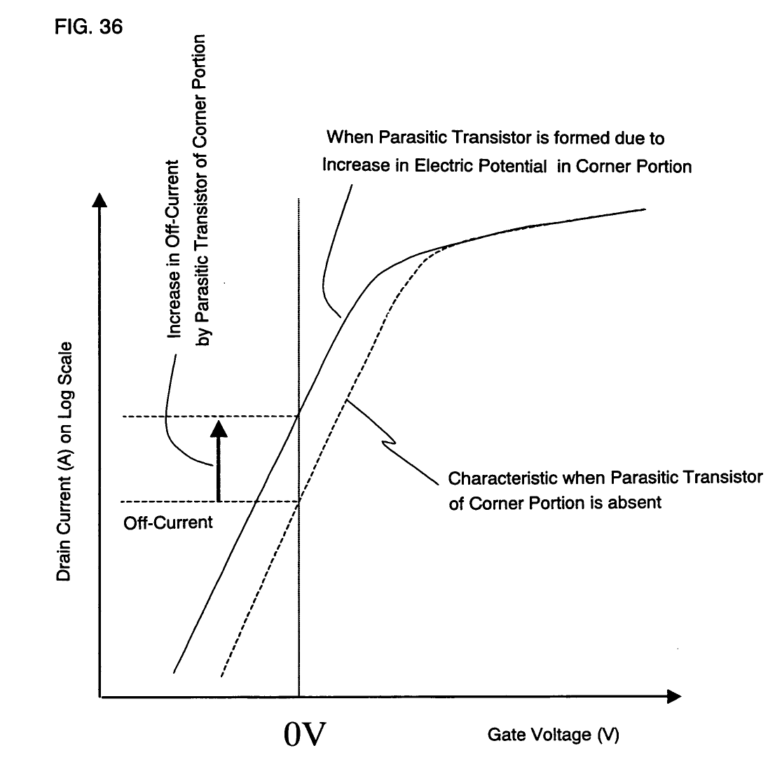

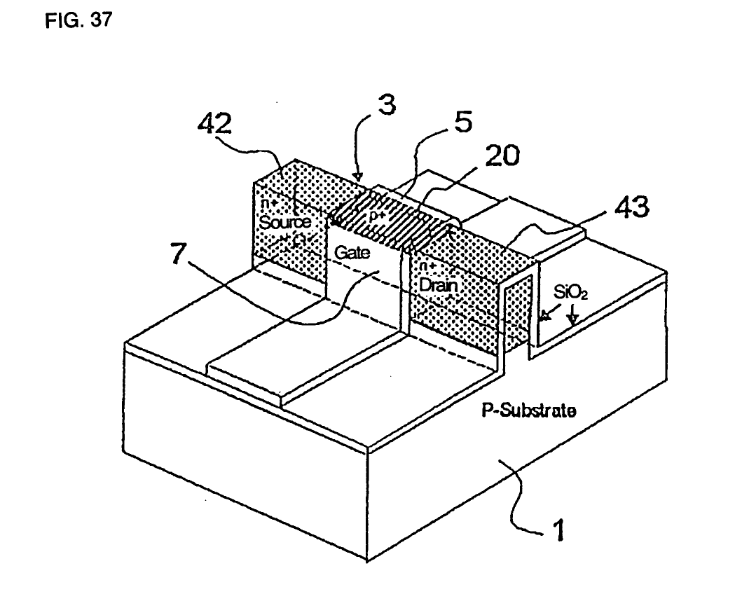

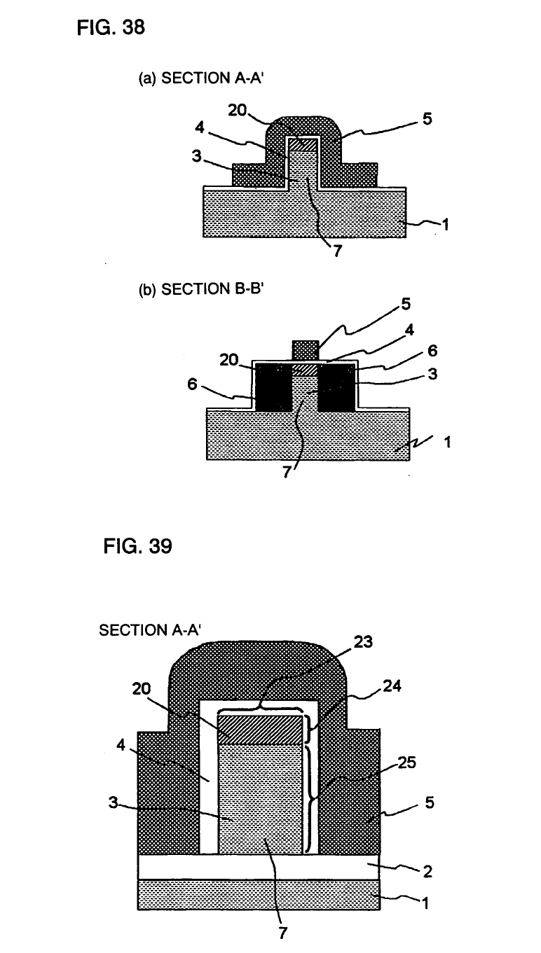

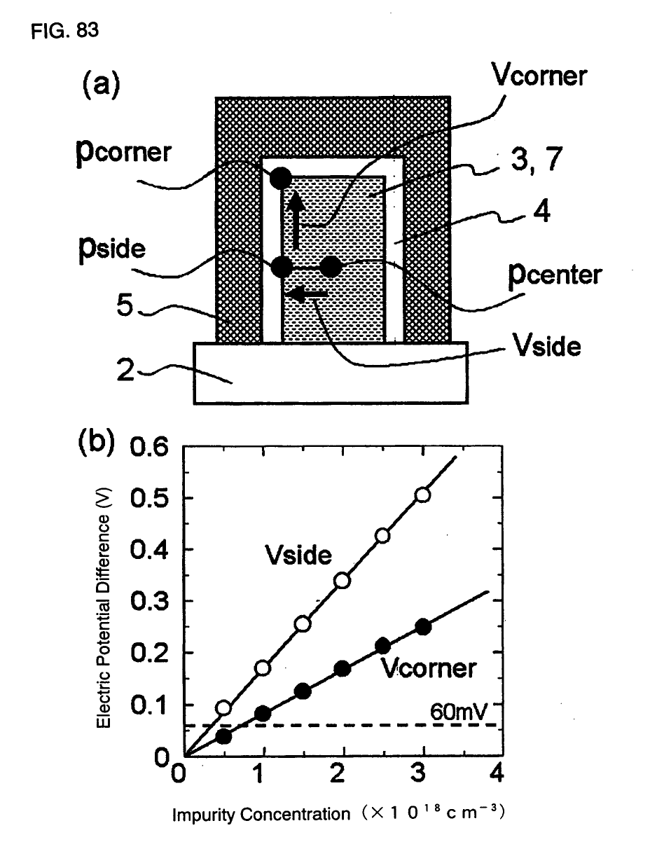

FIGS. 83(a) and 83(b) show the results of calculating a relationship between each of the amount of increase in electric potential Vcorner (black circle in the figure) in the upper corner portion and an difference in electric potential Vside (white circle in the figure) of the side surface of the semiconductor layer in a portion below the upper corner portion relative to the central portion of the semiconductor layer and the average value of the second conductivity type impurity concentration in the semiconductor layer 3 for the channel forming region. The calculation is performed for positions corresponding to the sections in FIG. 32(a) and FIG. 34(a) (see FIG. 83(a)).

A point pcorner shows a position at which the electric potential is highest (generally a corner portion, but if the corner is rounded, the position is determined from comparison of electric potentials of positions) in the upper corner portion of the semiconductor layer. A point pside shows a position of the side surface of the semiconductor layer in a position in a vertical direction (vertical direction refers to a longitudinal direction in the figure) where electric field concentration does not occur (side surface of the semiconductor layer in a portion below the upper corner portion; a position at which the dependency in the vertical direction of the electric potential is almost zero in the semiconductor side surface, or otherwise a position at which the electric potential is minimum in the side surface of the semiconductor layer). The point pcenter is identical to the point pside in position in the vertical direction, and is at a position of the center in the width direction (direction of Wfin, lateral direction in the figure) of the semiconductor layer. The amount of increase in electric potential Vcorner in the upper corner portion is a value obtained by subtracting the electric potential at the point pside from the electric potential at the point pcorner, and the difference in electric potential Vside of the side surface of the semiconductor layer in the portion below the upper corner portion relative to the central portion of the semiconductor layer is a value obtained by subtracting the electric potential at the point pcenter from the electric potential at the point pside. The calculation is performed provided that the width of the semiconductor layer is 30 nm, the thickness of a gate oxide film is 2 nm and the gate voltage is 0 V. The net concentration of the second conductivity type impurity is made constant in the semiconductor layer. The electric potential at the point pside is kept at a minimum value for the vertical direction of the side surface of the semiconductor layer, but when the electric potential at the point pcenter in the same position in the vertical direction changes, a position in the vertical direction at which the electric potential at the point pcenter is minimum.

The present invention is typically applied for improving a characteristic of a transistor in which Vcorner is 60 mV or more when no channel impurity concentration adjusting region is provided as described above, but from FIG. 83(b), it is conceivable that Vside is twice as large as Vcorner, and therefore the present invention is typically applied for improving a characteristic of a transistor in which Vside is 120 mV or more when no channel impurity concentration adjusting region is provided.

Since the channel impurity concentration adjusting region is typically provided less deeply than the upper corner portion where the electric potential increases, and the influence of provision of the channel impurity concentration adjusting region on Vside as a difference in electric potential in the horizontal direction in a region below the upper corner portion, the transistor of this embodiment is typically characterized in that Vside is 120 mV or more. However, pside in the transistor of this embodiment refers to a position at which the dependency in the vertical direction of the electric potential on the semiconductor side surface is almost zero on the side surface of the semiconductor layer situated in the lower part of the channel impurity concentration adjusting region (the channel forming region excepting the channel impurity concentration adjusting region), or otherwise a position at which the electric potential is minimum on the side surface of a region of the channel forming region situated in the lower part of the channel impurity concentration adjusting region. When electric potentials at pside, pcorner and pcenter change depending on the position in the direction of the gate length for a transistor with a short channel, an electric potential in a section in a position at which the electric potential at pcenter is the lowest is selected. When the electric potential at pcenter has a minimum value over a certain region in the direction of the gate length, an electric potential in a section in a position at which the electric potential at pside is the lowest is selected. When a region in which the electric potential at pcenter and the electric potential at pside each have a minimum value exists over a certain region in the direction of the gate length, an electric potential in a section in a position at which the electric potential at pcorner is the lowest is selected. When a region in which the electric potentials at the three points each have a minimum value exists over a certain region in the direction of the gate length, the electric potential is evaluated in a section in any position in the region. Evaluations of the electric potential and the difference in electric potential are made in a subthreshold region (the gate voltage is normally lower than the threshold voltage by 0.1 to 0.4 V and the gate voltage is typically 0 V) of a linear region (region having a low drain voltage, typically 0.05 V). The discussions concerning pside, pcorner, pcenter, Vcorner and Vside have been described with an n-channel transistor as an example, but in the case of a p-channel transistor, the polarity is reversed.

Since Vside becomes 120 mV or more when the impurity concentration is 7.5×10¹⁷ cm⁻³ or more, the present invention is typically applied for improving the performance of a transistor in which the average value of the impurity concentration in the semiconductor layer is 7.5×10¹⁷ cm⁻³ or more when no channel impurity concentration adjusting region is provided, and therefore in the transistor of this embodiment, the average value of the net concentration of the second conductivity type impurity in the channel forming region of a second conductivity type excepting the channel impurity concentration adjusting region is typically 7.5×10¹⁷ cm⁻³ or more.

If considering that Vcorner and Vside are normally slightly lower in a transistor of a short channel (gate length is typically 0.1 μm or less), the present invention is typically applied for improving the performance of a transistor in which the average value of the impurity concentration in the semiconductor layer is 1.0×10¹⁸ cm⁻³ or more when no channel impurity concentration adjusting region is provided, and therefore in the transistor of this embodiment having a short channel, the average value of the net concentration of the second conductivity type impurity in the channel forming region of a second conductivity type excepting the channel impurity concentration adjusting region is typically 1.0×10¹⁸ cm⁻³ or more.

In this specification, the following terms are used for the following meanings. The “net concentration of the second conductivity type impurity” refers to a value obtained by subtracting the concentration of the first conductivity type impurity (concentration of an activated donor for the n-channel transistor) from the concentration of the second conductivity type impurity (concentration of an activated acceptor ion for the n-channel transistor). The “channel forming region of a second conductivity type” refers to any of two regions: a region of the semiconductor layer 3 which is covered with the gate electrode and is a region of a second conductivity type and a region of the semiconductor layer 3 which is sandwiched between source/drain regions and is a region of a second conductivity type, whose volume is not larger than that of the other. The “region of a second conductivity type” refers to a region in which the concentration of an activated second conductivity type impurity is greater than the concentration of an activated first conductivity type impurity. In a normal FinFET, the end portion of the source/drain region is covered with the gate electrode, and therefore the “region of a second conductivity type in a region covered with the gate electrode” is synonymous with the “region of a second conductivity type in a region sandwiched between source/drain regions”, but if these regions are different, one of these regions which has a smaller volume is determined to be the “channel forming region of a second conductivity type” as described above. The first conductivity type refers to a conductivity type of the source/drain region, and the second conductivity type refers to a conductivity type different from that of the source/drain region.

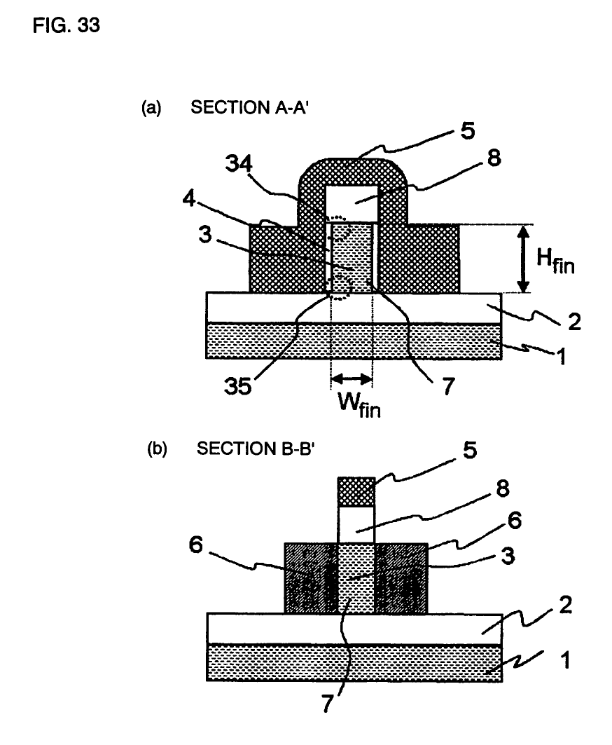

The depth Htop of the channel impurity concentration adjusting region 10 is normally half of the height Hfin of the semiconductor layer or less (see FIGS. 32(a) and 32(b) and FIGS. 33(a) and 33(b)). However, for a transistor in which the Hfin is very small (typically the Hfin is 40 nm or less), the Htop may be half of the Hfin or more.

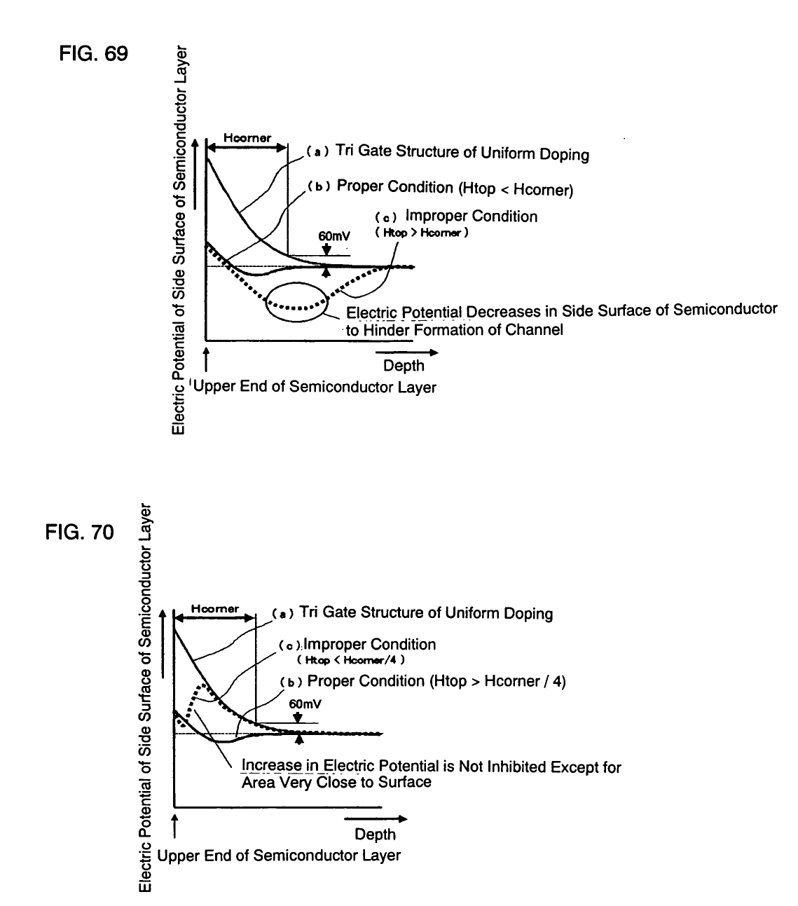

The channel impurity concentration adjusting region 10 is preferably provided in a region in which an increase in electric potential of the semiconductor layer occurs due to electric field concentration (referred to as Hcorner; typically a region in which an increase in electric potential by 60 mV or more, which corresponds to an increase by an order of magnitude in a leak current by a parasitic transistor). This will be described with reference to FIG. 69. If the depth Htop of the channel impurity concentration adjusting region 10 exceeds the Hcorner, the electric potential distribution has a shape like the curve (c) in FIG. 69, and an action for reducing the electric potential becomes so strong that the electric potential of the semiconductor side surface decreases excessively. If the electric potential decreases excessively, formation of a channel is hindered, and therefore a problem of a decrease in drain current arises. Thus, the Htop is preferably smaller than the Hcorner.

The size of Hcorner is determined from calculation. FIG. 60 shows the results of simulation showing a relationship between the width Wfin (see FIGS. 32(a) and 32(b) and FIGS. 33(a) and 33(b)) and the depth Hcorner in which electric field concentration occurs. Here, the depth refers to a length extending along a direction vertical to the plane of the base from the upper end of the semiconductor layer to any point below the upper end. The Hcorner is the depth of a region in which the electric potential in the side surface of the semiconductor layer of a FinFET having a tri gate structure increases by 60 mV or more (corresponding to an electric potential at which a leak current increases by an order of magnitude due to the parasitic transistor) from a minimum value in the side surface (normally an electric potential at a depth greater than half of the height Hfin of the semiconductor layer). In the channel forming region of the semiconductor layer, the concentration of the second conductivity type impurity is made uniform. The concentration of the second conductivity type impurity in the channel forming region of the FinFET of each Wfin is set to be inversely proportional to Wfin so that the threshold voltage does not change even if Wfin is changed. In this figure, it is apparent that Hcorner is proportional to Wfin (proportionality factor: 0.7) and electric field concentration occurs to a depth which is 0.7 times as large as the width Wfin of the semiconductor layer. In this respect, the depth Htop of the channel impurity concentration adjusting region is preferably 0.7 times or less as large as the width Wfin of the semiconductor layer.

If Htop is too small, an increase in electric potential is inhibited only a quite limited upper part of the semiconductor layer as shown in FIG. 70, and an increase in electric potential cannot be inhibited over an entire depth in which electric concentration occurs (curve (c) in FIG. 70). For inhibiting an increase in electric potential to a necessary degree over an entire depth in which electric field concentration occurs, Htop is preferably ¼ or more of Hcorner, more preferably ½ or more of Hcorner. Thus, if considering a relationship with FIG. 60 as well, Htop is preferably 7/40 times or more as large as Wfin, more preferably 7/20 times or more as large as Wfin.

For operating the FinFET in a fully depleting manner, the width of Wfin is normally 35 nm or less, and therefore Htop is typically 24.5 nm or less. Htop is preferably 5 nm or more in terms of ease in the production method. Thus, Htop is typically 5 nm to 24.5 nm. In view of a tradeoff between ease in the production method and effect (production becomes easier as Htop increases in terms of production), Htop is preferably in a range from 10 nm to 20 nm, and the most typical value of Htop is 10 nm.

If the impurity concentration in the channel forming region is low, an increase in electric potential in the upper corner is low, and therefore formation of the channel impurity concentration adjusting region 10 is especially effective when the average value of the net concentration of the second conductivity type impurity in the channel forming region is 1×10¹⁸ cm⁻³ or more.

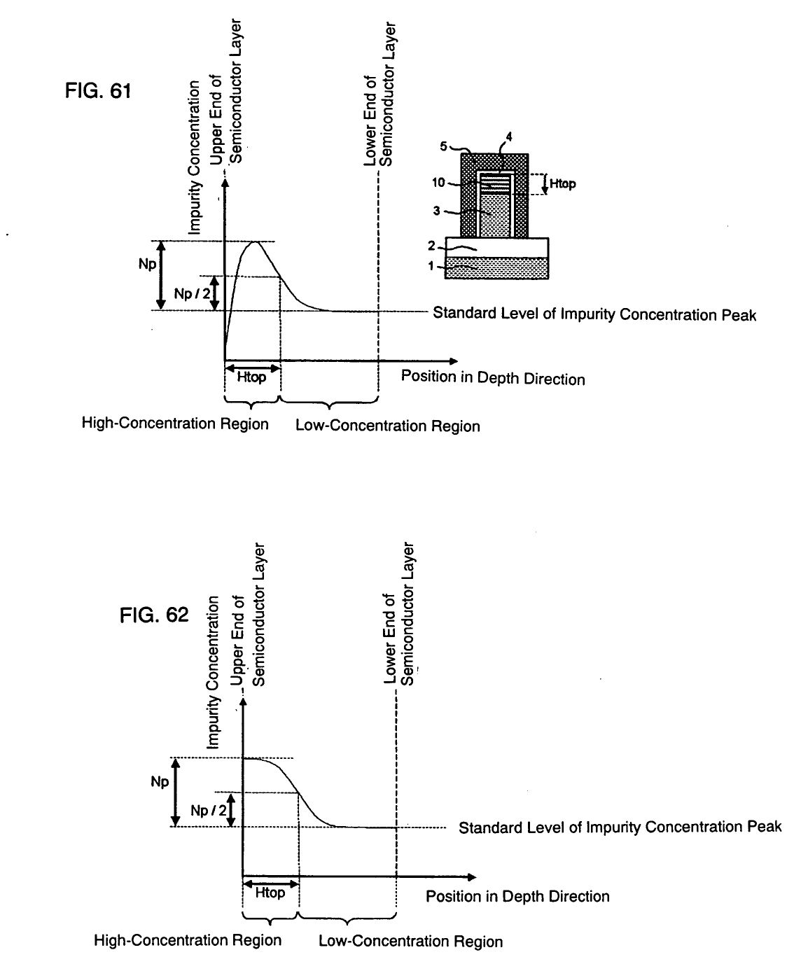

The definition of the depth (Htop) of the channel impurity concentration adjusting region 10 when the impurity distribution smoothly changes will be described with reference to FIGS. 61 to 68. FIGS. 61 to 68 depict an impurity concentration distribution in the longitudinal direction (direction vertical to the substrate) in the semiconductor layer where the position in the depth direction when viewed from the upper end of the semiconductor layer 3 of the FinFET is plotted on the abscissa and the net concentration of the second conductivity type impurity is plotted on the ordinate. In this connection, the net concentration of the second conductivity type impurity on the ordinate refers to the average value of the net concentration of the second conductivity type impurity in a section parallel to the plane of the substrate in the channel forming region of a second conductivity type at each position in the depth direction.

The depth Htop of the channel impurity concentration adjusting region 10 situated in the upper part of the semiconductor layer is a depth from the upper surface of the semiconductor layer 3 at a position below the position of the peak of the impurity concentration (right direction in the figure) and in which the height (Np) of an impurity concentration peak decreases (FIGS. 61 and 62). This is based on the result of simulation showing that if Htop is defined as described above, electric potential distributions for the same Htop are almost equal between the case where the impurity concentration smoothly changes and the case where the impurity concentration changes stepwise. The height (Np) of the impurity concentration peak refers to a difference between a maximum value of the impurity concentration and a standard level of the impurity concentration peak. The standard level of the impurity concentration peak refers to an impurity concentration at a position below (in depth direction) the position of the impurity concentration peak and in which the impurity concentration is minimum.

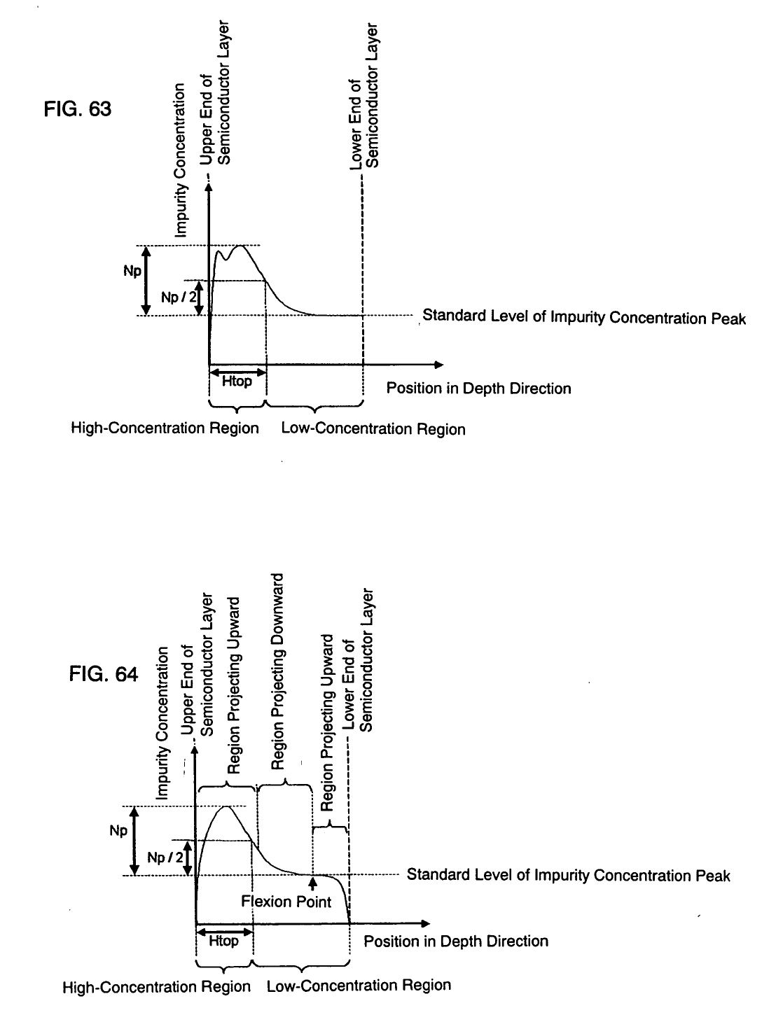

If there are a plurality of impurity concentration peaks as shown in FIG. 63, the height (Np) of the impurity concentration peak is based on an impurity concentration peak at which the impurity concentration is highest.

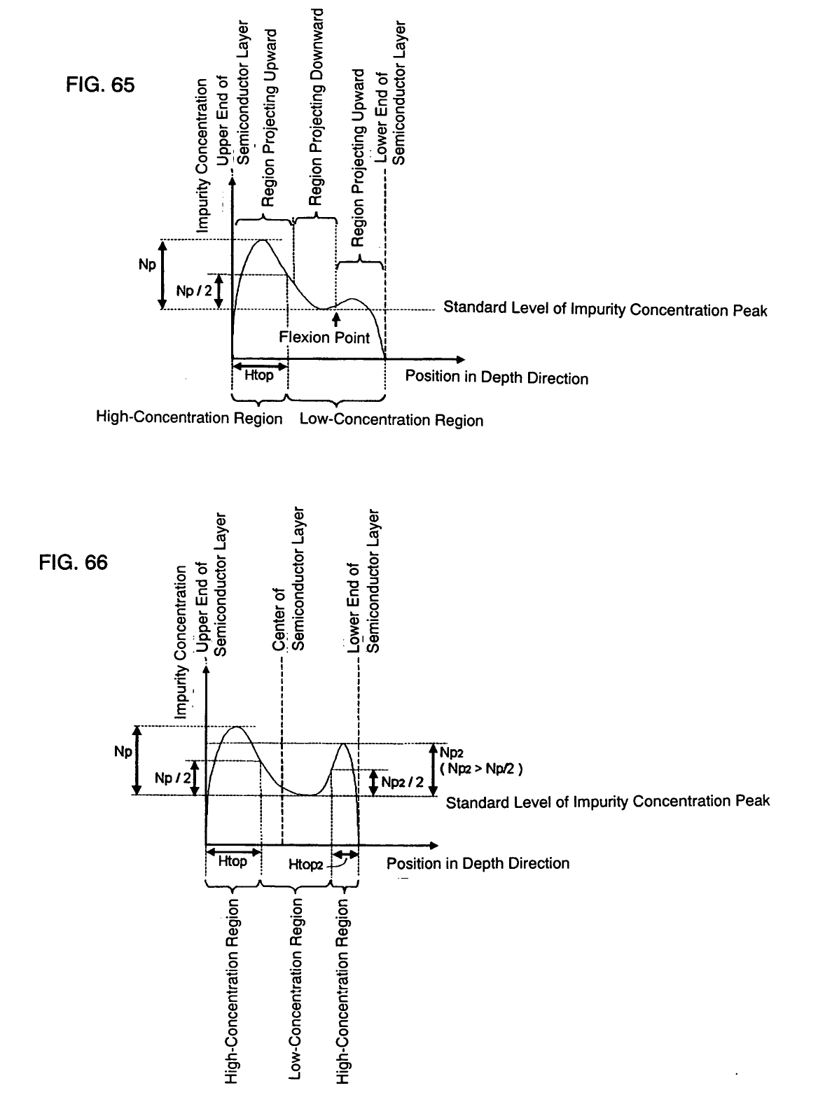

There may be cases where the concentration of the second conductivity type impurity decreases in a quite limited region in the vicinity of the boundary of the lower part of the semiconductor layer, but the impurity concentration in such a region is not included in determination of a standard level of the impurity concentration peak. Specifically, the impurity concentration in a region where the dependency of the net impurity concentration on the position in the depth direction takes on a curve raised upward in the vicinity of the boundary of the lower part (region where the secondary differentiation of the net impurity concentration with the position in the depth direction gives a negative value; it does not mean that the region projects upward) is excluded from determination of the standard level of impurity concentration peak (see FIGS. 64 and 65).

If channel impurity concentration adjusting regions 10 (upper channel impurity concentration adjusting region 19 and lower channel impurity concentration adjusting region 11) are provided on the upper end portion and the lower end portion, respectively, of the semiconductor layer according to the third embodiment described later, the height Htop2 of the lower channel impurity concentration adjusting region 11 is a distance from a position on the plane of the base relative to the semiconductor layer 3 (boundary between the lower end of the semiconductor layer and the buried insulating film if the semiconductor layer is provided on the buried insulating film on the support substrate) for a position above the position of the impurity concentration peak (left direction in the figure) and in which the height of the impurity concentration peak decreases to half (FIG. 66). The height (Np2) of the impurity concentration peak of the lower channel impurity concentration adjusting region 11 refers to a difference between a maximum value of the impurity concentration at the impurity concentration peak situated below the center of the semiconductor layer (right direction in the figure) and the standard level of the impurity concentration peak.

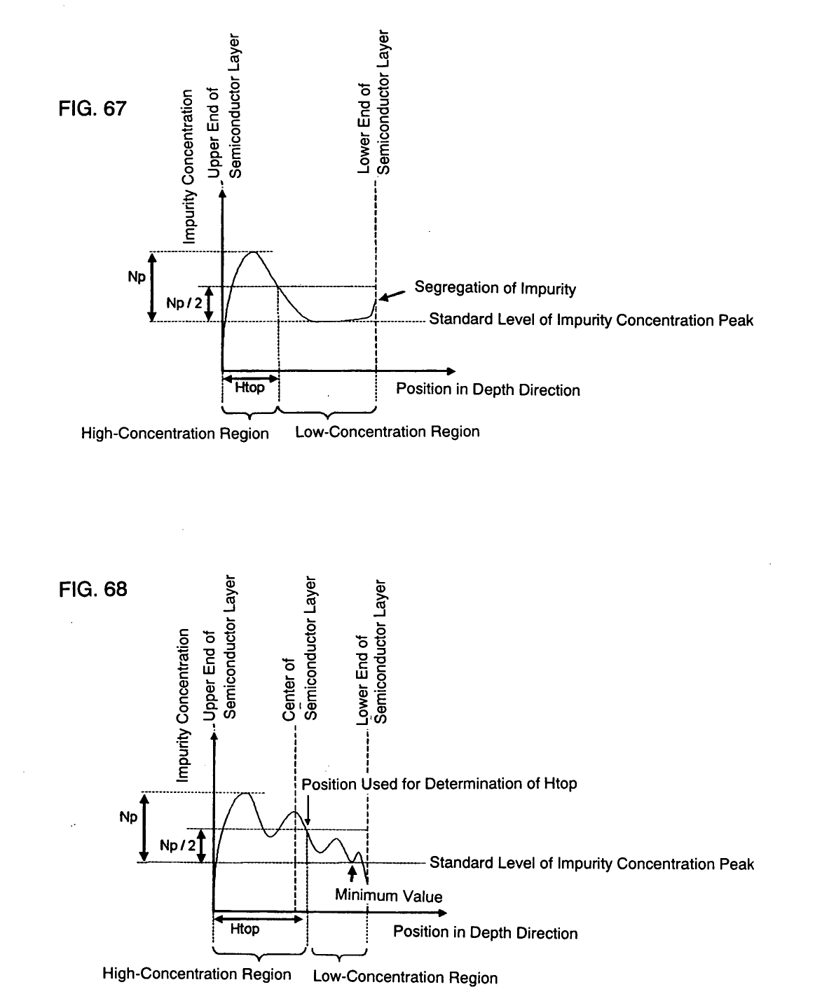

If the height of the impurity concentration peak situated below the center of the semiconductor layer does not exceed Np/2 when the concentration of the second conductivity type impurity increases in a quite limited region in the vicinity of the boundary of the lower part of the semiconductor layer due to segregation of an impurity or when an impurity is intentionally introduced into the lower part of the semiconductor layer, it is not considered that there is a lower channel impurity concentration adjusting region (see FIG. 67).

If there are a plurality of positions at which the impurity concentration is Np/2 or Np2/2, Htop or Htop2 is determined with a position closest to a position at which the impurity concentration decreases to the standard level of the impurity concentration peak (FIG. 68).

[Production Method]

### First Production Method of First Embodiment

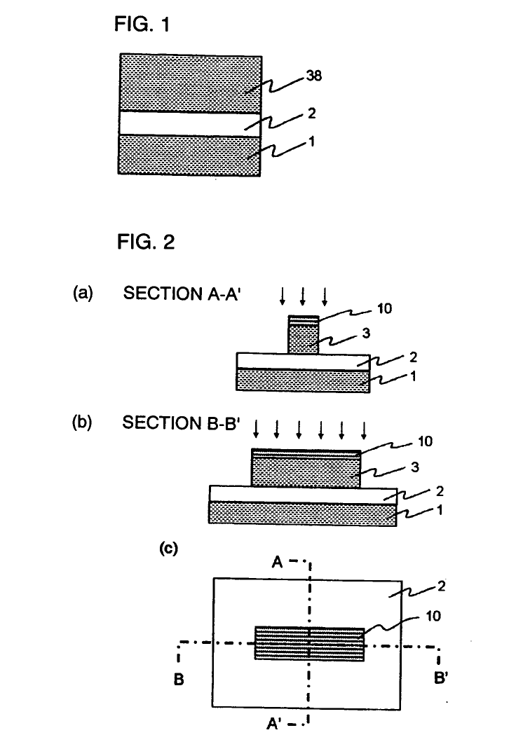

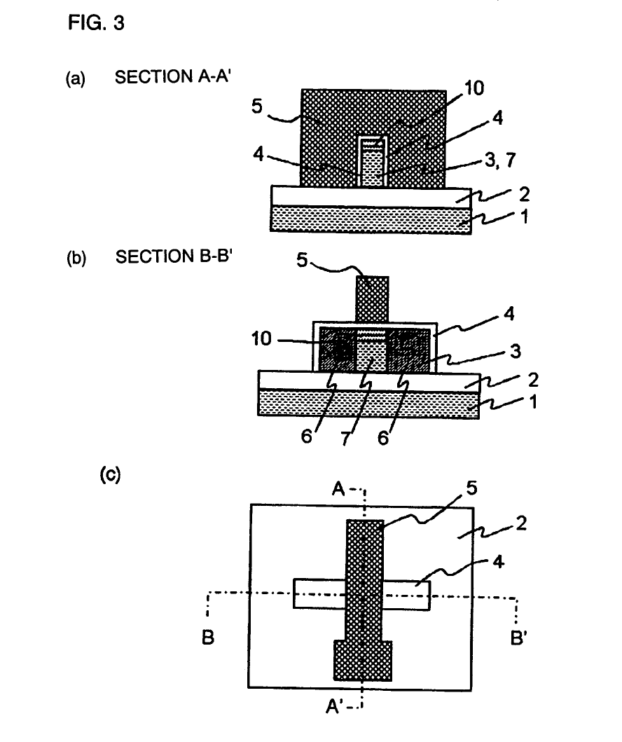

A first production method of the first embodiment will be described with reference to FIG. 1, FIGS. 2(a), 2(b) and 2(c), FIGS. 3(a), 3(b) and 3(c), FIGS. 4(a) and 4(b) and FIG. 5. FIG. 2(a), FIG. 3(a) and FIG. 4(a) are sectional views in sections A-A′ in FIG. 2(c), FIG. 3(c) and FIG. 5, respectively, and depict the shape of a section in a position corresponding to the section A-A′ in FIG. 31 which is a plan view showing an example of a conventional technique on a step-by-step basis. FIG. 2(b), FIG. 3(b) and FIG. 4(b) are sectional views in sections B-B′ in FIG. 2(c), FIG. 3(c) and FIG. 5, respectively, and depict the shape of a section in a position corresponding to the section B-B′ in FIG. 31 which is a plan view showing an example of a conventional technique on a step-by-step basis.

For producing the field effect transistor of the first embodiment, a semiconductor layer 38 of a substrate is patterned to a semiconductor layer 3 projecting from the surface of the substrate, and an impurity is introduced into a region of the upper part of the semiconductor layer 3 by an impurity introduction step such as ion implantation. In this way, a channel impurity concentration adjusting region 10 which has an impurity concentration higher than that of other regions of the semiconductor layer 3 and in which a second conductivity type impurity is introduced is provided in the upper part of the semiconductor layer 3 (FIGS. 2(a), 2(b) and 2(c)). Next, a gate insulating film 4 is formed on the side surface of the semiconductor 3, a gate electrode material is deposited, the gate electrode material is then patterned by RIE (reactive ion etching) or the like to form a gate electrode 5, and a high-concentration first conductivity type impurity is introduced into a region of the semiconductor layer 3 which is not covered with the gate electrode 5, whereby source/drain regions 6 are formed (FIGS. 3(a), 3(b) and 3(c)). Thereafter, an interlayer insulating film is deposited to form a contact 17 and an interconnect 18 for the source/drain regions 6 and the gate electrode 5 (FIGS. 4(a) and 4(b) and FIG. 5).

A low-concentration second conductivity type impurity is introduced into the semiconductor layer 3 (including a region other than the channel impurity concentration adjusting region 10) by the impurity introduction step carried out at an appropriate time point (e.g. before or after a step of carrying out ion implantation for the channel impurity concentration adjusting region 10, or before forming the semiconductor layer 3 projecting from the surface of the substrate by patterning, or the like).

Here, a typical structure of the first embodiment can be produced by setting the depth and the impurity concentration of the channel impurity concentration adjusting region 10 so as to satisfy the typical structure of the first embodiment (in which the average value of the net concentration of the second conductivity type impurity in an area extending from the upper end of the semiconductor layer 3 to a depth Htop in a channel forming region 7 of a second conductivity type is typically in a range from 1.3 times or more to 4 times or less as large as the average value of the net concentration of the second conductivity type impurity in the semiconductor layer excepting the area extending from the upper end of the semiconductor layer 3 to the depth Htop, and more typically, the average value of the net concentration of the second conductivity type impurity in an area extending from the upper end of the semiconductor layer 3 to the depth Htop in the channel forming region 7 of a second conductivity type is typically in a range from 1.5 times or more to 3 times or less as large as the average value of the net concentration of the second conductivity type impurity in the semiconductor layer excepting the area extending from the upper end of the semiconductor layer 3 to the depth Htop.

### Example of First Production Method of First Embodiment

For the first production method of the first embodiment, an example will be described more specifically with reference to FIGS. 1 to 5.

In an SOI substrate (FIG. 1) prepared by laminating a buried insulating layer 2 composed of an insulating material such as SiO₂ on a support substrate 1 composed of silicon, and further laminating thereon a semiconductor layer 38 composed of monocrystalline silicon, the semiconductor layer 38 is patterned by a normal lithography step and a normal etching step such as RIE to process the semiconductor layer 38 into an appropriate shape, and an element region composed of a semiconductor layer 3 projecting from the substrate is thereby shaped. A first channel ion implantation step of ion-implanting a second conductivity type impurity to the entire semiconductor layer with moderate energy is carried out, and a second channel ion implantation step of ion-implanting the second conductivity type impurity to the surface of the semiconductor layer with low energy is then carried out. In the second channel ion implantation step, the implantation depth is smaller than that in the first channel ion implantation step, and the impurity is implanted to a region where a channel impurity concentration adjusting region 10 is formed. Through this step, the channel impurity concentration adjusting region 10 having an impurity concentration higher than that in other regions of the semiconductor layer 3 is formed on the upper part of the semiconductor layer 3 (FIGS. 2(a), 2(b) and 2(c)).

Next, a gate insulating film 4 is provided on the side surface of the semiconductor layer 3, polysilicon is then deposited, etched by a normal lithography step and RIE step and thereby patterned to form a gate electrode, high-concentration ion implantation is subsequently carried out using the gate electrode as a mask, and a heat treatment is performed to provide source/drain regions 6 on the semiconductor layer 3 at a position in which the semiconductor layer 3 is not covered with the gate electrode, so that the shape in FIGS. 3(a), 3(b) and 3(c) is obtained. The gate insulating film is provided by, for example, thermally oxidizing the semiconductor layer 3. The source/drain regions are formed by introducing an impurity by an impurity introduction step such as vertical ion implantation, slanting ion implantation or plasma doping.

Subsequently, an insulating film is deposited on the entire surface and etched back to provide a gate side wall 14. For the insulating film forming the gate side wall 14, an insulating film such as, for example, a SiO₂ monolayer film, a Si₃N₄ monolayer film, a multilayered film composed of SiO₂ and Si₃N₄ is used. The insulating film forming the gate side wall 14 is formed by a film formation technique such as a CVD method. Subsequently, a metal is deposited on the upper part of the source/drain regions 6 and the upper part of the gate electrode 5, and a heat treatment is performed to form a silicide layer 15 on the upper part of the source/drain regions 6 and the upper part of the gate electrode 5. Subsequently, an interlayer insulating film 16 is deposited and flattened, contact holes are then opened to the source/drain regions 6 and the gate electrode 5, a metal is buried to form a contact 17, and an interconnect 18 composed of a metal is connected to the contact 17 to obtain the shape in FIGS. 4(a) and 4(b) and FIG. 5. The burying of the metal in a contact region and deposition of the metal as a interconnect may be performed at the same time. The contact 17 is situated below the interconnect 18, but its position is shown perspectively in FIG. 5.

The First channel ion implantation step, or the second channel ion implantation step for forming the channel impurity concentration adjusting region 10 may be carried out before the step of patterning the semiconductor layer 38 to process the same into an appropriate shape and thereby forming the element region composed of the semiconductor layer 3 projecting from the substrate.

Here, the depth and the impurity concentration of the channel impurity concentration adjusting region 10 are set to satisfy the typical structure of the first embodiment.

### Second Production Method of First Embodiment

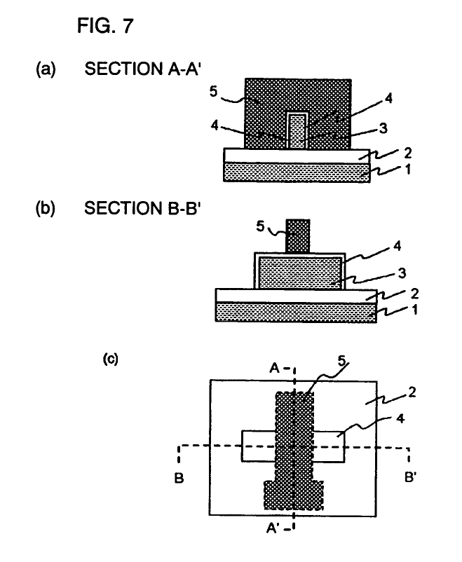

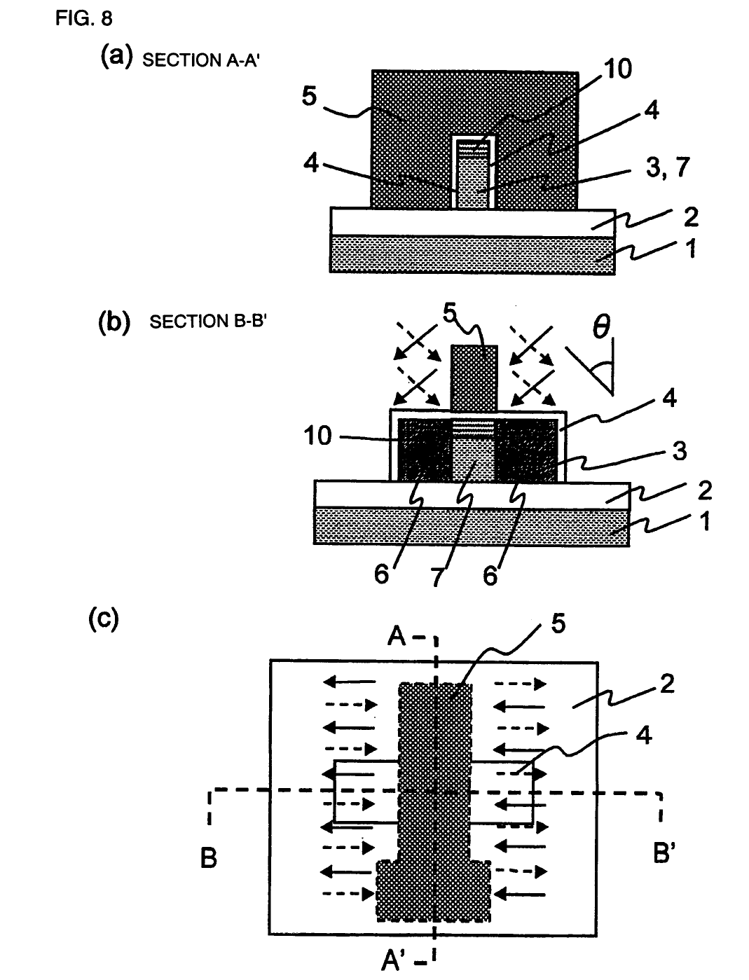

A second production method of the first embodiment will be described with reference to FIGS. 6(a), 6(b) and 6(c), FIGS. 7(a), 7(b) and 7(c) and FIGS. 8(a), 8(b) and 8(c). FIG. 6(a), FIG. 7(a) and FIG. 8(a) are sectional views in sections A-A′ in FIG. 6(c), FIG. 7(c) and FIG. 8(c), respectively, and depict the shape of a section in a position corresponding to the section A-A′ in FIG. 31 which is a plan view showing an example of a conventional technique on a step-by-step basis. FIG. 6(b), FIG. 7(b) and FIG. 8(b) are sectional views in sections B-B′ in FIG. 6(c), FIG. 7(c) and FIG. 8, respectively, and depict the shape of a section in a position corresponding to the section B-B′ in FIG. 31 which is a plan view showing an example of a conventional technique on a step-by-step basis.

For producing the field effect transistor of the first embodiment, a semiconductor layer 38 of a substrate is first patterned to form a semiconductor layer 3 projecting from the surface of the substrate (FIGS. 6(a), 6(b) and 6(c)). Next, a gate insulating film 4 is formed on the side surface of the semiconductor layer 3, a gate electrode material is deposited, and an electrode material is patterned by RIE (reactive ion etching) or the like to form a gate electrode 5 straddling the semiconductor layer 3 (FIGS. 7(a), 7(b) and 7(c)). Ion implantation is carried out using the gate electrode as a mask, whereby a channel impurity concentration adjusting region 10 of which the concentration of a second conductivity type impurity is higher than that in other regions of the semiconductor layer 3 is formed on the upper part of the semiconductor layer 3. Then, a high-concentration first conductivity type impurity is introduced into a region of the semiconductor layer 3 which is not covered with the gate electrode, and source/drain regions 6 are thereby formed (FIGS. 8(a), 8(b) and 8(c)). Thereafter, an interlayer insulating film is deposited, and a contact 17 and an interconnect 18 are formed for the source/drain regions 6 and the gate electrode 5 by a normal method (The obtained configuration is same as that in FIGS. 4(a) and 4(b) and FIG. 5 except that the impurity distribution is slightly different as described below. However, there may be a characteristic in which the impurity concentration changes within the channel impurity concentration adjusting region 10 according to the position as described below.)

A low-concentration second conductivity type impurity is introduced into the semiconductor layer 3 (including a region other than the channel impurity concentration adjusting region 10) by an impurity introduction step carried out at an appropriate time point (e.g. before or after forming the semiconductor layer 3 projecting from the surface of the substrate by patterning). In the second production method of the first embodiment, the channel impurity concentration adjusting region 10 is formed by slanting ion implantation, and therefore the impurity distribution in and near the channel impurity concentration adjusting region 10 is slightly different from that in the first production method of the first embodiment, but the channel impurity concentration adjusting region 10 satisfying a typical structure of the first embodiment is formed on the upper part of the semiconductor layer 3. However, in the second production method of the first embodiment, the channel impurity concentration adjusting region 10 is formed by slanting ion implantation, and therefore there may be an impurity distribution in which the impurity concentration changes in the longitudinal direction of a channel (direction in which two source/drain regions are linked) in the channel impurity concentration adjusting region 10 depending on the condition of ion implantation.

Here, a typical structure of the first embodiment can be produced by setting the depth and the impurity concentration of the channel impurity concentration adjusting region 10 so as to satisfy the typical structure of the first embodiment.

A replacement gate process may be applied for this production method. That is, in the production method described herein, a method of carrying out a production step in which a dummy gate electrode straddling the semiconductor layer 3 is processed instead of the gate electrode, slanting ion implantation is carried out using the dummy gate electrode as a mask to form a channel impurity concentration adjusting region 10 of which the concentration of a second conductivity type impurity is higher than that in other regions of the semiconductor layer 3 on the upper part of the semiconductor layer 3, a step of removing the dummy gate is carried out in an appropriate stage, for example after forming an interlayer insulating film covering the gate electrode, and a conductive material buried in a hollow portion formed as a result of the removal of the dummy gate electrode to form a gate electrode may be used.

### Example of Second Production Method of First Embodiment

For the second production method of the first embodiment, a more specific example will be described with reference to FIGS. 6(a), 6(b) and 6(c), FIGS. 7(a), 7(b) and 7(c) and FIGS. 8(a), 8(b) and 8(c).

In an SOI substrate (having a configuration same as that in FIG. 1) prepared by laminating a buried insulating layer 2 composed of an insulating material such as SiO₂ on a support substrate 1 composed of silicon, and further laminating thereon a semiconductor layer 38 composed of monocrystalline silicon, the semiconductor layer 38 is patterned by a normal lithography step and a normal etching step such as RIE to process the semiconductor layer 38 into an appropriate shape (FIGS. 6(a), 6(b) and 6(c)), and an element region composed of a semiconductor layer 3 projecting from the substrate is thereby shaped. A channel ion implantation step of ion-implanting a second conductivity type impurity to the semiconductor layer 3 with energy allowing an impurity to be introduced into the semiconductor layer 3 in its entirety (e.g. energy equal to the energy in the first channel ion implantation of the first production method of the first embodiment) is carried out.

Next, a gate insulating film 4 is provided on the side surface of the semiconductor layer 3, polysilicon is then deposited, etched by a normal lithography step and RIE step and thereby patterned to form a gate electrode 5 straddling the semiconductor layer 3, and slanting ion implantation is carried out with an angle provided with respect to a plane vertical to the plane of the substrate and the longitudinal direction of a channel using the gate electrode as a mask (see FIGS. 8(a), 8(b) and 8(c) illustrating a case where an angle of +θ and −θ is provided with respect to a plane vertical to the plane of the substrate and the longitudinal direction of the channel), whereby a channel impurity concentration adjusting region 10 of which the concentration of a second conductivity type impurity is higher than that in other regions of the semiconductor layer 3 is formed on the upper part of the semiconductor layer 3.

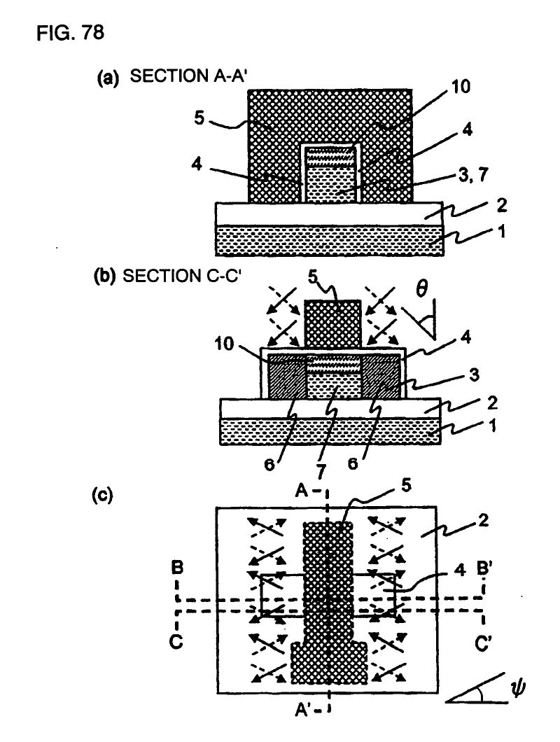

If the slanting ion implantation has an angle with respect to a plane vertical to the plane of the substrate and parallel to the longitudinal direction of the channel (angle ψ) in FIG. 78(c)), it also has a capability of forming a hollow region as described later, but if the main purpose is to form the channel impurity concentration adjusting region 10 on the upper part of the semiconductor layer 3, the ion implantation is most preferably carried out parallel to a plane vertical to the plane of the base and parallel to the longitudinal direction of the channel. If the angle with respect to a plane vertical to the plane of the substrate and parallel to the longitudinal direction of the channel (angle ψ FIG. 78(c)) is 10 degrees or less, although the ion implantation is not carried out parallel to the plane, a capability of forming a hollow region is low, and therefore if the main purpose is to form the channel impurity concentration adjusting region 10 on the upper part of the semiconductor layer 3, the angle with respect to a plane vertical to the plane of the substrate and parallel to the longitudinal direction of the channel is preferably 10 degrees or less.

Subsequently, high-concentration ion implantation is carried out using the gate electrode 5 as a mask, and a heat treatment is performed to provide source/drain regions 6 on the semiconductor layer 3 at a position in which the semiconductor layer 3 is not covered with the gate electrode, so that the shape in FIGS. 8(a), 8(b) and 8(c) is obtained. The gate insulating film is provided by, for example, thermally oxidizing the semiconductor layer 3. The source/drain regions are formed by introducing an impurity by an impurity introduction step such as vertical ion implantation, slanting ion implantation or plasma doping.

Subsequently, an insulating film is deposited on the entire surface and etched back to provide a gate side wall 14. For the insulating film forming the gate side wall 14, an insulating film such as, for example, a SiO₂ monolayer film, a Si₃N₄ monolayer film, a multilayered film composed of SiO₂ and Si₃N₄ is used. The insulating film forming the gate side wall 14 is formed by a film formation technique such as a CVD method. Subsequently, a metal is deposited on the upper part of the source/drain regions 6 and the upper part of the gate electrode 5, and a heat treatment is performed to form a silicide layer 15 on the upper part of the source/drain regions 6 and the upper part of the gate electrode 5. Subsequently, an interlayer insulating film 16 is deposited and flattened, a contact hole is then opened to the source/drain regions 6 and the gate electrode 5, a metal is buried to form a contact 17, and an interconnect 18 composed of a metal is connected to the contact 17 (the obtained configuration is same as that in FIGS. 4(a) and 4(b) and FIG. 5 except that the impurity distribution is slightly different). The burying of the metal in a contact region and deposition of the metal as an interconnect may be performed at the same time. The contact 17 is situated below the interconnect 18, but its position is shown perspectively in FIG. 5.

As shown in FIGS. 78(a), 78(b) and 78(c), if a capability of forming a hollow region is positively provided when slanting ion implantation is carried out using the gate electrode as a mask, ion implantation may be carried out not only with an angle (in FIGS. 8(a), 8(b) and 8(c), angles −θ, +θ with respect to the vertical line of the plane of the substrate in a plane vertical to the plane of the substrate and parallel to the longitudinal direction of the channel) provided in a plane vertical to a wafer but also with an angle (in FIG. 78(c), angles +ψ, −ψ, 180°+ψ, 180°−ψ with respect to a plane vertical to the plane of the substrate and parallel to the longitudinal direction of the channel) provided in the plane of the wafer (FIG. 78(c)). Ion implantation with an angle provided in the plane of the wafer corresponds to slanting ion implantation for forming a hollow region in a normal flat field effect transistor. Here, by providing an angle in the surface of the wafer, two effects: an effect of hollow ion implantation and an effect of forming a channel impurity concentration adjusting region on the upper part of the semiconductor layer can be obtained at the same time. In this case, the typical magnitude of ψ is 20 to 70 degrees.

Both of first slanting ion implantation which has an angle in a plane vertical to the wafer and is parallel to a plane vertical to the plane of the substrate and parallel to the longitudinal direction of the channel (ion implantation illustrated in FIGS. 8(a), 8(b) and 8(c)) and second slanting ion implantation having an angle in a plane vertical to the wafer and having an angle with respect to the longitudinal direction of the channel in the plane of the wafer (ion implantation illustrated in FIGS. 78(a), 78(b) and 78(c) may be carried out. In this case, second ion plantation has a role of normal hollow ion implantation (inhibition of a short channel effect) and first ion implantation has a role of introducing into the upper part of the semiconductor layer an impurity sufficient for formation of a channel impurity concentration adjusting region capable of inhibiting parasitic transistor, thus being especially effective for formation of a FinFET with a short channel.

First slanting ion implantation which has an angle in a plane vertical to the wafer and is not parallel to a plane vertical to the plane of the substrate and parallel to the longitudinal direction of the channel and second slanting ion implantation having an angle in a plane vertical to the wafer and having an angle with respect to a plane vertical to the plane of the substrate and parallel to the longitudinal direction of the channel, with the angle greater than that of first slanting ion implantation, may be carried out. The case where first ion implantation has a role of introducing into the upper part of the semiconductor layer an impurity sufficient for formation of a channel impurity concentration adjusting region capable of inhibiting a parasitic transistor and second slanting ion implantation has a role of hollow ion implantation is same as the aforementioned case where first slanting ion implantation is parallel to a plane vertical to the plane of the substrate and parallel to the longitudinal direction of the channel. In this case, an angle with respect to a plane vertical to the plane of the substrate and parallel to the longitudinal direction of the channel in first slanting ion implantation is preferably 10 degrees or less in terms of formation of a channel impurity concentration adjusting region.

If energy for slanting ion implantation is low or if the angle θ is small, two channel impurity concentration adjusting regions may be formed such that they are adjacent to each other or explicitly isolated from each other, in the vicinity of two source/drain regions having a channel forming region sandwiched therebetween, but such a state will be described in the second embodiment.

Here, the depth and the impurity concentration of the channel impurity concentration region 10 are set so as to satisfy the typical structure of the first embodiment.

[Effect]

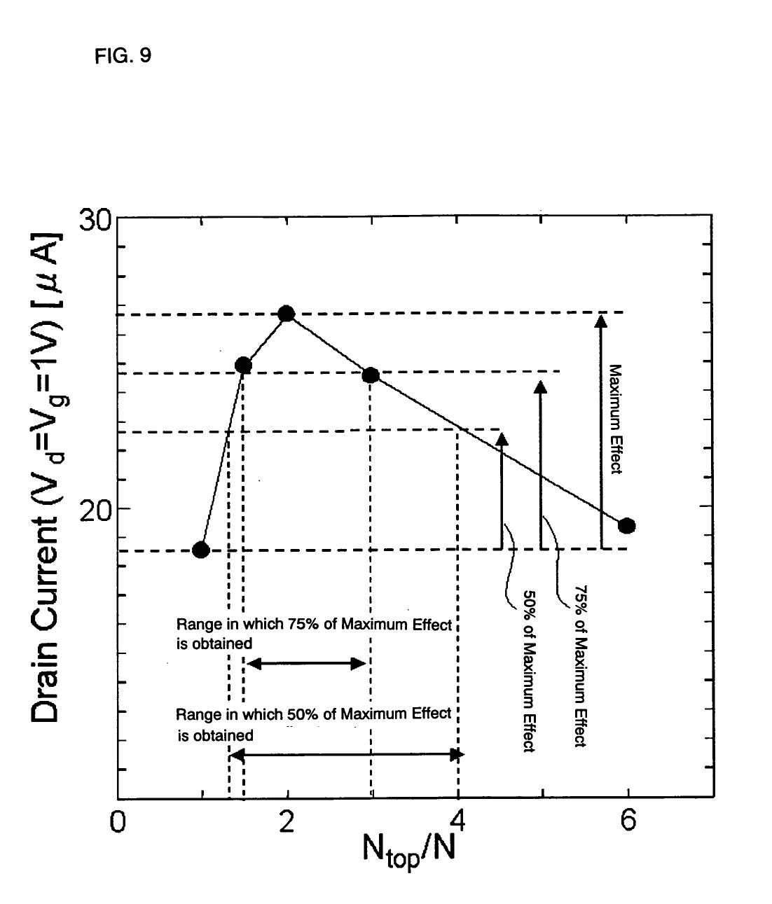

The results of simulation for a transistor characteristic when applying the first embodiment to an n-channel field effect transistor (structure in FIGS. 3(a), 3(b) and 3(c), FIGS. 4(a) and 4(b) and FIG. 5) are shown in FIG. 9. The value Ntop/N obtained by dividing the average value Ntop of the acceptor impurity concentration in a region extending from the upper end of the semiconductor layer 3 to the depth of 10 nm in the channel forming region of a second conductivity type by the average value N of the acceptor impurity concentration in the channel forming region of a second conductivity type excepting the region extending from the upper end of the semiconductor layer 3 to the depth of 10 nm is plotted on the abscissa, and the on-current (drain current when applying an on-state voltage to the gate electrode) is plotted on the ordinate. The threshold voltage at each level is set so that the off-current at each level (drain current when the gate voltage is set to 0 volt) is the same. No donor impurity is introduced in the channel region of the semiconductor layer.

If the impurity concentration is uniform throughout the semiconductor layer (Ntop/N=1), the on-current is low. In this case, the electric potential increases in an upper corner portion 34 of the semiconductor layer 3 to generate a parasitic transistor, and the off-current increases. Thus, when a comparison is made on the on-current with the off-current kept constant as in FIG. 9, the on-current is low.

If Ntop/N is very high (e.g. Ntop/N=6), the upper end portion of the semiconductor layer 3 does not operate as a channel. In this case, the off-current is inhibited because the parasitic transistor is inhibited, but the drain current decreases because channels are no longer formed on the upper surface 23 of the semiconductor layer and the upper side surface 24 of the semiconductor layer (see FIG. 39). It is believed that this condition corresponds to the structure described in Patent Document 1.

The on-current becomes maximum when Ntop is twice as large as N. In a condition close to this condition, channels are formed on the upper surface 23 of the semiconductor layer and the upper side surface 24 of the semiconductor layer, and there is an action of inhibiting the parasitic transistor. Thus, inhibition of the off-current is compatible with improvement of the on-current, and the on-current is improved. When Ntop is twice as large as N, this action becomes most remarkable, and a maximum effect can be obtained.

When Ntop is in a range from 1.5 times to 3.5 times as large as N, an effect accounting for 75% of the maximum effect can be obtained, and a sufficient action can be obtained. When Ntop is in a range from 1.3 times to 4 times as large as N, an effect accounting for 50% of the maximum effect can be obtained, and an action that is effective in a practical standpoint is obtained.

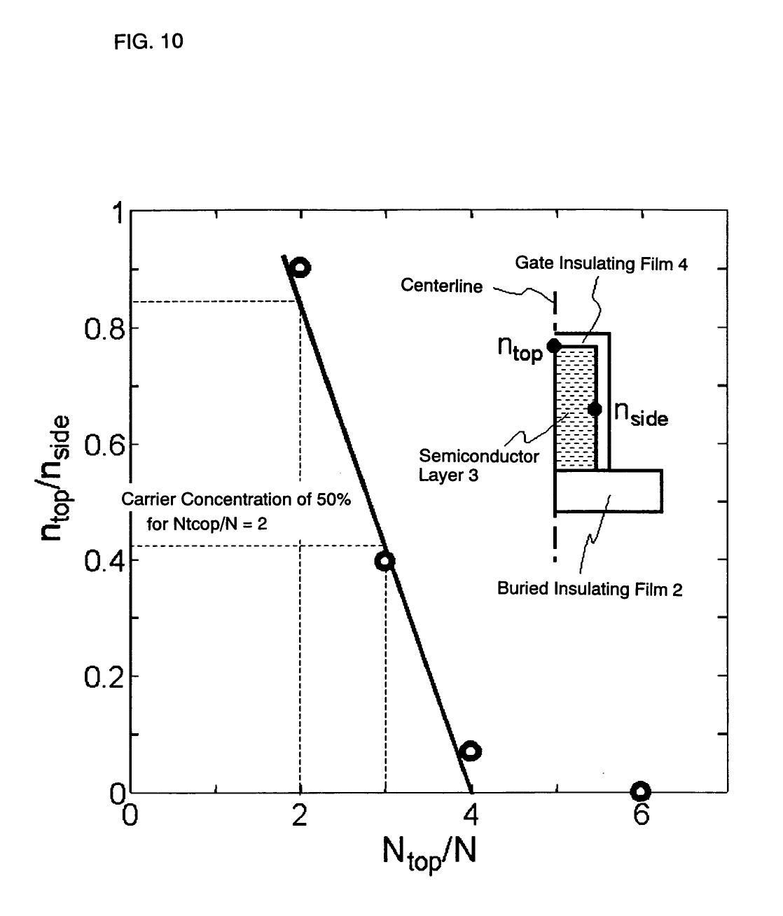

The results of calculating a ratio of the electron concentration of a channel formed on the upper surface of the semiconductor layer to the electron concentration of a channel formed on the side surface of the semiconductor layer are shown in FIG. 10. The abscissa represents Ntop/N and the ordinate represents ntop/nside. Here, ntop denotes the concentration of electrons as a channel carrier in the upper surface of the semiconductor layer and nside denotes the concentration of electrons as a channel carrier in the side surface of the semiconductor layer. ntop is a value at a position of the center in the Fin width direction (lateral direction in the section in FIG. 3(a)), and nside is a value at a position of the center in a direction vertical to the plane of the substrate (vertical direction in the section in FIG. 3(a)). When the result of FIG. 10 is extrapolated, the electron concentration of the upper surface of the semiconductor layer becomes substantially 0 when Ntop/N exceeds 4. That is, a channel is no longer formed on the upper surface of the semiconductor layer. When Ntop/N is limited to 4 or less, a channel is formed on the upper surface of the semiconductor layer; the condition of Ntop/N of 4 or less coincides with the upper limit of a range where the effect of increasing the on-current accounts for 50% or more in FIG. 9. When Ntop/N is substantially 3 or less, carriers accounting for 50% or more are induced to the upper surface of the semiconductor layer for ntop for Ntop/N=2 as a condition under which the on-current becomes maximum (see FIG. 9). This condition coincides with the upper limit of a range where the effect of increasing the on-current accounts for 75% or more in FIG. 9.

Here, Ntop is determined at a position of the center in the Fin width direction (Wfin direction) on the upper surface of the semiconductor layer, but this position is a position in which a channel becomes hardest to be formed when the impurity concentration in the upper part of the semiconductor layer is increased, and therefore if a condition under which the channel is formed in this position is used, channels are formed on the entire upper surface and side surface of the channel impurity concentration adjusting region. Here, the text “channels are formed on the upper surface and the side surface” means that channel carriers are induced to an area of a certain depth of the semiconductor layer facing the upper surface and the side surface.

Thus, for inducing channel carriers to the upper surface of the semiconductor layer so that the semiconductor upper surface functions as a channel, Ntop/N is preferably 4 or less. For inducing sufficient channel carriers to the upper surface of the semiconductor layer so that the semiconductor upper layer operates sufficiently as a channel, Ntop/N is preferably 3 or less.

In the element structure described in Patent Document 1, the channel is not formed in a p⁺ region 20 of the upper end portion of the semiconductor layer, and therefore it is conceivable that the channel is neither formed on the upper surface of the p⁺ region 20 (upper surface 23 of the semiconductor layer in FIG. 39) nor formed on the side surface of the p⁺ region 20 (upper side surface 24 of the semiconductor layer in FIG. 39). If the aforementioned condition (Ntop/N of 4 or less, more typically 3 or less) under which the channel is formed on the upper surface of the semiconductor layer is used, the channel is formed on the upper side surface 24 of the semiconductor layer. Thus, an effect of increasing the on-current accordingly as the channel is formed on the upper side surface 24 of the semiconductor layer can be obtained.

In the conventional technique in which the parasitic transistor of the upper corner portion is inhibited by means of merely providing the p⁺ region 20 in the upper end portion of the semiconductor layer, a depleted layer does not extend throughout a portion of the semiconductor upper end portion where the impurity concentration is high, and a neutral region is formed in the portion of the semiconductor upper end portion where the impurity concentration is high. In the FinFET, it is desirable to satisfy the condition that the semiconductor layer is fully depleted and no neutral region is formed in the semiconductor layer at least in a state in which the transistor is ON (state in which a voltage equal to or greater than a threshold voltage is applied to the gate electrode) (when this condition is satisfied, the field effect transistor is called a full depletion field effect transistor). Generally, however, if the concentration of an impurity introduced into the semiconductor layer increases, the neutral region is more easily formed. On the other hand, if the condition describe in this embodiment is followed, the channel impurity concentration adjusting region can be formed on the upper part of the semiconductor layer with a depth and impurity concentration just necessary for inhibition of the parasitic transistor, and therefore a situation in which a larger amount of impurity than is necessary is introduced into the upper part of the semiconductor layer is prevented to facilitate depletion of the entire semiconductor layer. When the neutral region is formed, an abnormal operation called a substrate floatation effect in which excessive carriers are accumulated in the semiconductor layer so that the current varies tends to occur, but according to the present invention, the parasitic transistor can be inhibited and at the same time, the transistor can be operated in a fully depleted state, thus making it possible to prevent this problem. In the subthreshold, by operating the transistor in a fully depleted state, an S factor (variation in gate voltage required for changing the drain current by an order of magnitude) can be reduced to make on-off transition steep.

FIG. 10 shows results in a state applying an on-voltage to the gate electrode. Here, calculation is performed for the n-channel transistor, and therefore application of an on-voltage refers to a state of applying a power supply voltage to the gate. For the p-channel transistor, application of an on-voltage refers to a state of applying an earth voltage to the gate in a state of applying a power supply voltage to the source. In the case of a digital circuit having a plurality of power supply voltages, application of an on-voltage refers to a case where an H level (high level) of voltage is applied to the gate for the n-channel transistor, and refers to a case where an L level (low level) of voltage is applied to the gate for the p-channel transistor. In the case of an analog circuit, application of an on-voltage refers to a state of applying a maximum level of signal to the gate of the transistor. In the present invention, channels are formed on the upper side surface 24 of the semiconductor layer and the upper surface 23 of the semiconductor layer in a state of applying an on-current to the gate electrode, and therefore a high on-current is obtained.

### Second Embodiment

[Structure]

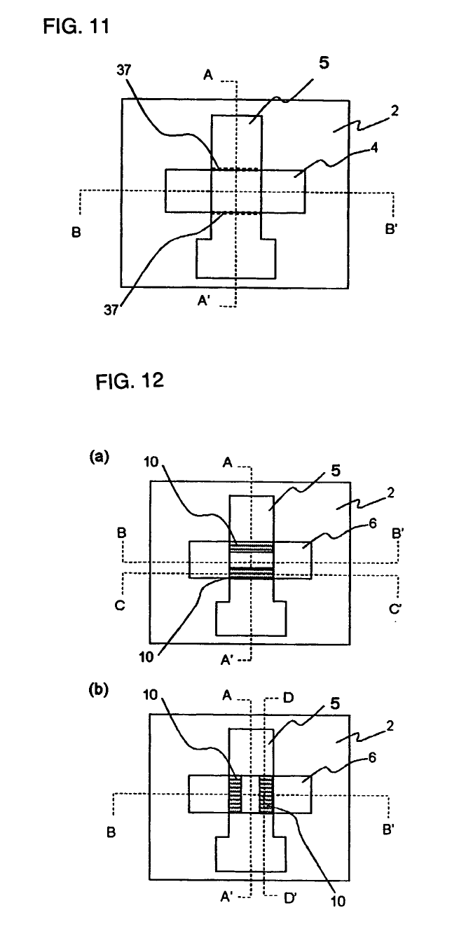

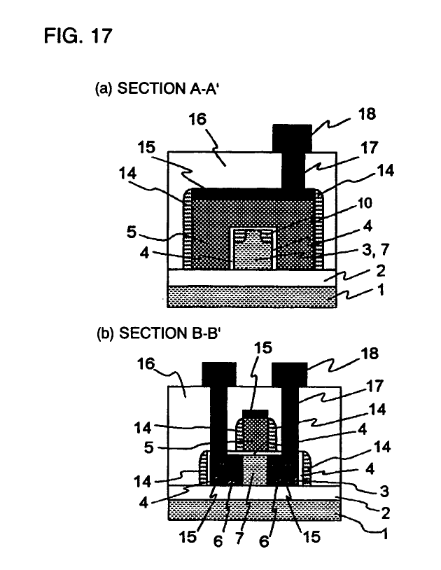

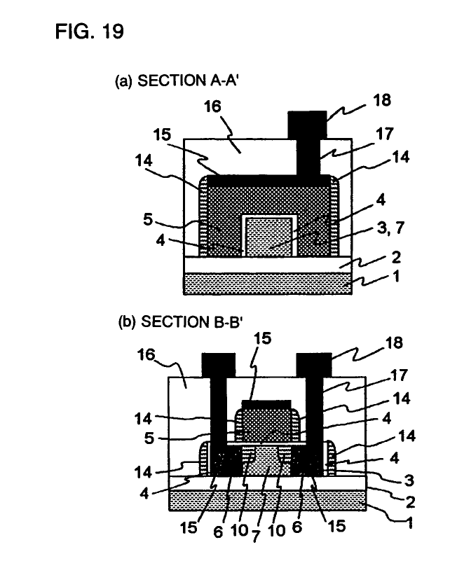

In the second embodiment, a region having a high impurity concentration is provided only in a part of the upper end portion of the semiconductor layer. This embodiment will be described with reference to FIG. 11, FIGS. 12(a) and 12(b), FIG. 13, FIGS. 17(a) and 17(b), FIGS. 19(a) and 19(b), FIGS. 81(a) and 81(b) and FIGS. 82(a) and 82(b). FIG. 11, FIGS. 12(a) and 12(b), FIG. 13, FIGS. 81(a) and 81(b) and FIGS. 82(a) and 82(b) are plan views corresponding to the plan view of FIG. 31 showing an example of a conventional technique. However, for the sake of convenience of explanations, a channel impurity concentration adjusting region 10 and a region 37 near an upper corner portion representing a part of semiconductor layer 3 covered with a gate electrode are depicted perspectively. FIG. 17(a) and FIG. 19(a) are sectional views in a position corresponding to the section A-A′ in FIG. 31 which is a plan view showing an example of a conventional technique. FIG. 17(b) and FIG. 19(b) are sectional views in a position corresponding to the section B-B′ in FIG. 31 which is a plan view showing an example of a conventional technique.

In this embodiment, a semiconductor layer 3 projecting upward from a substrate is provided, a gate electrode 5 is provided on the side surface of the semiconductor layer via a gate insulating film 4. The gate electrode 5 is patterned in an appropriate dimension, and source/drain regions 6 where a first conductivity type impurity is introduced in a high concentration are formed on the semiconductor layer in a position at which the semiconductor layer is not covered with the gate electrode. On a channel forming region 7 representing the semiconductor layer covered with the gate electrode 5, a channel composed of a first conductivity type carrier is formed by applying an appropriate voltage to the gate electrode 5. An interconnect 18 is connected to the gate electrode 5 or the source/drain region 6 via a contact 17.

A second conductivity type impurity of which the concentration is higher than that in the semiconductor layer 3 excepting a channel impurity concentration adjusting region 10 is introduced into the channel impurity concentration adjusting region 10 provided over a certain area (depth Htop) extending from the upper end of the semiconductor layer 3 forming the channel forming region 7. In the second embodiment, the channel impurity concentration adjusting region 10 may be formed on a part of the semiconductor layer including an upper corner portion. In the plan view of FIG. 11, the position (symbol 37) shown by two bold broken lines corresponds to two upper corner portions of the semiconductor layer 3, and the channel impurity concentration adjusting region 10 may be provided only in a part including at least a part of the region shown by these two broken lines.

FIG. 12(a) and FIGS. 17(a) and 17(b) show one example of the second embodiment, where the channel impurity concentration adjusting region 10 is provided only in and near the upper corner portion of the semiconductor layer 3 in the upper end portion of the semiconductor layer 3, and no channel impurity concentration adjusting region 10 is provided at a position distant from the upper corner portion although the position is included in the upper end of the semiconductor layer.

FIG. 12(b) and FIGS. 19(a) and 19(b) show a configuration in which the channel impurity concentration adjusting region 10 is provided only in a region of the upper end portion of the semiconductor layer contacting source/drain regions, and the channel concentration adjusting region 10 is provided in a certain region of the upper corner portion contacting the source/drain regions, but no channel impurity concentration adjusting region 10 is provided in a region of the upper corner portion distant from the source/drain regions.

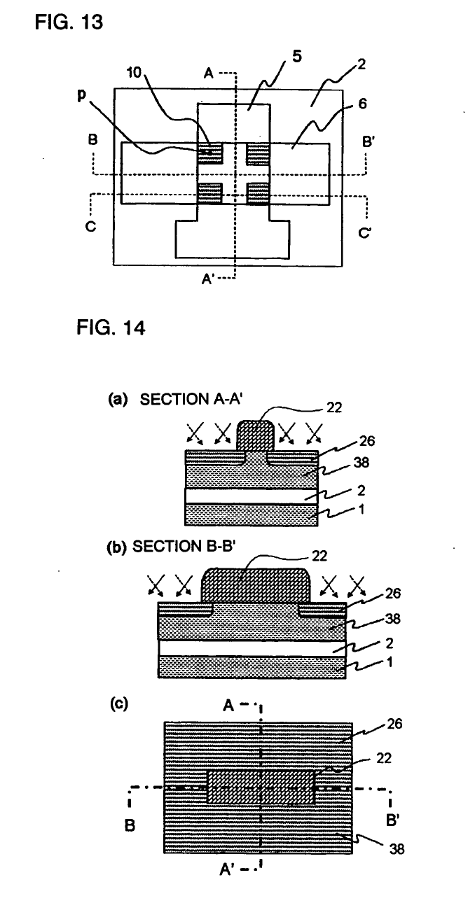

FIG. 13 shows a case where the channel impurity concentration adjusting region 10 is provided only in and near the upper corner portion of the upper end portion of the semiconductor layer contacting the source/drain regions.

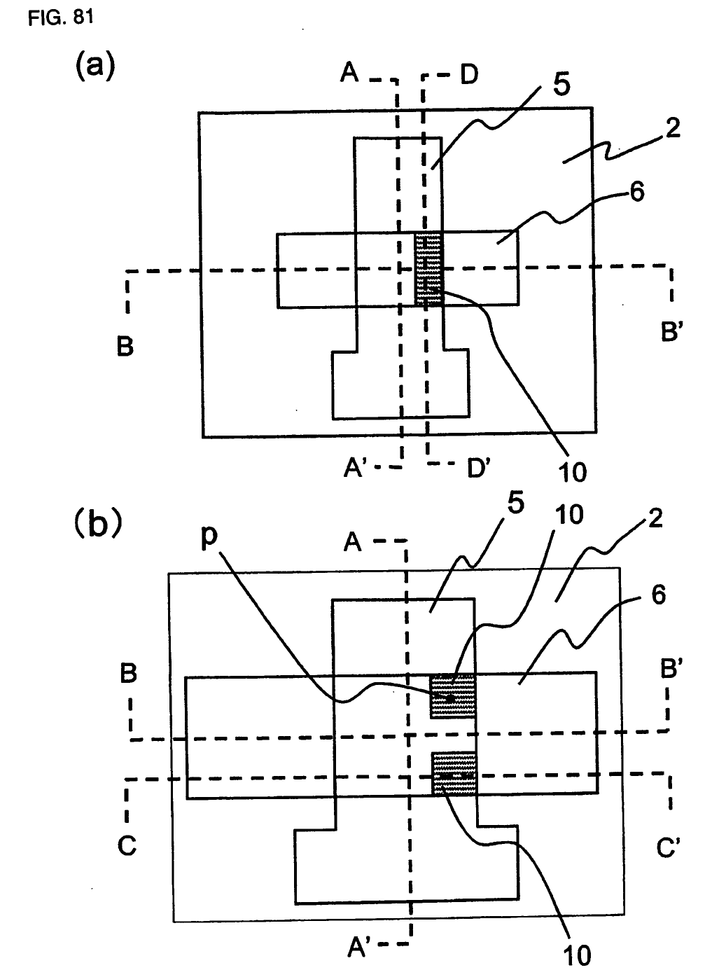

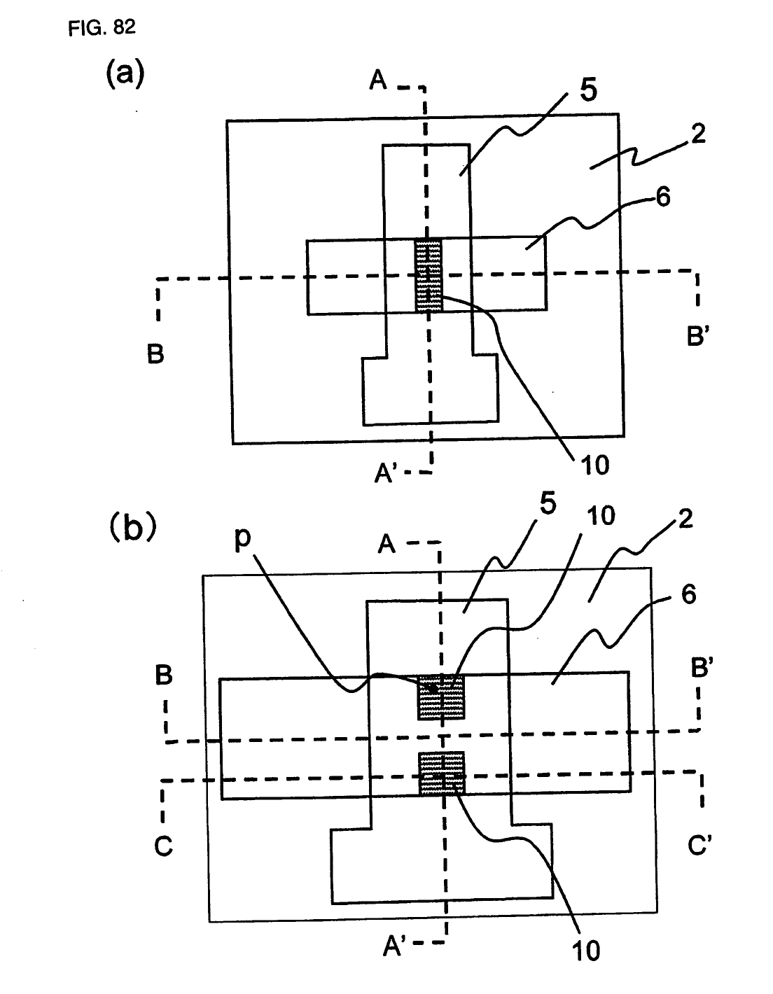

FIGS. 81(a) and 81(b) show a case where the channel impurity concentration adjusting region 10 is provided to contact only one of source/drain regions in the configuration shown in FIG. 12(b) and FIG. 13, respectively. FIGS. 82(a) and 82(b) shows a case where the channel impurity concentration adjusting region 10 is provided in a position distant from two source/drain regions, FIG. 82(a) shows a case where the channel impurity concentration adjusting region 10 is provided so as to connect two upper corner portions together, and FIG. 82(b) shows a case where the channel impurity concentration adjusting region 10 is provided only in and near the upper corner portion.

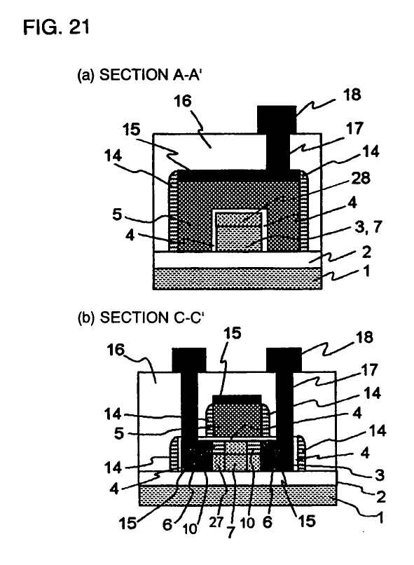

FIGS. 21(a) and 21(b) show a case where in a transistor in which a hollow region is formed, the channel impurity concentration adjusting region 10 having an especially high impurity concentration is formed in and near the upper corner portion contacting the source/drain regions (position shown in FIG. 13).

The hollow region refers to a region provided in a part of a channel region of a second conductivity type contacting the source/drain regions (or region called an extension where the source/drain regions are extended into the channel region), wherein the concentration of the second conductivity type impurity is higher than that in the channel region excepting the hollow region. A general purpose for providing the hollow region is to improve a short channel effect (variation in threshold voltage in a short channel transistor).

In the second embodiment, the ratio of the average value of the net concentration of the second conductivity type impurity in the area extending from the upper end of the semiconductor layer 3 to the depth Htop in the channel forming region of a second conductivity type to the average value of the net concentration of the second conductivity type impurity in the semiconductor layer excepting the area extending from the upper end of the semiconductor layer 3 is set to be in a range same as the range for the ratio of Ntop to N in the first embodiment.

In the second embodiment, the ratio of the average value of the net concentration of the second conductivity type impurity in the area extending from the upper end of the semiconductor layer 3 to the depth Htop in the channel forming region of a second conductivity type to the average value of the net concentration of the second conductivity type impurity in the semiconductor layer excepting the area extending from the upper end of the semiconductor layer 3 may be set according to a criterion different from the criterion in the first embodiment as described later.

The range of Htop applied in the second embodiment is set to a range same as the range of Htop in the first embodiment.

The definition of Htop in the second embodiment follows the definition described in the first embodiment. However, when the concentration of the channel impurity concentration adjusting region is set based on the rule for Ntop1 described later, Htop is determined according to the descriptions of the first embodiment based on the distribution of the net concentration of the second conductivity type impurity on a line for evaluation of Ntop1. When the concentration of the channel impurity concentration adjusting region is set based on the rule for Ntop2 described later, Htop is determined according to the descriptions of the first embodiment based on the distribution of the average value of the net concentration of the second conductivity type impurity at each depth in a plane for evaluation of Ntop2.

The net concentration of the second conductivity type impurity on the ordinate is an average value of the net concentration of the second conductivity type impurity in a section parallel to the plane of the substrate in the channel forming region of a second conductivity type in each position of the depth direction.

Generally, in the second embodiment, the impurity concentration of the channel impurity concentration adjusting region 10 may be higher than that for the first embodiment.

In the second embodiment, a region provided with no channel impurity concentration adjusting region 10 is locally formed on a part of the upper surface of the semiconductor layer or the upper side surface of the semiconductor layer, and this region becomes a path for a channel current (particularly, structure in FIG. 12(a) and FIG. 13), and therefore even if the impurity concentration of the channel impurity concentration adjusting region 10 is so high that a channel is hard to be formed on the channel impurity concentration adjusting region 10, a channel path is locally formed on a part of the upper surface of the semiconductor layer or the upper side surface of the semiconductor layer, and therefore a high drain current is obtained as compared to, for example, the conventional technique in Patent Document 1. However, in this case, the depth of the channel impurity concentration adjusting region 10 is preferably in a range similar to the range for the first embodiment.

In the second embodiment, a channel is more preferably formed on the channel impurity concentration adjusting region 10 because the drain current increases as compared to a case where no channel is formed on the channel impurity concentration adjusting region 10. For a channel to be formed on the channel impurity concentration adjusting region 10, in the second embodiment, the depth and the impurity concentration of the channel impurity concentration adjusting region 10 are set so as to satisfy the condition for the channel impurity concentration adjusting region 10 in the first embodiment described above.

That is, in the second embodiment, most preferably, the average value of the net concentration of the second conductivity type impurity in an area extending from the upper end to the depth Htop in the channel forming region of a second conductivity type is set typically to be in a range from 1.3 times to 4 times as large as the average value of the net concentration of the second conductivity impurity in a region other than the area extending from the upper end to the depth Htop in the channel forming region of a second conductivity type as in the first embodiment. More typically, the average value of the net concentration of the second conductivity type impurity in an area extending from the upper end to the depth Htop in the channel forming region of a second conductivity type is set typically to be in a range from 1.5 times to 3 times as large as the average value of the net concentration of the second conductivity impurity in a region other than the area extending from the upper end to the depth Htop in the channel forming region of a second conductivity type. However, in the second embodiment, Ntop may be set to be 4 times or more as large as N. This is because in the second embodiment, a region of which the concentration of the second conductivity type impurity is low is locally provided in a part of the upper surface or the upper side surface of the semiconductor layer, and therefore even if Ntop is set to be 4 times or more as large as N, a constant channel current can be passed through the upper surface or the upper side surface of the semiconductor layer.

In the second embodiment, Ntop may be set to be 1.3 times or less as large as N if Ntop is higher than N. This is because in the second embodiment, the channel impurity concentration adjusting region of which the concentration of the second conductivity type impurity is high is locally provided in a part of the upper surface or the upper side surface of the semiconductor layer, and therefore an average value for the entire channel forming region to a certain depth (Htop in the first embodiment) may be below the range of Ntop defined in the first embodiment. As a typically lower limit, if considering the configuration in FIG. 13, the volume of the channel impurity concentration adjusting region 10 is 4/9, and thus the lower limit of Ntop is 1.13 times, i.e. a value obtained by subtracting 1 from 1.3, multiplying the resulting difference by 4/9 and adding 1 to the resulting product.

In the second embodiment, the impurity concentration in the locally provided channel impurity concentration adjusting region 10, rather than the average of the impurity concentration for the entire semiconductor layer to a certain depth, influences the operation, and therefore for forming a sufficient channel in the channel impurity concentration adjusting region 10 and obtaining an action of inhibiting the parasitic transistor of the upper corner portion as in the first embodiment, as the most preferred form of the second embodiment, Ntop1 or Ntop2 described below preferably satisfies the condition defined for Ntop in the first embodiment for the impurity concentration of the channel impurity concentration adjusting region 10.

In the second embodiment, the impurity concentration of the channel impurity concentration adjusting region 10 may be defined by an average value Ntop2 of the net concentration of the second conductivity type impurity in the area of the channel forming region extending from the upper end to the depth Htop in a section (e.g. section C-C′ in FIG. 12(a), section D-D′ in FIG. 12(b)) including the channel impurity concentration adjusting region 10, instead of defining the impurity concentration of the channel impurity concentration adjusting region 10 by the average value Ntop of the net concentration of the second conductivity type impurity in the area extending from the upper end to the depth Htop in the channel forming region of a second conductivity type. In this case, Ntop2 is set to be in a range from 1.3 times to 4 times, more typically from 1.5 times to 3 times as large as N.

The impurity concentration of the channel impurity concentration adjusting region 10 may be defined by an average value Ntop1 of the net concentration of the second conductivity type impurity in the area of the channel forming region extending from the upper end to the depth Htop in a distribution in the depth direction at a point p included in the channel impurity concentration adjusting region 10 (e.g. distribution from the upper end surface to the lower end surface of the semiconductor layer at the point p in FIG. 13). In this case, if Ntop is in a range from 1.3 times to 4 times, more typically from 1.5 times to 3 times as large as N, an effect that is effective from a practical standpoint is obtained.

The condition for Ntop1 or Ntop2 described above is preferably satisfied over a length of 10 nm or more in the longitudinal direction of the channel for one channel impurity concentration adjusting region 10.

In the configuration in which the condition for Ntop1 or Ntop2 described above is satisfied, it is not necessary that the average value Ntop of the net concentration of the second conductivity type impurity in the area extending from the upper end to the depth Htop in the channel region of a second conductivity type should satisfy defined condition. For example, Ntop may be set to be 1.3 times or less as large as N.

In the configuration in which the condition for Ntop1 described above is satisfied, it is not necessary for Ntop2 to satisfy the defined condition. For example, Ntop2 may be set to be 1.3 times or less as large as N.

The characteristic of the electric potential difference such as Vside and Vcorner and the characteristic of the impurity concentration in the channel forming region in a transistor of which characteristics are to be improved by application of this embodiment and the transistor of this embodiment are same as those of the first embodiment.

That is, the impurity concentration of the channel impurity concentration adjusting region is set to satisfy a relationship between Ntop and N, which can reduce an increase in electric potential in the upper corner portion of the semiconductor layer, as compared to a case where no channel impurity concentration adjusting region is provided. At this time, the amount of reduction of an increase in electric potential in the upper corner portion of the semiconductor layer is preferably 60 mV or more typically in at least a part of the upper corner portion of the semiconductor layer.

The present invention is typically applied for improving the characteristic of the transistor in which the electric potential increases by 60 mV or more in at least part of the upper corner portion of the semiconductor layer when no channel impurity concentration region is provided. The present invention is typically applied for improving the characteristic of the transistor in which Vside is 120 mV or more when no channel impurity concentration adjusting region is provided.

The transistor of this embodiment has a characteristic in which Vside is typically 120 mV or more. The process for determining pside, pcorner, pcenter, Vcorner and Vside is same as that in the first embodiment. However, pside of this embodiment is selected from a region provided at any position in the channel forming region below the lower end of the channel impurity concentration adjusting region, irrespective of whether or not the channel impurity concentration adjusting region is provided just above pside.

In this connection, pside, pcorner, pcenter, Vcorner and Vside have been discussed above taking an n-channel transistor as an example, but for a p-channel transistor, the polarity is reversed.

The present invention is typically applied for improving the performance of the transistor in which the average value of the impurity concentration in the semiconductor layer is 7.5×10¹⁷ cm⁻³ or more when no channel impurity concentration adjusting region is provided, and therefore in the transistor of this embodiment, the average value of the net concentration of the second conductivity type impurity in the channel forming region of a second conductivity type excepting the channel impurity concentration adjusting region is typically 7.5×10¹⁷ cm⁻³ or more.

For a transistor with a short channel (gate length is typically 0.1 μm or less), the present invention is typically applied for improving the performance of the transistor in which the average value of the impurity concentration in the semiconductor layer is 1.0×10¹⁸ cm⁻³ or more when no channel impurity concentration adjusting region is provided, and in the transistor of this embodiment with a short channel, the average value of the net concentration of the second conductivity type impurity in the channel forming region of a second conductivity type excepting the channel impurity concentration adjusting region is typically 1.0×10¹⁸ cm⁻³ or more.

[Production Method]

### First Production Method of Second Embodiment

The first production method of the second embodiment is a method for forming a configuration in which a channel impurity concentration adjusting region 10 is provided in the vicinity of the upper corner portion of the semiconductor layer, and no channel impurity concentration adjusting region 10 is provided in a region distant from the upper corner portion although the region is included in the upper end portion of the semiconductor layer (FIG. 12(a)).

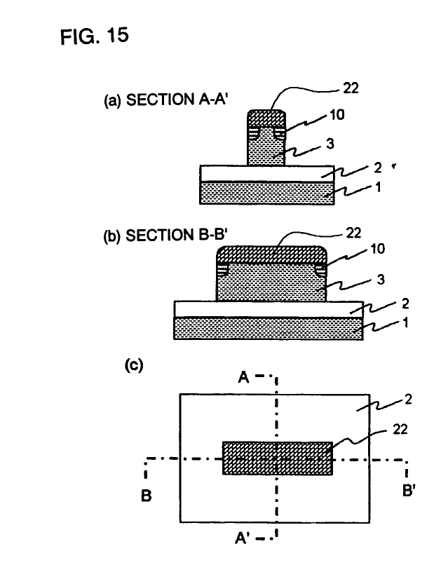

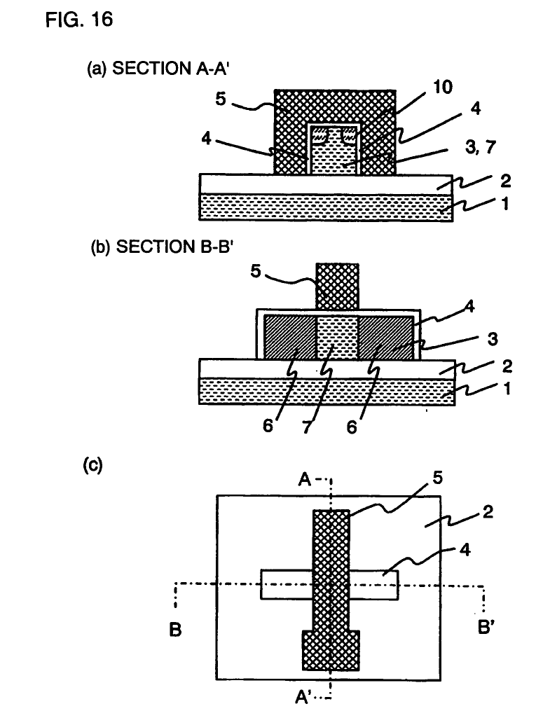

The first production method of the second embodiment will be described with reference to FIGS. 14(a), 14(b) and 14(c), FIGS. 15(a), 15(b) and 15(c), FIGS. 16(a), 16(b) and 16(c) and FIGS. 17(a) and 17(b). FIG. 14(a), FIG. 15(a) and FIG. 16(a) are sectional views in sections A-A′ in FIG. 14(c), FIG. 15(c) and FIG. 16(c) which are plan views, respectively, and depict the shape of a section in a position corresponding to the section A-A′ in FIG. 31 which is a plan view showing an example of a conventional technique on a step-by-step basis.

FIGS. 14(b), 15(b) and 16(b) are sectional views in sections B-B′ of FIGS. 14(c), 15(c) and 16(c) which are plan views, respectively, and depict the shape of a section in a position corresponding to the section B-B′ in FIG. 31 which is a plan view showing an example of a conventional technique on a step-by-step basis.

For producing the field effect transistor of the second embodiment, a resist pattern 22 (resist pattern may be replaced by a mask pattern composed of an oxide film) for defining an element region is formed on a semiconductor layer 38, and a second conductivity type impurity for forming a channel impurity concentration adjusting region 10 is introduced by slanting ion implantation using the resist pattern 22 as a mask. In this way, the second conductivity type impurity is introduced into the upper part of a region near the end portion of a resist in a region of the semiconductor layer 38 covered with the resist (symbol 26 in FIGS. 14(a), 14(b) and 14(c) denote a region where the second conductivity type impurity is introduced). Next, an element region having a semiconductor layer 3 projecting from a substrate is formed by patterning by an etching step such as RIE using the resist pattern 22 as a mask. In this way, the channel impurity concentration adjusting region 10 which is a region where the second conductivity type impurity is higher than that in other regions of the semiconductor layer is formed in the upper corner portion of the semiconductor layer 3 (FIGS. 15(a), 15(b) and 15(c)).

The resist pattern 22 is removed, a gate insulating film 4 is then formed on the side surface of the semiconductor 3, a gate electrode material is deposited, the gate electrode material is then patterned by RIE (reactive ion etching) or the like to form a gate electrode 5, and a high-concentration first conductivity type impurity is introduced into a region of the semiconductor layer 3 which is not covered with gate electrode 5, whereby source/drain regions 6 are formed (FIGS. 16(a), 16(b) and 16(c)). Thereafter, an interlayer insulating film is deposited, and a contact 17 and an interconnect 18 are formed for the source/drain regions 6 and the gate electrode 5 by a normal method (FIGS. 17(a) and 17(b), the form of the plan view is same as that of FIG. 5).

The depth and the impurity concentration of the channel impurity concentration adjusting region 10 are set so as to satisfy the structural characteristic of the second embodiment described above.

### Example of First Production Method of Second Embodiment

A specific example of the first production method of the second embodiment will be described as a supplementary explanation.

In the specific example, in an SOI substrate prepared by, for example, laminating a buried insulating layer 2 composed of an insulating material such as SiO₂ on a support substrate 1 composed of silicon and further laminating thereon a semiconductor layer 38 composed of monocrystalline silicon, a resist pattern 22 for defining an element region is provided by a normal lithography step (FIGS. 14(a), 14(b) and 14(c)).

For a step of forming a gate side wall 14, an interlayer insulating film 16, a contact 17, an interconnect 18 and the like after forming a gate electrode 5, a step same as that of the first production method of the first embodiment or the second production method of the first embodiment is used.

### Second Production Method of Second Embodiment

The second production method of the second embodiment is a method for forming a configuration in which a channel impurity concentration adjusting region 10 is provided so as to include a part of the upper corner portion, only in the vicinity of a portion of the upper end of a channel forming region 7 contacting source/drain regions 6, and no channel impurity concentration adjusting region 10 is provided in a region distant from the source/drain regions 6 although the region is included in the upper end portion of the semiconductor layer (FIG. 12(b)).

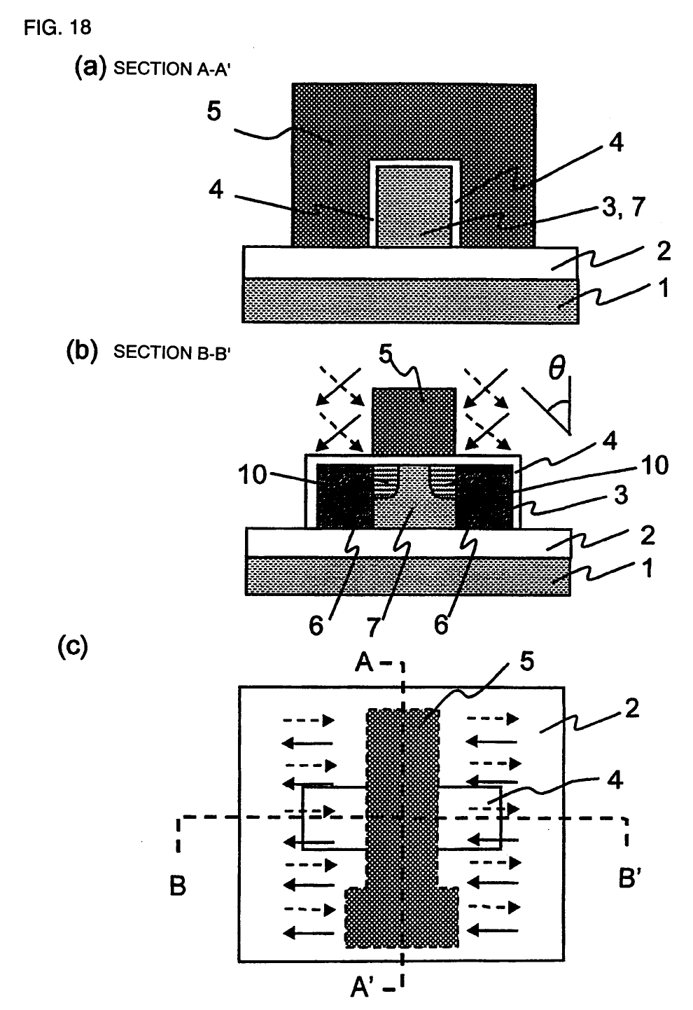

The second production method of the second embodiment will be described with reference to FIGS. 18(a), 18(b) and 18(c) and FIGS. 19(a) and 19(b). FIG. 18(a) and FIG. 19(a) are sectional views in sections A-A′ in FIG. 18(c) and FIG. 19(c) which are plan views, respectively, and depict the shape of a section in a position corresponding to the section A-A′ in FIG. 31 which is a plan view showing an example of a conventional technique on a step-by-step basis, FIG. 18(b) and FIG. 19(b) are sectional views in sections B-B′ in FIG. 18(c) and FIG. 19(c) which are plan views, respectively, and depict the shape of a section in a position corresponding to the section B-B′ in FIG. 31 which is a plan view showing an example of a conventional technique on a step-by-step basis, and FIGS. 18(a), 18(b) and 18(c) and FIGS. 19(a) and 19(b) are views corresponding to FIGS. 8(a), 8(b) and 8(c) and FIGS. 4(a) and 4(b) in the second production method of the first embodiment, respectively.

The second production method of the second embodiment is a method in which in the second production method of the first embodiment, the step of carrying out slanting ion implantation using a gate electrode as a mask to form on the upper part of a semiconductor layer 3 a channel impurity concentration adjusting region 10 of which the concentration of a second conductivity type impurity is higher than that in other regions of the semiconductor layer 3 is modified, and the production method excluding this step is all same as the second production method of the first embodiment.

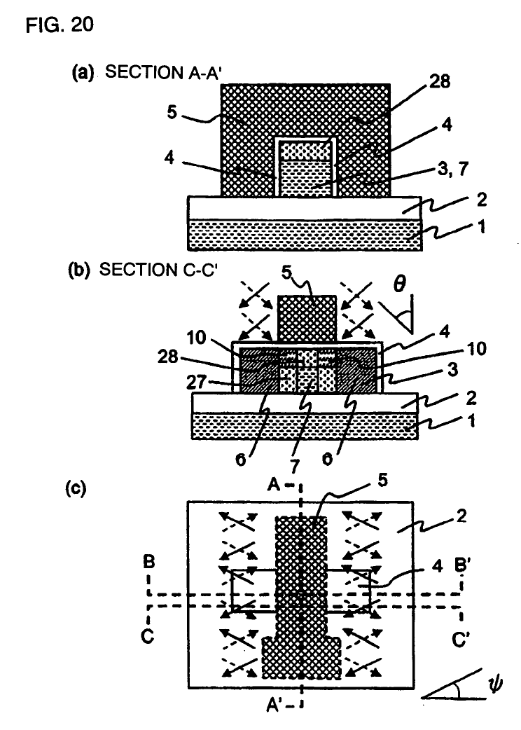

FIGS. 18(a), 18(b) and 18(c) show a case where slanting ion implantation is carried out parallel to a plane vertical to the plane of a substrate and parallel to the longitudinal direction of a channel. Slanting ion implantation is most preferably carried out parallel to a plane vertical to the plane of the substrate and parallel to the longitudinal direction of the channel in terms of formation of the channel impurity concentration adjusting region 10 on the upper part of the semiconductor layer 3 as in the second production method of the first embodiment. If an angle (angle V in FIG. 20(c)) with respect to a plane vertical to the plane of the substrate and parallel to the longitudinal direction of the channel is 10 degrees or less, although slanting ion implantation is not carried out parallel to the plane, a capability of forming a hollow region is low, and therefore when the main purpose is to form the channel impurity concentration adjusting region 10 on the upper part of the semiconductor layer 3, the angle with respect to a plane vertical to the plane of the substrate and the parallel to the longitudinal direction of the channel is preferably 10 degrees or less.

If slanting ion implanting is carried out only from one side (only at an angle −θ in FIG. 18(b); only in the direction of the arrow of a solid line in FIG. 18(c)), the configuration of FIG. 81(b) is obtained.

The configuration of FIG. 82(a) is obtained when a step of slantingly ion-implanting a first conductivity type impurity under the aforementioned condition is added to each production method of the first embodiment and a second conductivity type impurity near source/drain regions is compensated, and the configuration of FIG. 82(b) is obtained when a step of slantingly ion-implanting the first conductivity type impurity under the aforementioned condition is added to the first production method of the second embodiment and the second conductivity type impurity near source/drain regions is compensated.

In the second production method of the second embodiment, channel impurity concentration adjusting regions 10 are formed by implanting ions from opposite sides of the gate electrode so as not to contact each other when slanting ion implantation is carried out using a gate electrode as a mask.

For example, ion implantation is carried out with energy lower than that in the second production method of the first embodiment. Alternatively, ions heavier than those in the second production method of the first embodiment are implanted. Alternatively, for example, the transistor of the second embodiment is formed when the second production method of the first embodiment is applied to a transistor having a long gate length.

For this production method, a displacement gate process may be applied as in the second production method of the first embodiment.

### Third Production Method of Second Embodiment

The third production method of the second embodiment is a method for a configuration in which a channel impurity concentration adjusting region 10 is provided in the vicinity of a portion where the upper corner portion of a semiconductor layer 3 contacts source/drain regions 6, and no channel impurity concentration adjusting region 10 is provided in a region distant from the source/drain regions 6 and a region distant from the upper corner portion although those regions are included in the upper end portion of the semiconductor layer (FIG. 13), and also a method for forming a transistor having a hollow region in a channel forming region.

The third production method of the second embodiment will be described with reference to FIGS. 20(a), 20(b) and 20(c) and FIGS. 21(a) and 21(b). FIG. 20(a) is a sectional view in the section A-A′ in FIG. 20(c) which is a plan view, and depicts the shape of a section in a position corresponding to the section A-A′ in FIG. 31 which is a plan view showing an example of a conventional technique. FIG. 20(b) is a sectional view in the section C-C′ in FIG. 20(c) which is a plan view, and depicts the shape of a section in a position corresponding to the section C-C′ in FIG. 31 which is a plan view showing an example of a conventional technique. FIGS. 21(a) and 21(b) are sectional views when the step progresses, in sections in FIGS. 20(a) and 20(b), respectively. FIGS. 20(a), 20(b) and 20(c) and FIGS. 21(a) and 21(b) are views corresponding to FIGS. 8(a), 8(b) and 8(c) and FIGS. 4(a) and 4(b) in the second production method of the first embodiment, respectively. Symbol 27 denotes a hollow region.

The third production method of the second embodiment is a method in which in the second production method of the first embodiment, the step of carrying out slanting ion implantation using a gate electrode as a mask to form on the upper part of a semiconductor layer 3 a channel impurity concentration adjusting region 10 of which the concentration of a second conductivity type impurity is higher than that in other regions of the semiconductor layer 3 is modified, and the production method excluding this step is all same as the second production method of the first embodiment.

In the third production method of the second embodiment, ion implantation is carried out with an angle (in FIG. 20(c), angles +ψ, −ψ, 180°+ψ, 180°−ψ with respect to a plane vertical to the plane of the substrate and parallel to the longitudinal direction of the channel) provided with respect to the longitudinal direction of a channel in the surface of a wafer when slanting ion implantation is carried out using a gate electrode as a mask. Consequently, the concentration of the second conductivity type impurity increases at every depth in the semiconductor layer 3 in a region situated near a gate insulating film of the semiconductor layer of the channel forming region and contacting source/drain regions. A typical magnitude of V is 20 to 70 degrees.

By providing an angle +θ, −θ in a plane perpendicular to the wafer (angle with respect to the vertical line of the plane of the substrate in a plane vertical to the plane of the substrate and parallel to the longitudinal direction of the channel), the impurity concentration in the upper end portion of the semiconductor layer 3 is increased.

If slanting ion implantation is carried out only from one side of a gate (only at an angle +ψ, −ψ in FIG. 20(c); only in the direction of the arrow of a solid line in the figure), the configuration of FIG. 81(b) is obtained.

Thus, in the third production method of the second embodiment, the impurity concentration is highest in a region of the upper end portion of the semiconductor layer 3 contacting both one of the upper corner portions and one of the source/drain regions, and therefore the channel impurity concentration adjusting region 10 is formed only in the region of the upper end portion of the semiconductor layer 3 contacting both one of the upper corner portions and one of the source/drain regions.

The “region 28 having a slightly high concentration” in the figure is a region that is formed according to a feature of this production method in terms of the step, and in the region, the net concentration of the second conductivity type impurity is lower than that in the channel impurity concentration adjusting region 10, but the net concentration of the second conductivity type is higher than that in the semiconductor layer 3 below the “region 28 having a slightly high concentration”.

Both of first slanting ion implantation which has an angle in a plane vertical to the wafer and is parallel to a plane vertical to the plane of the substrate and parallel to the longitudinal direction of the channel (ion implantation illustrated in FIGS. 18(a), 18(b) and 18(c)) and second slanting ion implantation having an angle in a plane vertical to the wafer and having an angle (ψ in FIG. 20(c)) with respect to a plane vertical to the plane of the substrate and parallel to the longitudinal direction of the channel (ion implantation illustrated in FIGS. 20(a), 20(b) and 20(c)) may be carried out. In this case, second ion plantation has a role of normal hollow ion implantation (inhibition of a short channel effect) and first ion implantation has a role of introducing into the upper part of the semiconductor layer an impurity sufficient for formation of a channel impurity concentration adjusting region capable of inhibiting parasitic transistor, thus being especially effective for formation of a FinFET with a short channel.

First slanting ion implantation which has an angle in a plane vertical to the wafer and is not parallel to a plane vertical to the plane of the substrate and parallel to the longitudinal direction of the channel and second slanting ion implantation having an angle in a plane vertical to the wafer and having an angle with respect to a plane vertical to the plane of the substrate and parallel to the longitudinal direction of the channel, with the angle greater than that of first slanting ion implantation, may be carried out. The case where first ion implantation has a role of introducing into the upper part of the semiconductor layer an impurity sufficient for formation of a channel impurity concentration adjusting region capable of inhibiting a parasitic transistor and second slanting ion implantation has a role of hollow ion implantation is same as the aforementioned case where first ion implantation is parallel to a plane vertical to the plane of the substrate and parallel to the longitudinal direction of the channel. In this case, an angle (ψ in FIG. 20(c)) with respect to a plane vertical to the plane of the substrate and parallel to the longitudinal direction of the channel in first slanting ion implantation is preferably 10 degrees or less in terms of formation of a channel impurity concentration adjusting region.

[Effect]

In the second embodiment, the channel impurity concentration adjusting region 10 is formed on at least a part of each of two corner portions (positions (symbol 37) shown by two bold broken lines in the plan view of FIG. 11) of the semiconductor layer in the upper part of the semiconductor layer 3. For inhibiting the parasitic transistor, a region having a high impurity concentration may be provided in at least a part of each of two upper corner portions of the semiconductor layer, and therefore in the second embodiment, occurrence of the parasitic transistor is inhibited to solve the first problem as in the first embodiment.

The feature of the field effect transistor of the second embodiment in terms of the action consists in that the channel impurity concentration adjusting region 10 is limited to minimum regions necessary for inhibition of the parasitic transistor, whereby regions where the impurity concentration is locally lower than that in the channel impurity concentration adjusting region 10 are formed on the upper surface of the semiconductor layer and the upper side surface of the semiconductor layer. In the region where the impurity concentration is locally low, the threshold locally low enough to induce a channel charge easily, and the mobility of channel carriers is improved, so that a region where the channel resistance is locally low is formed. That is, in the field effect transistor of the second embodiment, the channel impurity concentration adjusting region 10 is provided in minimum necessary regions, whereby a region having a low channel resistance is expanded and the drain current is increased.

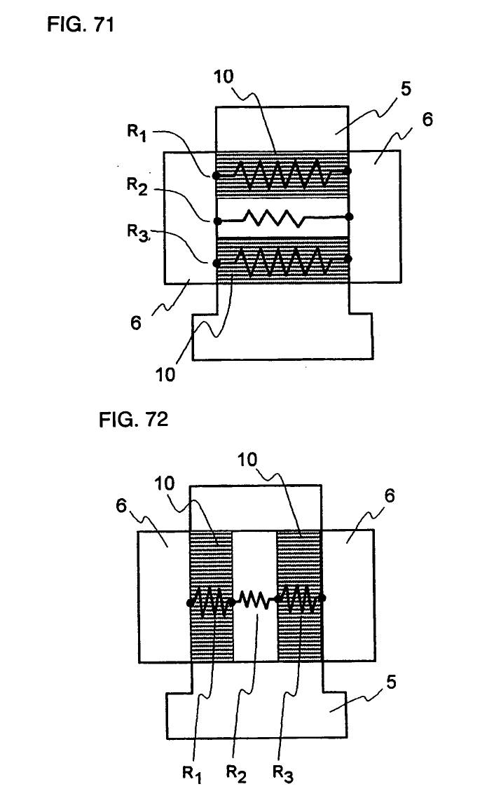

The action in the configuration of FIG. 12(a) will be described with reference to FIG. 71. FIG. 71 schematically depicts the upper surface part of the semiconductor layer in an enlarged scale in FIG. 12(a), and resistances R1 and R3 schematically show channel resistances in the channel impurity concentration adjusting region 10 and a resistance 2 schematically shows a channel resistance in a region where no channel impurity concentration adjusting region 10 is formed. The channel resistance R2 in the region where no channel impurity concentration adjusting region 10 is formed is lower than resistances R1 and R3 for the reason described above, and therefore the value of a synthetic resistance formed by connecting resistances R1, R2 and R3 in parallel decreases as compared to a case where the channel impurity concentration adjusting region 10 is formed on the entire upper surface of the semiconductor layer. As a result, the drain current increases as compared to a case where the channel impurity concentration adjusting region 10 is formed on the entire upper surface of the semiconductor layer.

The action in the configuration of FIG. 12(b) will be described with reference to FIG. 72. FIG. 72 schematically depicts the upper surface part of the semiconductor layer in an enlarged scale in FIG. 12(b), and resistances R1 and R3 schematically show channel resistances in the channel impurity concentration adjusting region 10 and a resistance 2 schematically shows a channel resistance in a region where no channel impurity concentration adjusting region 10 is formed. In this configuration, resistances R1, R2 and R3 are connected in series. The channel resistance R2 in the region where no channel impurity concentration adjusting region 10 is formed is lower than resistances R1 and R3 for the reason described previously, and therefore the value of a synthetic resistance formed by connecting resistances R1, R2 and R3 in series decreases as compared to a case where the channel impurity concentration adjusting region 10 is formed on the entire upper surface of the semiconductor layer. As a result, the drain current increases as compared to a case where the channel impurity concentration adjusting region 10 is formed on the entire upper surface of the semiconductor layer.

In the second embodiment, a channel is formed on a region of the upper end portion of the semiconductor layer where the channel impurity concentration adjusting region 10 having a high impurity concentration is not provided (e.g. near the upper end portion in the section B-B′ in FIG. 12(a) and FIG. 13), and therefore the area of the region where the channel is formed increases and the drain current increases as compared to the example of the conventional technique in Patent Document 1, so that the second problem is improved.

In the second embodiment, the concentration of the channel impurity concentration adjusting region 10 is most preferably controlled to the extent that the channel is formed on and near the channel impurity concentration adjusting region 10 (if the concentration in the channel impurity concentration adjusting region 10 is too high, no channel is formed not only on the channel impurity concentration adjusting region 10 but also near the channel impurity concentration adjusting region 10).

In the field effect transistor of the second embodiment, on checking with the result of simulation for the field effect transistor of the first embodiment in consideration of the fact that for the reason described previously, a channel is easily formed on the upper end portion of the semiconductor layer and a drain current equivalent or greater than that of the field effect transistor of the first embodiment is obtained, the depth and the impurity concentration of the channel impurity concentration of the channel impurity concentration adjusting region 10 are preferably set so as to satisfy the condition for the channel impurity concentration adjusting region 10 of the first embodiment, and if the condition for the field effect transistor is within the range of such a condition, a sufficient effect is obtained. For example, if the average value of the net concentration of the second conductivity type impurity in an area extending from the upper end of the semiconductor layer to the depth Htop in the channel impurity concentration adjusting region 10 is in a range from 1.5 times to 3 times as large as the average value of the net concentration of the second conductivity type impurity in the channel forming region excepting the area extending from the upper end of the semiconductor layer to the depth Htop in the channel impurity concentration adjusting region, a sufficient effect is obtained.

If the average value of the net concentration of the second conductivity type impurity in an area extending from the upper end to the depth Htop in the channel forming region of a second conductivity type is in a range from 1.3 times to 4 times as large as the average value of the net concentration of the second conductivity type impurity in the channel forming region of a second conductivity type excepting the area extending from the upper end to the depth Htop, an effect which is effective from a practical standpoint is obtained.

In the second embodiment, if the average value Ntop2 of the net concentration of the second conductivity type impurity in an area extending from the upper end to the depth Htop in a section (e.g. section C-C′ in FIG. 12(a), section D-D′ in FIG. 12(b)) including the channel impurity concentration adjusting region 10, rather than the average value Ntop of the net concentration of the second conductivity type impurity in the area extending from the upper end to the depth Htop in the channel forming region of a second conductivity type, is in a range from 1.5 times to 3 times as large as N, a sufficient effect is obtained. If Ntop2 is in a range from 1.3 times to 4 times as large as N, an effect which is effective from a practical standpoint is obtained.

If the average value Ntop1 of the net concentration of the second conductivity type impurity in an area extending from the upper end to the depth Htop in a distribution in the depth direction at a point p included in the channel impurity concentration adjusting region 10 (e.g. distribution from the upper end surface to the lower end surface of the semiconductor layer at the point p in FIG. 13) is in a range from 1.5 times to 3 times as large as N, a sufficient effect is obtained. If Ntop 1 is in a range from 1.3 times to 4 times as large as N, an effect which is effective from a practical standpoint is obtained.

However, if the length of the channel impurity concentration adjusting region 10 in the longitudinal direction of the channel (direction in which two source/drain regions are linked; e.g. B-B′ direction in FIG. 12(b) and B-B′ direction in FIG. 13) is too small, the action of inhibiting the parasitic transistor is weakened, and therefore the condition for Ntop1 or Ntop2 described above is preferably satisfied over a length of 10 nm or more in the longitudinal direction of the channel for one channel impurity concentration adjusting region 10.

In a configuration in which the condition for Ntop1 or Ntop2 described above is satisfied, an effect for solving the first problem is obtained even if the average value Ntop of the net concentration of the second conductivity type impurity in the area extending from the upper end of the semiconductor layer to the depth Htop in the channel region of a second conductivity type does not satisfy the specified condition (e.g. Ntop is 1.3 times or less as large as N).

In the transistor of the second embodiment, it is most preferable that no neutral region is formed in the semiconductor layer as in the first embodiment. As in the case of the first embodiment, if the condition described in this embodiment is followed, the channel impurity concentration adjusting region can be formed on the upper part of the semiconductor layer with a depth and an impurity concentration just necessary for inhibiting the parasitic transistor, and therefore a situation in which a larger amount of impurity than is necessary is introduced into the upper part of the semiconductor layer is prevented to facilitate depletion of the entire semiconductor layer.

This configuration and effect in the first embodiment or the second embodiment for depletion of the entire semiconductor layer are the same in each embodiment described later in which the channel impurity concentration adjusting region is formed under the condition described in the first embodiment or the second embodiment.

A preferable range of the depth Htop of the channel impurity concentration adjusting region defining Ntop, Ntop1 and Ntop2 is same as that in the first embodiment. Htop is typically 5 nm to 24.5 nm. In view of the tradeoff between ease in the production method (production becomes easier as Htop increases in terms of production) and the effect, Htop is preferably in a range from 10 nm to 20 nm, and the most typical value of Htop is 10 nm. The preferable value of Htop is the same in each embodiment described later in which the channel impurity concentration adjusting region is formed under the condition described in the first embodiment and the second embodiment.

### Third Embodiment

[Structure]

In the third embodiment, a channel impurity concentration adjusting region 10 having a configuration same as that in the first embodiment and the second embodiment is provided on both the upper end portion and lower end portion of a semiconductor layer 3.

In the third embodiment, a condition for the upper channel impurity concentration adjusting region 10 in the first embodiment and the second embodiment can appropriately be applied to a condition for the lower channel impurity concentration adjusting region. In a concentration condition for the upper channel impurity concentration adjusting region 10 in the first embodiment and the second embodiment, a concentration range defined for the net concentration of a second conductivity type impurity in the semiconductor layer excepting a certain area extending from the upper end of the semiconductor layer is applied as an impurity concentration range of the channel impurity concentration adjusting region 10 defined for the net concentration of the second conductivity type impurity in the semiconductor layer region excepting a certain area extending from the upper end of the semiconductor layer and a certain area extending from the lower end of the semiconductor layer. For example, the value of a concentration range defined for the “net concentration of the second conductivity type impurity in the semiconductor layer excepting an area extending from the upper end of the semiconductor layer 3 to the depth Htop” is applied to a concentration range defined for the “net concentration of the second conductivity type impurity in the semiconductor layer excepting both of an area extending from the upper end of the semiconductor layer 3 to the depth Htop and an area extending from the lower end of the semiconductor layer to the height Htop2”.

### Example of Structure of Third Embodiment

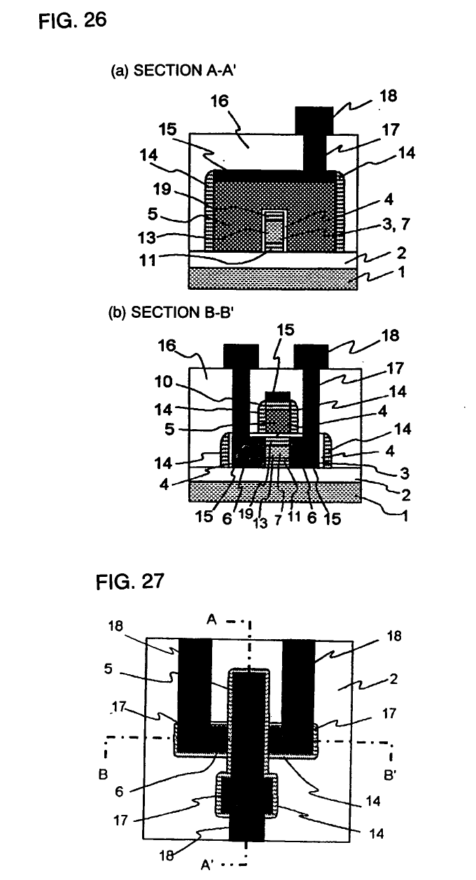

The third embodiment will be described with reference to FIGS. 26(a) and 26(b) and FIG. 27. FIG. 26(a) is a sectional view in the section A-A′ in FIG. 27, which is a sectional view in a position corresponding to the section A-A′ in FIG. 31 showing an example of a conventional technique. FIG. 26(b) is a sectional view in the section B-B′ in FIG. 27, which is a sectional view in a position corresponding to the section B-B′ in FIG. 31 showing an example of a conventional technique.

In this embodiment, a semiconductor layer 3 projecting upward from a substrate is provided, and a gate electrode 5 is provided on the side surface of the semiconductor layer via a gate insulating film 4. The gate electrode 5 is patterned in an appropriate dimension, and source/drain regions 6 where a first conductivity type impurity is introduced in a high concentration are formed on the semiconductor layer 3 at a position in which the semiconductor layer is not covered with the gate electrode 5. A low-concentration second conductivity type impurity is introduced into a channel forming region 7 representing the semiconductor layer covered with the gate electrode 5, and a channel composed of a first conductivity type carrier is formed by applying an appropriate voltage to the gate electrode 5. An interconnect 18 is connected to the gate electrode 5 or the source/drain region 6 via a contact 17.

Into a channel impurity concentration adjusting region 10 provided over a certain area from the upper end of the semiconductor layer 3 forming the channel forming region 7 (to the depth Htop) (hereinafter referred to as an upper channel impurity concentration adjusting region 19) and a channel impurity concentration adjusting region 10 provided over a certain area from the lower end of the semiconductor layer 3 (to the height Htop2) (hereinafter referred to as a lower channel impurity concentration adjusting region 11) is introduced a second conductivity type impurity having a concentration higher than that is the semiconductor layer 3 excepting the upper channel impurity concentration adjusting region 19 and the lower channel impurity concentration adjusting region 11 (referred to as a middle channel forming region).

The impurity concentration in the lower channel impurity concentration adjusting region is adjusted to be a concentration with which an increase in electric potential in the lower corner portion of the semiconductor layer is inhibited and a channel is formed on the side surface of the lower channel impurity concentration adjusting region with application of a gate voltage.

If the average value of the net concentration of the second conductivity type impurity in the semiconductor layer excepting the area extending from the upper end of the semiconductor layer 3 to the depth Htop and the area extending from the lower end of the semiconductor layer 3 to the height Htop2 in the channel forming region of a second conductivity type is represented by N2, the impurity concentration in the lower channel impurity concentration adjusting region is set so as to satisfy a relationship between Ntop and N2 in which an increase in electric potential in the corner portion of the upper part of the semiconductor layer can be reduced as compared to a case where no lower channel impurity concentration adjusting region is provided (i.e. a case where the impurity concentration in the lower channel impurity concentration adjusting region is replaced by N2). At this time, the amount of reduction of an increase in electric potential in the lower corner portion of the semiconductor layer is preferably 60 mV or more typically in at least a part of the lower corner portion of the semiconductor layer (the reduction amount of 60 mV corresponds to a condition under which a leak current by the parasitic transistor decreases by an order of magnitude).

In the third embodiment, a ratio of the average value of the net concentration of the second conductivity type impurity in the area extending from the upper end of the semiconductor layer 3 to the depth Htop in the channel forming region of a second conductivity type to the average value (N2) of the net concentration of the second conductivity type impurity in the semiconductor layer excepting the area extending from the upper end of the semiconductor layer 3 to the depth Htop and the area extending from the lower end of the semiconductor layer 3 to the height Htop2 in the channel forming region of a second conductivity type is set to be in a range same as the range of the ratio of Ntop to N in the first embodiment.

In the third embodiment, a ratio of the average value of the net concentration of the second conductivity type impurity in the area extending from the lower end of the semiconductor layer 3 to the height Htop2 in the channel forming region of a second conductivity type to the average value of the net concentration of the second conductivity type impurity in the semiconductor layer excepting the area extending from the upper end of the semiconductor layer 3 to the depth Htop and the area extending from the lower end of the semiconductor layer 3 to the height Htop2 is set to be in a range same as the range of the ratio of Ntop to N in the first embodiment.

The range of Htop that is applied in the third embodiment is set to a range same as the range of Htop in the first embodiment.

The range of Htop2 that is applied in the third embodiment is set to a range same as the range of Htop in the first embodiment.

Definitions of Htop and Htop2 in the third embodiment conform to those described in the first embodiment.

The average value of the net concentration of the second conductivity type impurity in the area extending from the upper end of the semiconductor layer 3 to the depth Htop in the channel forming region of a second conductivity type is typically in a range from 1.3 times to 4 times as large as the average value of the net concentration of the second conductivity type impurity in the semiconductor layer excepting the area extending from the upper end of the semiconductor layer 3 to the depth Htop and the area extending from the lower end of the semiconductor layer 3 to the height Htop2, and more typically in a range from 1.5 times to 3 times as large as the average value of the net concentration of the second conductivity type impurity in the semiconductor layer excepting the area extending from the upper end of the semiconductor layer 3 to the depth Htop and the area extending from the lower end of the semiconductor layer 3 to the height Htop2. Alternatively, the average value of the net concentration of the second conductivity type impurity in the area extending from the upper end of the semiconductor layer 3 to the depth Htop is in a range from 1.5 times to 3 times as large as the average value of the net concentration of the second conductivity type impurity in the semiconductor layer excepting the area extending from the upper end of the semiconductor layer 3 to the depth Htop and the area extending from the lower end of the semiconductor layer 3 to the height Htop2 exclusive of an area within 1 nm of the boundary surface.

The average value of the net concentration of the second conductivity type impurity in the area extending from the lower end of the semiconductor layer 3 to the height Htop2 in the channel forming region of a second conductivity type is typically in a range from 1.3 times to 4 times as large as the average value of the net concentration of the second conductivity type impurity in the semiconductor layer excepting the area extending from the upper end of the semiconductor layer 3 to the depth Htop and the area extending from the lower end of the semiconductor layer 3 to the height Htop2, and more typically in a range from 1.5 times to 3 times as large as the average value of the net concentration of the second conductivity type impurity in the semiconductor layer excepting the area extending from the upper end of the semiconductor layer 3 to the depth Htop and the area extending from the lower end of the semiconductor layer 3 to the height Htop2. Alternatively, the average value of the net concentration of the second conductivity type impurity in the area extending from the upper end of the semiconductor layer 3 to the depth Htop is in a range from 1.5 times to 3 times as large as the average value of the net concentration of the second conductivity type impurity in the semiconductor layer excepting the area extending from the upper end of the semiconductor layer 3 to the depth Htop and the area extending from the lower end of the semiconductor layer 3 to the height Htop2 exclusive of an area within 1 nm of the boundary surface.

In the third embodiment, the second embodiment may be applied to the upper channel impurity concentration adjusting region 19 or the lower channel impurity concentration adjusting region 11. That is, a region having a high impurity concentration is provided only in a part of the upper end portion of the semiconductor layer. Alternatively, a region having a high impurity concentration is provided only in a part of the lower end portion of the semiconductor layer. When the second embodiment is applied to the lower channel impurity concentration adjusting region 11, the “upper end portion” is replaced by the “lower end portion” in the description of the impurity distribution in the upper end portion in the second embodiment.

When the second embodiment is applied to the upper channel impurity concentration adjusting region 19, a ratio of the average value of the net concentration of the second conductivity type impurity in the area extending from the upper end of the semiconductor layer 3 to the depth Htop in the channel forming region of a second conductivity type to the average value of the net concentration of the second conductivity type impurity in the semiconductor layer excepting the area extending from the upper end of the semiconductor layer 3 to the depth Htop and the area extending from the lower end of the semiconductor layer 3 to the height Htop2 is set to be in a range same as the range of any of the ratio of Ntop to N, the ratio of Ntop1 to N and the ratio of Ntop2 to N in the second embodiment.

When the second embodiment is applied to the lower channel impurity concentration adjusting region 11, a ratio of the average value of the net concentration of the second conductivity type impurity in the area extending from the lower end of the semiconductor layer 3 to the height Htop2 in the channel forming region of a second conductivity type to the average value of the net concentration of the second conductivity type impurity in the semiconductor layer excepting the area extending from the upper end of the semiconductor layer 3 to the depth Htop and the area extending from the lower end of the semiconductor layer 3 to the height Htop2 is set to be in a range same as the range of any of the ratio of Ntop to N, the ratio of Ntop1 to N and the ratio of Ntop2 to N in the second embodiment.

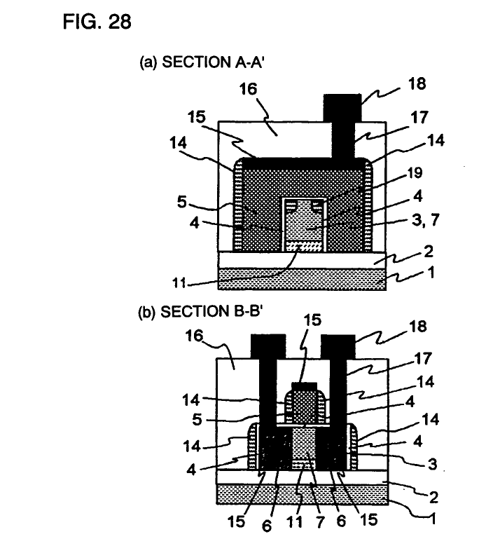

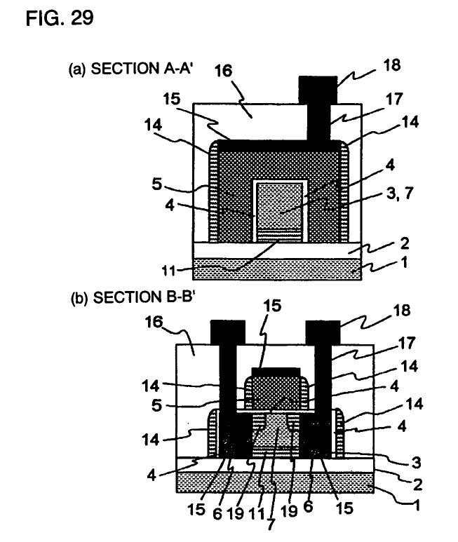

Configurations when combining the configuration of the channel impurity concentration adjusting region 10 of the second embodiment with the configuration of the upper channel impurity concentration adjusting region 19 in the third embodiment are shown in FIGS. 28(a) and 28(b), FIGS. 29(a) and 29(b) and FIGS. 30(a) and 30(b). The configurations of FIGS. 28(a) and 28(b), FIGS. 29(a) and 29(b) and FIGS. 30(a) and 30(b) are configurations obtained by combining the configurations of FIGS. 17(a) and 17(b), FIGS. 19(a) and 19(b) and FIGS. 21(a) and 21(b), respectively, with the third embodiment having the lower channel impurity concentration adjusting region 11 in the lower part of the semiconductor layer.

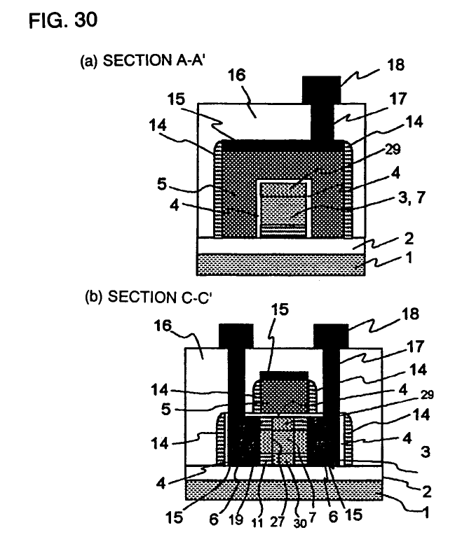

The “upper region 29 having a slightly high concentration 29” and the “lower region 30 having a slightly high concentration” in FIG. 30 are regions that are formed according to a feature of the production method in terms of the step when the second production method of the second embodiment is applied for formation of the upper channel impurity concentration adjusting region in the production method of the third embodiment described below. The “upper region 29 having a slightly high concentration” is a region of which the net concentration of the second conductivity type impurity is lower than that in the upper channel impurity concentration adjusting region 19, but higher than that in the semiconductor layer 3 below the “upper region 29 having a slightly high concentration”. The “lower region 30 having a slightly high concentration” is a region of which the net concentration of the second conductivity type impurity is lower than that in the lower channel impurity concentration adjusting region 11, but higher than that in the semiconductor layer 3 above the “lower region 30 having a slightly high concentration”.

The characteristic of the electric potential difference such as Vside and Vcorner and the characteristic of the impurity concentration in the channel forming region in a transistor of which the characteristic is to be improved by application of this embodiment and the transistor of this embodiment are same as those in the first embodiment.

That is, the impurity concentration in the channel impurity concentration adjusting region is set so that an increase in electric potential in the upper corner portion of the semiconductor layer and an increase in electric potential in the lower corner portion of the semiconductor layer can be reduced as compared to a case where no channel impurity concentration adjusting region is provided. At this time, at least one of the amount of reduction of an increase in electric potential in the upper corner portion of the semiconductor layer and the amount of reduction of an increase in electric potential in the lower corner portion of the semiconductor layer is preferably 60 mV or more typically in at least a part of the upper corner portion of the semiconductor layer or the lower corner portion of the semiconductor layer.

The present invention is typically applied for improving the characteristic of the transistor in which an increase in electric potential by 60 mV or more occurs in at least a part of the upper corner portion of the semiconductor layer or the lower corner portion of the semiconductor layer when no channel impurity concentration adjusting region is provided. Furthermore, the present invention is typically applied for improving the characteristic of the transistor in which Vside is 120 mV or more when no channel impurity concentration adjusting region is provided.

The transistor of this embodiment has a characteristic in which Vside is typically 120 mV or more. The process for determining pside, pcorner, pcenter, Vcorner and Vside is same as that in the first embodiment. However, pcorner is set for both the upper corner and lower corner of the semiconductor layer, and Vcorner is either Vcorner for the upper corner of the semiconductor layer or Vcorner for the lower corner of the semiconductor layer, whichever is greater. Vside is situated at a position below the lower end of the upper channel impurity concentration adjusting region and above the upper end of the lower channel impurity concentration adjusting region. When any of the upper channel impurity concentration adjusting region or the upper channel impurity concentration adjusting region is provided in accordance with the second embodiment, pside of this embodiment is selected from a region below the lower end of the upper channel impurity concentration adjusting region provided at any position in the channel forming region and above the upper end of the lower channel impurity concentration adjusting region provided at any position in the channel forming region, irrespective of whether or not the channel impurity concentration adjusting region is provided just above pside or irrespective of whether or not the channel impurity concentration adjusting region is provided just below pside.

In this connection, pside, pcorner, pcenter, Vcorner and Vside have been discussed above taking an n-channel transistor as an example, but for a p-channel transistor, the polarity is reversed. The present invention is typically applied for improving the performance of the transistor in which the average value of the impurity concentration in the semiconductor layer is 7.5×10¹⁷ cm⁻³ or more when neither the upper channel impurity concentration adjusting region nor the lower channel impurity concentration adjusting region is provided, and therefore in the transistor of this embodiment, the average value of the net concentration of the second conductivity type impurity in the channel forming region of a second conductivity type excepting both the upper channel impurity concentration adjusting region and the lower channel impurity concentration adjusting region is typically 7.5×10¹⁷ cm⁻³ or more. For the transistor with a short channel (typically, the gate length is 0.1 μm or less), the present invention is typically applied for improving the performance of the transistor in which the average value of the impurity concentration in the semiconductor layer is 1.0×10¹⁸ cm⁻³ or more when neither the upper channel impurity concentration adjusting region nor the lower channel impurity concentration adjusting region is provided, and in the transistor of this embodiment with a short channel, the average value of the net concentration of the second conductivity type impurity in the channel forming region of a second conductivity type excepting both the upper channel impurity concentration adjusting region and the lower channel impurity concentration adjusting region is typically 1.0×10¹⁸ cm⁻³ or more.

[Production Method]

### Production Method of Third Embodiment

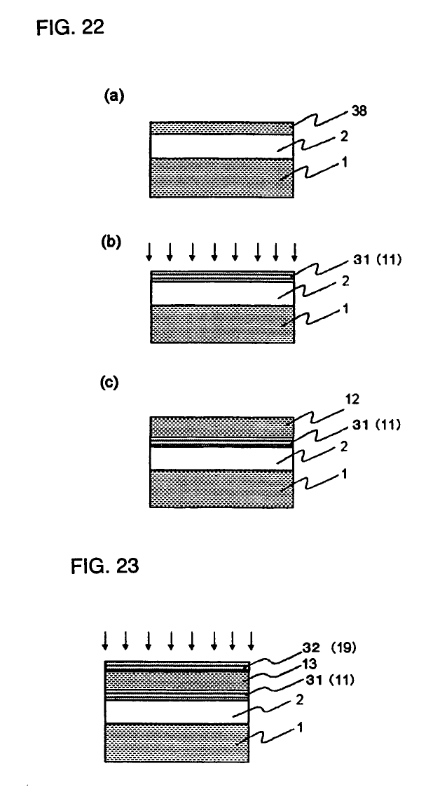

One example of the production method of the third embodiment will be described with reference to FIGS. 22(a), 22(b) and 22(c), FIG. 23, FIGS. 24(a), 24(b) and 24(c), FIGS. 25(a), 25(b) and 25(c), FIGS. 26(a) and 26(b) and FIG. 27.

FIGS. 22(a), 22(b) and 22(c) and FIG. 23 depict the shape of a section in a position corresponding to the section A-A′ or the section B-B′ in FIG. 31 on a step-by-step basis.

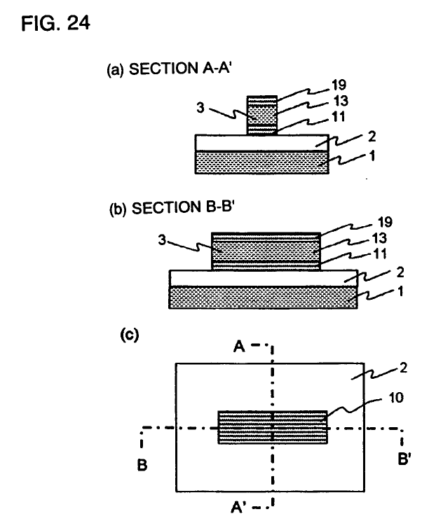

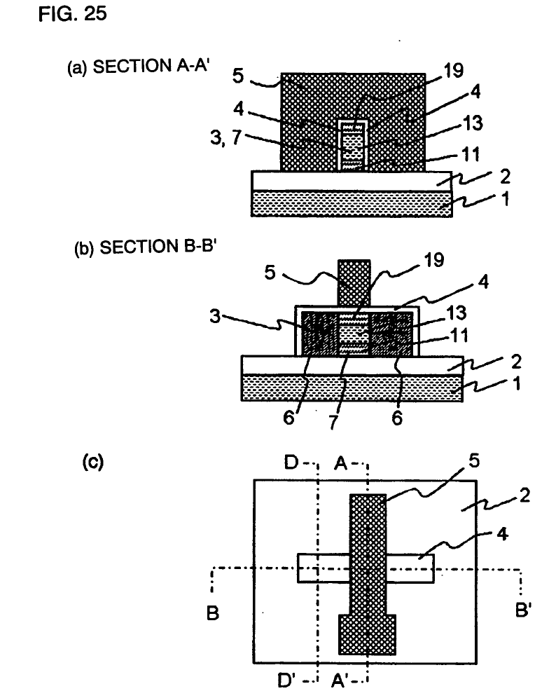

FIG. 24(a), FIG. 25(a) and FIG. 26(a) are sectional views in sections A-A′ in FIG. 24(c), FIG. 25(c) and FIG. 27, respectively, and depict the shape of a section in a position corresponding to the section A-A′ in FIG. 31 which is a plan view showing an example of a conventional technique on a step-by-step basis. FIG. 24(b), FIG. 25(b) and FIG. 26(b) are sectional views in sections B-B′ in FIG. 24(c), FIG. 25(c) and FIG. 27, respectively, and depict the shape of a section in a position corresponding to the section B-B′ in FIG. 31 which is a plan view showing an example of a conventional technique on a step-by-step basis.

In this production method, a semiconductor layer having a low impurity concentration (shown as an epitaxial layer 12 in the figure; typically composed of monocrystalline silicon) is epitaxially grown (FIG. 22(c)) on the upper part of a middle-concentration second conductivity type semiconductor layer 31 (FIG. 22(b)) forming a lower channel impurity concentration adjusting region 11, whereby a structure of a semiconductor layer having a high impurity concentration in the lower part of the semiconductor layer is formed, and a step similar to that of the production method of the first embodiment or the production method of the second embodiment is then carried out, whereby a field effect transistor of the third embodiment is formed (FIGS. 24(a), 24(b) and 24(c), FIGS. 25(a), 25(b) and 25(c), FIGS. 26(a) and 26(b) and FIG. 27).

Into the middle-concentration second conductivity type semiconductor layer 31 and an upper middle-concentration second conductivity type semiconductor layer 32 is introduced a second conductivity type impurity having a concentration with which an upper channel impurity concentration adjusting region 19 and a lower channel impurity concentration adjusting region 11 of the formed transistor satisfy the condition of the first embodiment or the second embodiment.

### Example of Production Method of Third Embodiment

The production method of the third embodiment will be described with reference to FIGS. 22(a), 22(b) and 22(c), FIG. 23, FIGS. 24(a), 24(b) and 24(c), FIGS. 25(a), 25(b) and 25(c), FIGS. 26(a) and 26(b) and FIG. 27.

Into an SOI substrate prepared by laminating a buried insulating layer 2 composed of an insulating material such as SiO₂ on a support substrate 1 composed of silicon and further laminating thereon a semiconductor layer 38 composed of monocrystalline silicon (FIG. 22(a)) is introduced a second conductivity type impurity by ion implantation (FIG. 22(b)) to form the semiconductor layer into a middle-concentration second conductivity type semiconductor layer 31. Next, an epitaxial layer 12 is formed on the upper part of the middle-concentration second conductivity type semiconductor layer 31 by epitaxially growing a silicon layer of which the concentration of the second conductivity type impurity is lower than that in the middle-concentration second conductivity type semiconductor layer 31. Next, the second conductivity type impurity is introduced into the upper part of the epitaxial layer 12 by ion implantation to form an upper middle-concentration second-conductivity type semiconductor layer 32 on the upper part of the epitaxial layer 12 (FIG. 23). The middle-concentration second conductivity type semiconductor layer 32 may be formed by epitaxially growing monocrystalline silicon containing the second conductivity type impurity on the upper part of the epitaxial layer 12.

A preferable value of the thickness Htop of the middle-concentration second conductivity type semiconductor layer 31 is typically 24.5 nm or less, and Htop is preferably 5 nm or more in terms of ease in the production method, and therefore Htop is typically 5 nm to 24.5 nm, and in view of the tradeoff between ease in the production method (production becomes easier as Htop increases in terms of production) and the effect, Htop is preferably in a range from 10 nm to 20 nm, and the most typical value of Htop is 10 nm.

The thickness of the epitaxial layer 12 is typically 30 nm to 100 nm.

Next, a semiconductor layer 3 projecting from the surface of a substrate is formed by patterning by a normal lithography step and a normal etching step such as RIE (FIG. 24, symbol 13 denotes a low-concentration channel forming region). Next, a gate insulating film 4 is provided on the side surface of the semiconductor layer 3, polysilicon is then deposited, and patterned by a normal lithography step and etching by an RIE step to form a gate electrode, ion implantation is subsequently carried out using the gate electrode as a mask, and a heat treatment is carried out to provide source/drain regions 6 on the semiconductor layer 3 in a position at which the semiconductor layer is not covered with the gate electrode, and the shape in FIGS. 25(a), 25(b) and 25(c) is thereby obtained. In this connection, the gate insulating film is provided by, for example, thermally oxidizing the semiconductor layer 3. The source/drain regions are formed by introducing an impurity by an impurity introduction step such as vertical ion implantation, slanting ion implantation or plasma doping.

Subsequently, an insulating film is deposited on the entire surface and etched back to provide a gate side wall 14. For the insulating film forming the gate side wall 14, an insulating film such as, for example, a SiO₂ monolayer film, a Si₃N₄ monolayer film, a multilayered film composed of SiO₂ and Si₃N₄ is used. The insulating film forming the gate side wall 14 is formed by a film formation technique such as a CVD method. Subsequently, a metal is deposited on the upper part of the source/drain regions 6 and the upper part of the gate electrode 5, and a heat treatment is carried out to form a silicide layer 15 on the upper part of the source/drain regions 6 and the upper part of the gate electrode 5. Subsequently, an interlayer insulating film 16 is deposited and flattened, a contact hole is then opened in the upper part of the source/drain regions 6 or the upper part of the gate electrode 5, a metal is buried in the contact hole to form a contact 17, and an interconnect 18 composed of a metal is connected to the contact 17 to obtain the shape in FIGS. 26(a) and 26(b) and FIG. 27. The burying a metal in the contact region and the deposition of a metal forming an interconnect may be carried out at the same time. The contact 17 is situated below the interconnect 18, but its position is shown perspectively in FIG. 27.

[Effect]

The transistor of this embodiment has an effect of inhibiting concentration of an electric field on the lower corner of a semiconductor layer in addition to an effect of inhibiting concentration of an electric field on the upper corner of the semiconductor layer. Thus, not only a parasitic in the upper corner of the semiconductor layer but also a parasitic transistor in the lower corner of the semiconductor layer can be inhibited.

### Fourth Embodiment

[Structure]

The fourth embodiment has a configuration in which a cap insulating film thicker than a gate electrode is provided between the upper part of a projecting semiconductor layer in the present invention and the gate electrode so that a channel is not formed on the upper surface of the semiconductor layer.

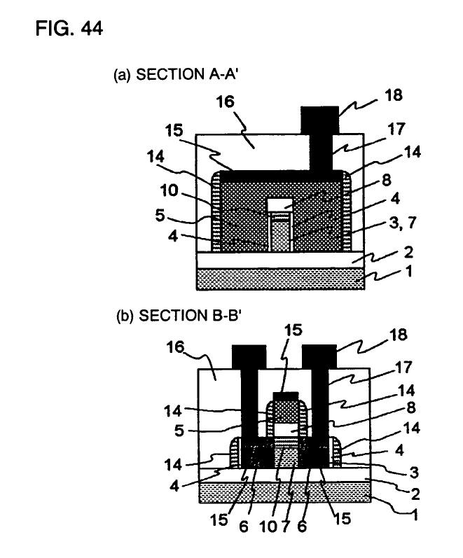

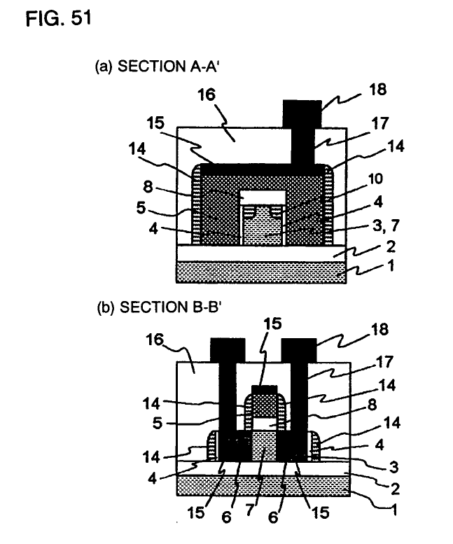

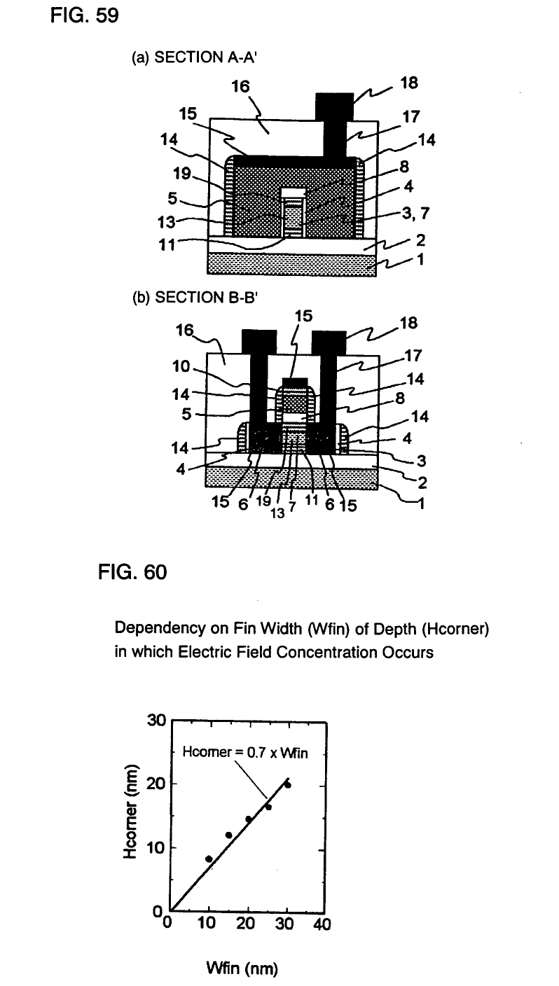

For example, the fourth embodiment may have configuration in which a cap insulating film 8 is formed on the upper part of the semiconductor layer 3 and below the gate electrode 5 in the first embodiment, the second embodiment and the third embodiment. There is a configuration shown in FIGS. 44(a) and 44(b) as a configuration corresponding to FIGS. 4(a) and 4(b) in the first embodiment. There are configurations shown in FIGS. 51(a) and 51(b), FIGS. 53(a) and 53(b) and FIGS. 55(a) and 55(b) as configurations corresponding to FIGS. 17(a) and 17(b), FIGS. 19(a) and 19(b) and FIGS. 21(a) and 21(b), respectively, in the second embodiment. There is a configuration shown in FIGS. 59(a) and 59(b) as a configuration corresponding to FIGS. 26(a) and 26(b) in the third embodiment.

[Production Method]

In this embodiment, a field effect transistor can be produced by a production method similar to those of the first embodiment, the second embodiment and the third embodiment except that a step of forming a cap insulating film on a semiconductor layer is carried out before a step of forming a gate electrode.

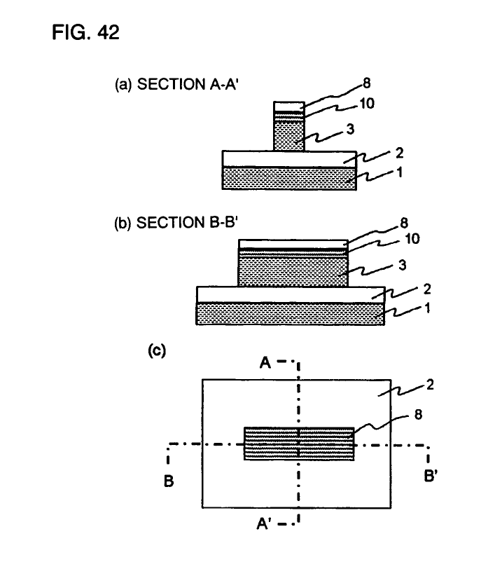

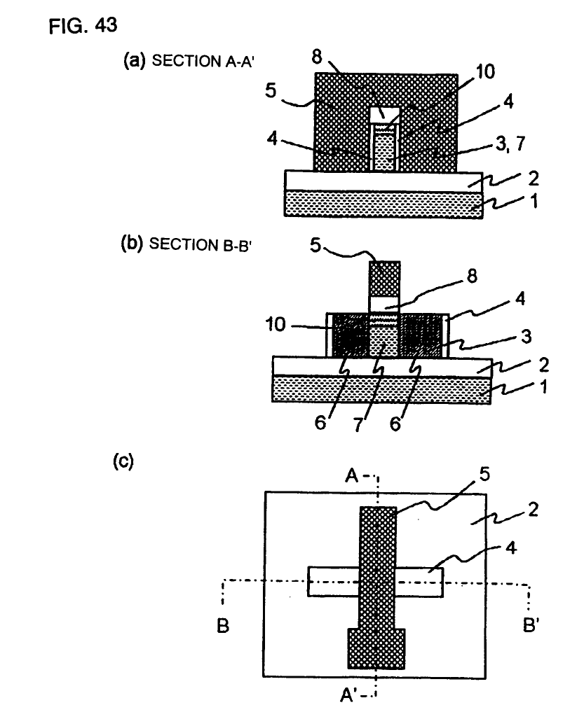

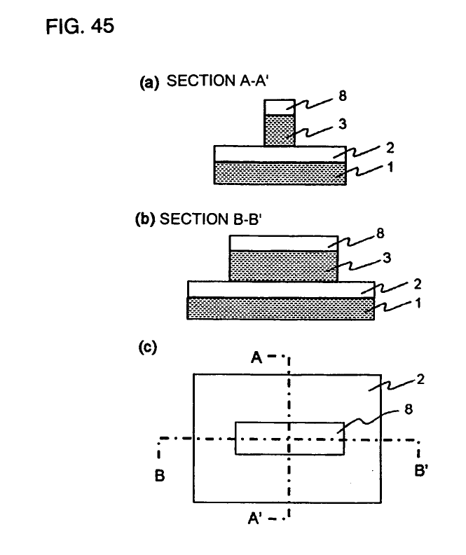

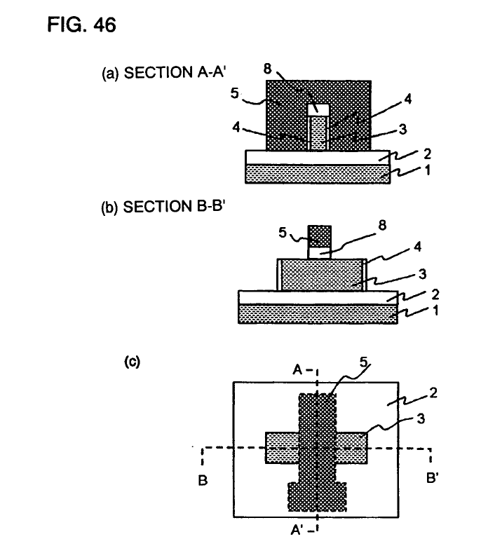

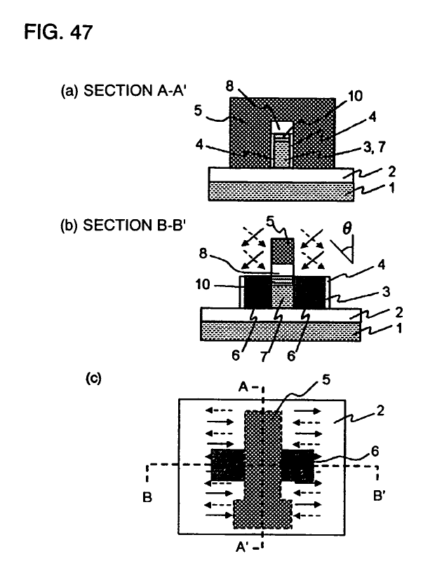

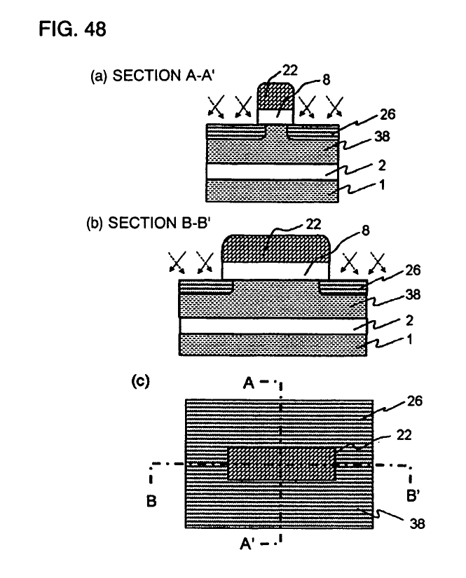

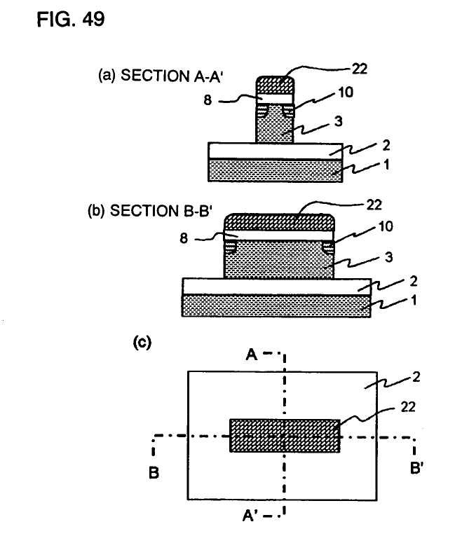

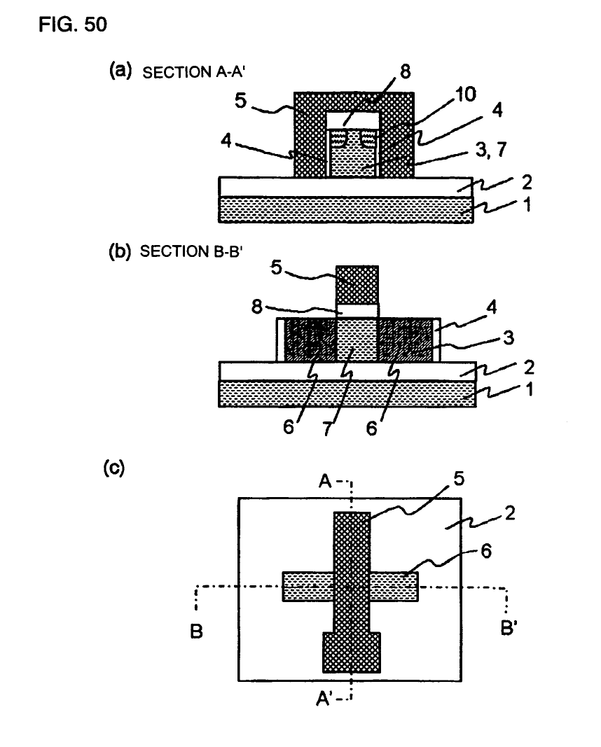

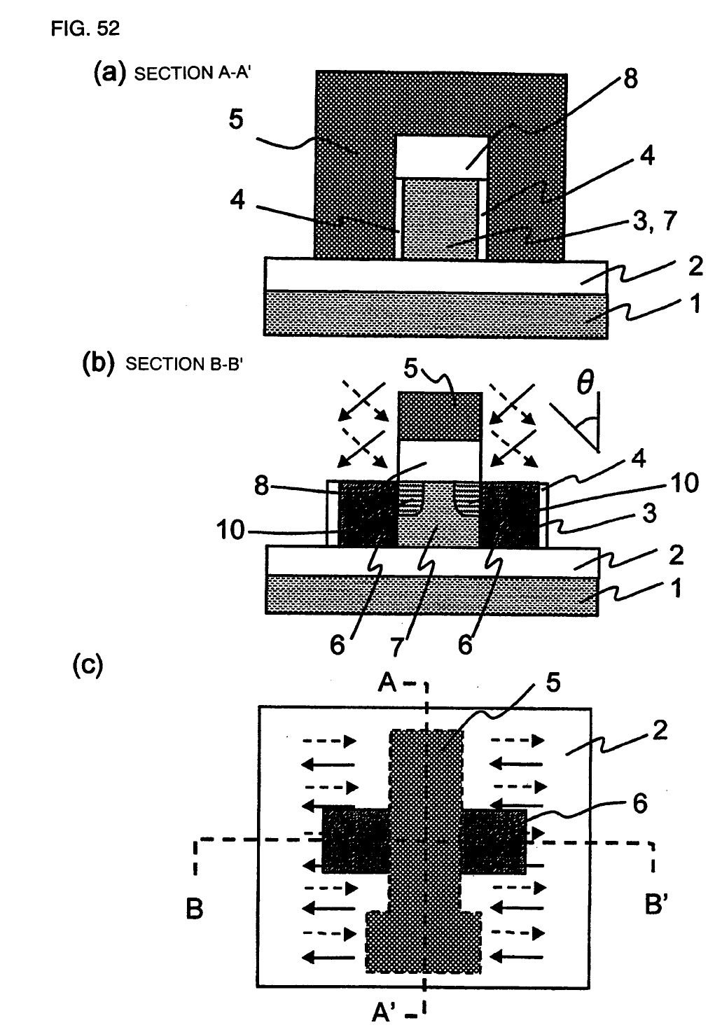

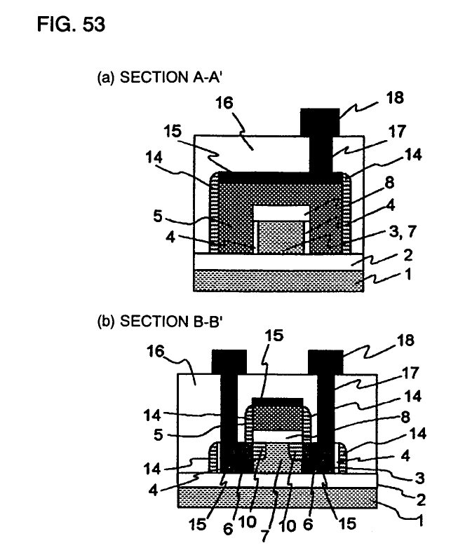

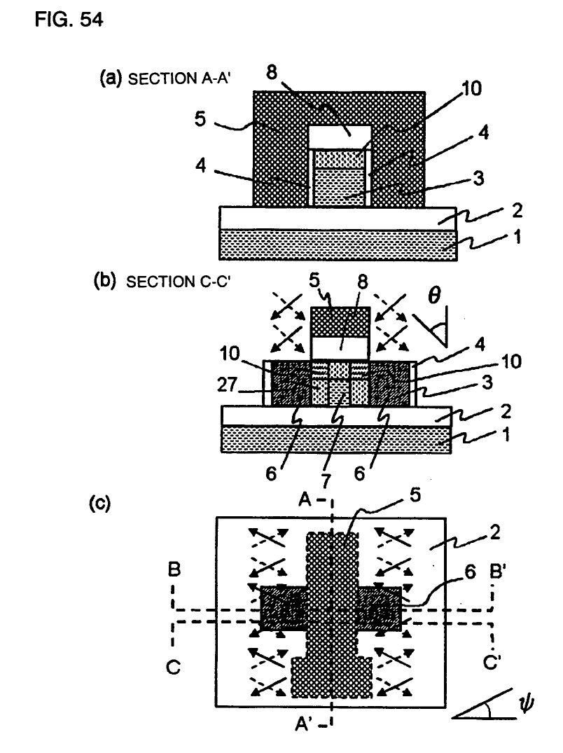

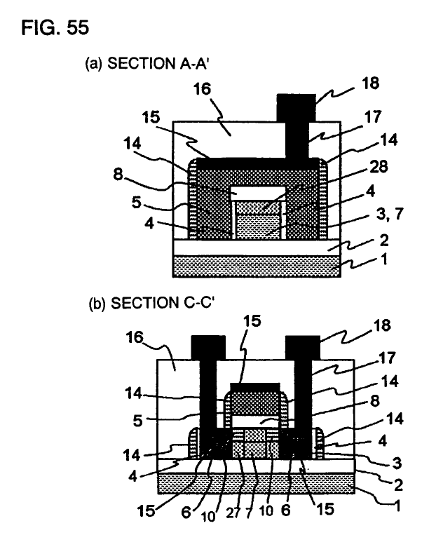

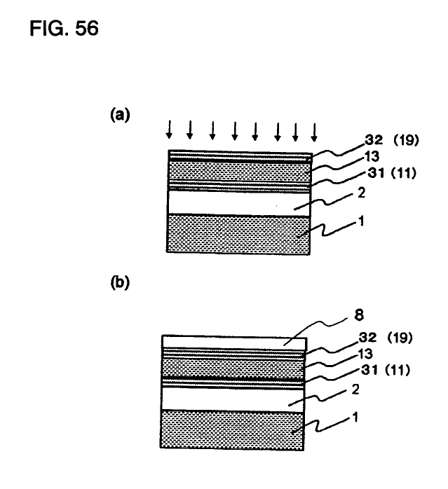

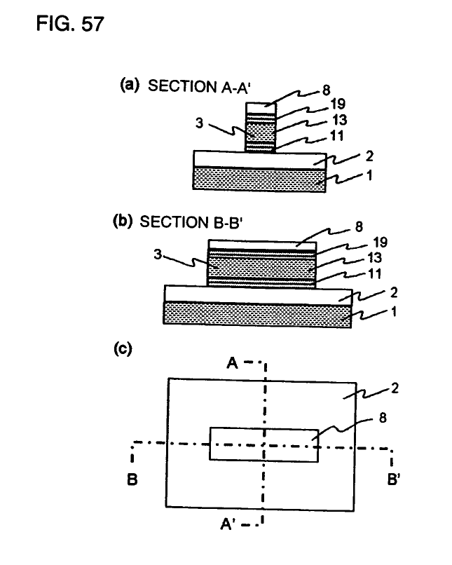

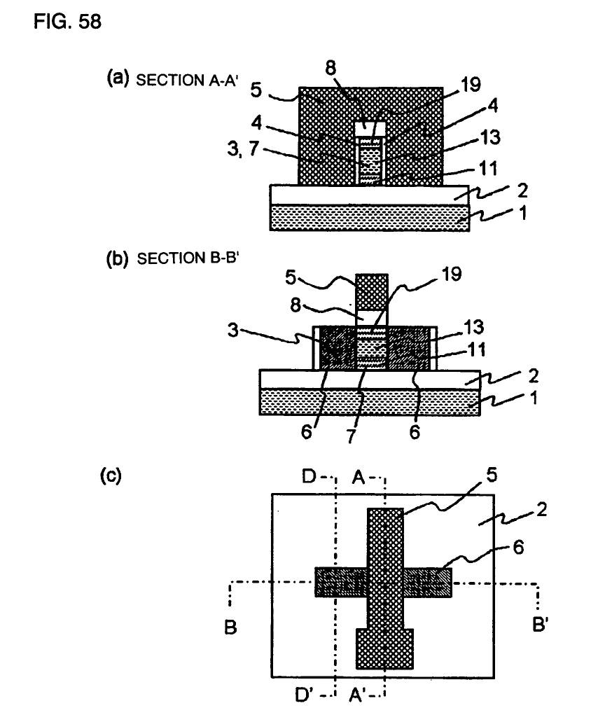

Views for explaining the production of the configuration shown in FIGS. 44(a) and 44(b) are shown in FIGS. 41 (a) to 43(c) and FIGS. 45(a) to 47(c). FIGS. 41 (a) to 43(c) correspond to FIGS. 1 to 3(c) and FIGS. 45(a) to 47(c) correspond to FIGS. 6(a) to 8(c). In the method shown in FIGS. 1 to 3(c), a projecting semiconductor layer 3 is formed, and an impurity is then ion-implanted to form a channel impurity concentration adjusting region 10, but in FIGS. 41(a) to 43(c), an impurity region 10 as a channel impurity concentration adjusting region 10 is formed, an insulating layer 8 as a cap insulating layer is formed thereon, and patterning is then carried out to form a projecting semiconductor layer 3 having the cap insulating film 8 in the upper part. Views for explaining the production of the configuration shown in FIGS. 51(a) and 51(b) are shown in FIGS. 48(a) to 50(c). FIGS. 48(a) to 50(c) correspond to FIGS. 14(a) to 16(c). Views for explaining the production of the configuration shown in FIGS. 53(a) and 53(b) are shown in FIGS. 52(a), 52(b) and 52(c). FIGS. 52(a), 52(b) and 52(c) correspond to FIGS. 18(a), 18(b) and 18(c). Views for explaining the production of the configuration shown in FIGS. 55(a) and 55(b) are shown in FIGS. 54(a), 54(b) and 54(c). FIGS. 54(a), 54(b) and 54(c) correspond to FIGS. 20(a), 20(b) and 20(c). Views for explaining the production of the configuration shown in FIGS. 59(a) and 59(b) are shown in FIGS. 56(a) to 58(c). FIGS. 56(a) to 58(c) correspond to FIGS. 23(a) to 25(c).

For the slanting ion implantation step in FIGS. 48(a), 48(b) and 48(c), ion implantation may be carried out using a resist pattern 22 as a mask, or may be carried out using the cap insulating film 8 as a mask after removing the resist pattern 22.

In the step in FIGS. 52(a), 52(b) and 52(c) and FIGS. 54(a), 54(b) and 54(c), the gate electrode is patterned, the cap insulating film 8 in a region which is not covered with the gate electrode is subsequently etched, and slanting ion implantation is then carried out.

[Effect]

Concentration of an electric field on the upper corner of a semiconductor layer can also be inhibited in a double gate structure in which a cap insulating film 8 is provided on a semiconductor layer 3. Thus, a parasitic transistor can be inhibited in the upper corner of the semiconductor layer.

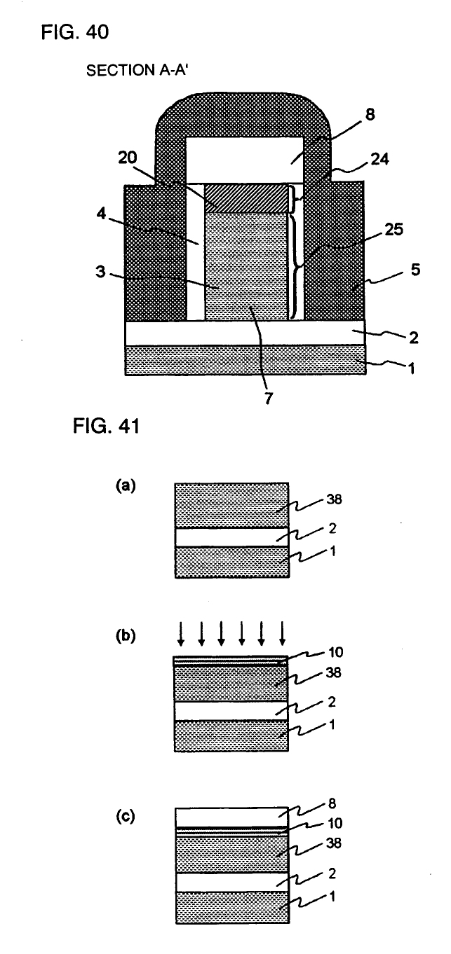

If the impurity concentration in a channel impurity concentration adjusting region is set to be in the aforementioned suitable concentration range applied to the first embodiment, the second embodiment and the third embodiment, formation of a channel on the upper side surface 24 of the semiconductor layer (FIG. 40) is facilitated, thus making it possible to improve an on-current in a double gate transistor.

If the concentration of a second conductivity type impurity introduced into the upper end portion of the semiconductor layer for inhibiting the parasitic transistor is high (e.g. p⁺) in the transistor having a double gate structure, no channel is formed on the upper side surface 24 of the semiconductor layer in FIG. 40, but by applying the present invention, a channel is formed on the upper side surface 24 of the semiconductor layer, and therefore an on-current increases accordingly.

Since FIG. 10 shows the result in a state of applying an on-voltage to the gate electrode, it can be said that in the present invention, a channel is formed on the upper side surface 24 of the semiconductor layer in a state of applying an on-voltage to the gate electrode, whereby a high on-current is obtained.

### Fifth Embodiment

[Structure]

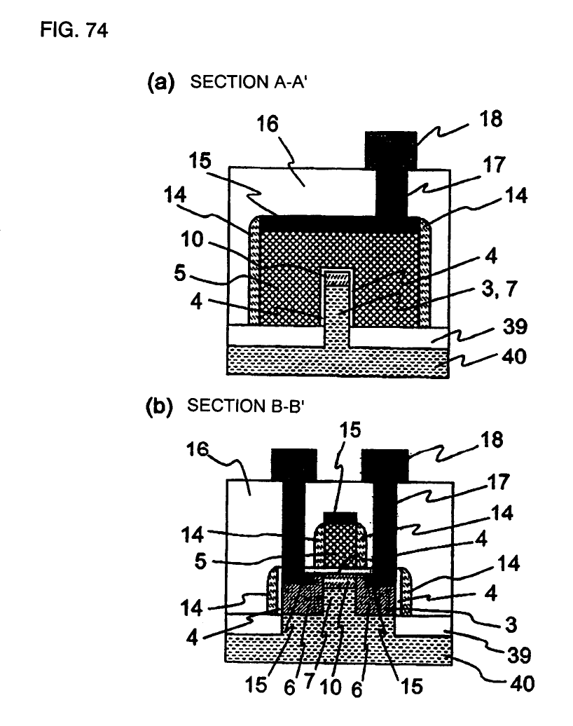

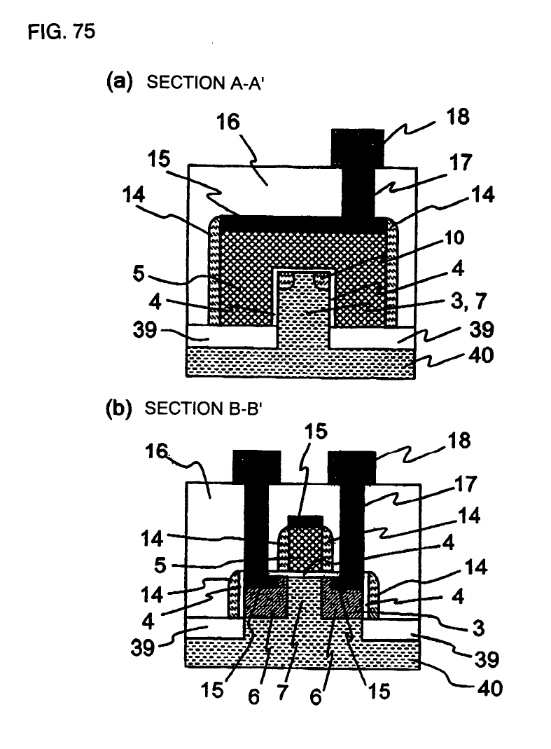

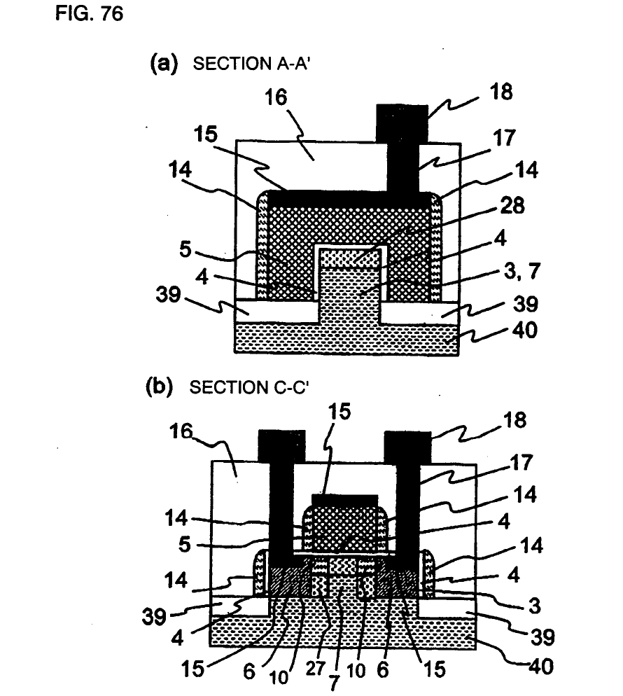

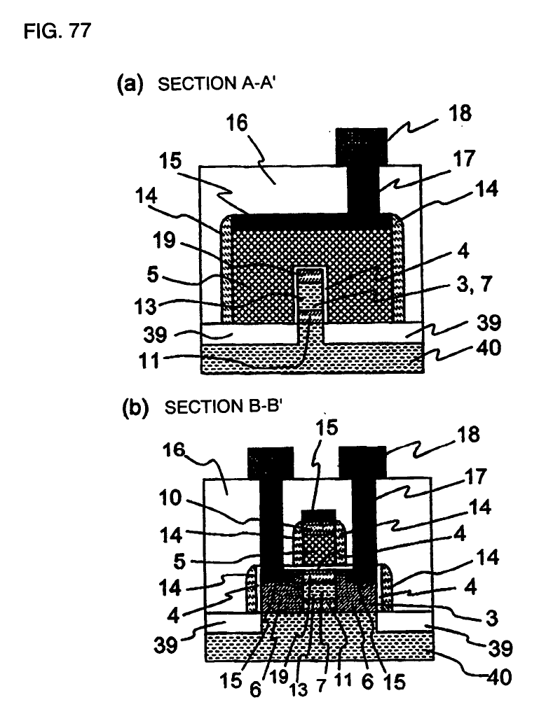

The fifth embodiment has a configuration in which a projecting semiconductor layer is united with a support substrate in the first embodiment, the second embodiment, the third embodiment and the fourth embodiment (FIGS. 74(a) and 74(b), FIGS. 75(a) and 75(b), FIGS. 76(a) and 76(b) and FIGS. 77(a) and 77(b)). FIGS. 74(a) and 74(b), FIGS. 75(a) and 75(b), FIGS. 76(a) and 76(b) and FIGS. 77(a) and 77(b) show a configuration in which the projecting semiconductor layer is united with the support substrate in embodiments shown by FIGS. 4(a) and 4(b), FIGS. 17(a) and 17(b), FIGS. 21(a) and 21(b) and FIGS. 26(a) and 26(b), respectively.

In the fifth embodiment, the channel forming region 7 refers to a region sandwiched between source/drain regions in a semiconductor layer 3 situated above the lower end of a region where gate electrodes face the semiconductor layer via a gate insulating film on the side surface of the semiconductor layer. Equally, the “channel forming region of a second conductivity type” is assumed to be a region situated above the lower end of a region where gate electrodes face a semiconductor layer via the gate insulating film on the side surface of the semiconductor layer.

[Production Method]

A field effect transistor is produced by applying the production method of the first embodiment, the second embodiment, the third embodiment and the fourth embodiment using a bulk semiconductor substrate 40 instead of an SOI substrate.

A bulk semiconductor substrate (typically a silicon substrate) is processed by etching such as RIE to form a projecting semiconductor layer. A step of forming an under-gate insulating film 39 composed of an insulating material such as SiO₂ on a substrate (e.g. depositing SiO₂ by the CVD method and then etching back SiO₂ to a predetermined height by RIE) is carried out after forming the projecting semiconductor layer and before forming a gate electrode.

The under-gate insulating film 39 has an action of reducing a parasitic capacity of the lower part of the gate electrode, but if it is desired to simplify the step, the capacity of the lower part of the gate electrode is allowed to increase, or the like, the step of providing the under-gate insulating film 39 may be omitted. In this case, an insulating film having a thickness comparable to the thickness of the gate insulating is formed at the position of the under-gate insulating film 39 by the step of forming the gate insulating film.

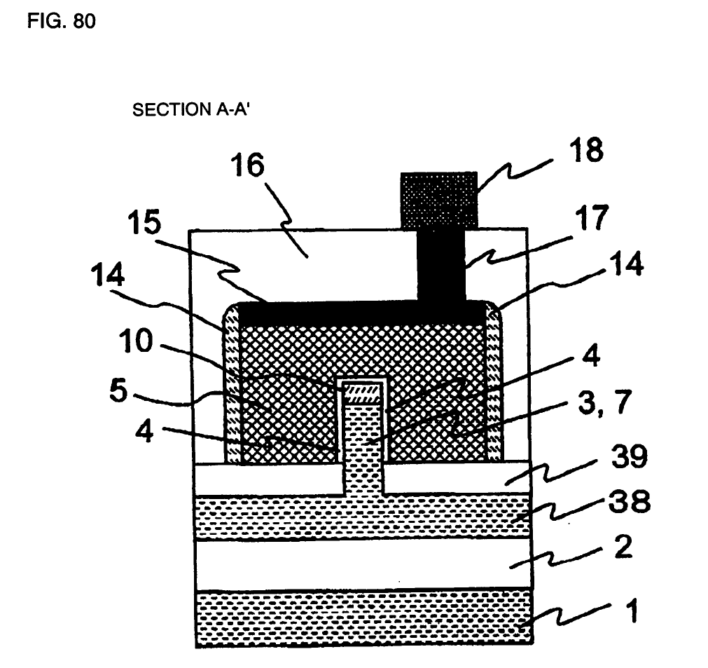

The structure above a buried insulating layer when the SOI substrate is used, but a semiconductor layer 38 is not fully removed in a region around a projecting semiconductor layer 3 (for example, when a semiconductor layer around the projecting semiconductor layer 3 is not fully removed in etching for forming the projecting semiconductor layer 3, and the lower part of the projecting semiconductor layer 3 is connected to a semiconductor layer on the buried insulating layer. See FIG. 80. FIG. 80 is a sectional view of a section corresponding to FIG. 4(a) and FIG. 74(a)) and the method for forming the under-gate insulating film 39 are same as those of the fifth embodiment.

[Effect]

In the configuration in which a projecting semiconductor layer is united with a support substrate, an effect same as the effect of the first embodiment, the second embodiment, the third embodiment and the fourth embodiment can be obtained.

### Specific Examples of Materials, Dimensions and Process Conditions in Embodiments

Specific examples of materials, dimensions and process conditions in first to fifth embodiments will be described.

(Support Substrate)

The support substrate 1 is normally a monocrystalline silicon wafer, but a substrate other than a silicon substrate, such as a substrate of silica, glass, sapphire or a semiconductor other than silicon, may be used.

(Buried Insulating Layer 2)

The buried insulating layer 2 is normally Sio₂, but may be some other insulating material, or may be a multilayered film composed of a plurality of materials. The buried insulating layer may be a low-dielectric constant material having a dielectric constant lower than that of Sio₂, such as porous SiO₂ or SiOF. When the support substrate is an insulating material such as silica, glass or sapphire, the support substrate 1 may also serve as the insulating layer 2. The thickness of the buried insulating layer 2 is normally about 50 nm to 2 μm, more typically 50 nm to 200 nm, but may be 50 nm or less or 2 μm or more as necessary.

In the fifth embodiment, a structure having no buried insulating layer 2 is used.

(Semiconductor Layer 3)

The semiconductor layer 3 is most preferably monocrystalline in terms of improvement of an on-current and inhibition of an off-current, but may be a material other than a monocrystalline material, such as an amorphous material or a polycrystalline material, if the on-current is set to be low in a required specification or the off-current is set to be high in a required specification.

The semiconductor layer 3 may be replaced by a semiconductor layer other than silicon. It may be replaced by a combination of two or more types of semiconductors.

The semiconductor layer 3 has a shape projecting from the substrate plane. The substrate plane is generally the upper surface of the support substrate 1, but in the case of a structure in which the buried insulating layer 2 and the support substrate are united, the substrate plane is the upper surface of the buried insulating layer 2.

The height Hfin of the semiconductor layer 3 (see FIGS. 32(a) and 32(b) and FIGS. 33(a) and 33(b)) is typically 20 nm to 150 nm, more typically 50 nm to 100 nm, and the width Wfin of the semiconductor layer (see FIGS. 32(a) and 32(b) and FIGS. 33(a) and 33(b)) is typically 5 nm to 100 nm, more typically 15 nm to 50 nm. However, for both Hfin and Wfin, a value outside the above range may be used. However, it is preferable that the semiconductor layer in a channel forming region is depleted in a state of applying a threshold voltage to a gate electrode in terms of taking advantage of characteristics of a FinFET (the steeping of the ON-OFF characteristic represented by a reduction in S factor, etc.). For achieving a fully depleted state in which depleted layers extending from opposite side surfaces of the semiconductor layer contact each other in a state of applying a threshold voltage to the gate electrode, it is preferable that Wfin is set to normally 50 nm or less, more typically 35 nm or less.

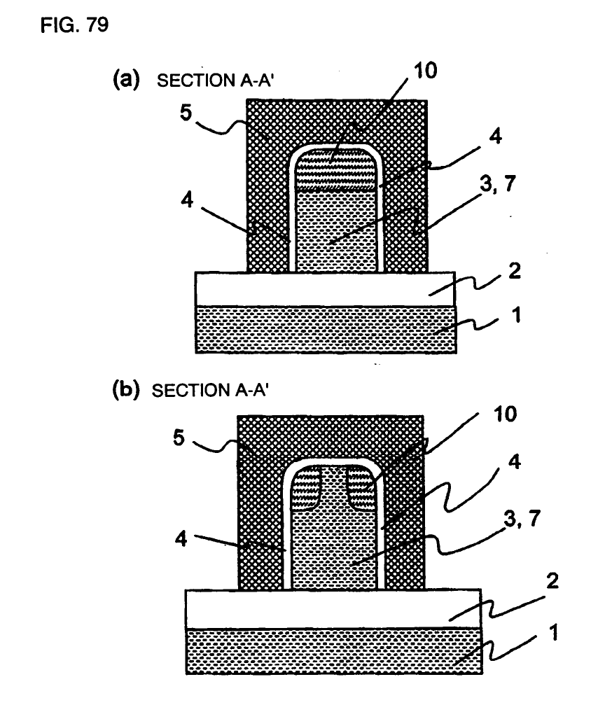

In each example of the present invention, the upper corner portion of the semiconductor layer 3 may be processed into a rounded shape by a rounding step of thermal oxidization or the like. A shape obtained in a section corresponding to FIG. 3(a) when the upper corner portion of the semiconductor layer 3 is processed into a rounded shape is shown in FIG. 79(a), and a shape obtained in a section corresponding to FIG. 16(a) is shown in FIG. 79(b). Rounding the upper corner portion of the semiconductor layer 3 also provides an action of inhibiting electric field concentration in the upper corner portion to inhibit a parasitic transistor, and therefore by rounding the upper corner portion, an effect of inhibiting electric field concentration in the upper corner portion to inhibit a parasitic transistor can further be enhanced in each embodiment of the present invention. The lower corner portion of the semiconductor layer 3 on the buried insulating layer may also be processed into a shape having a curvature similarly by the rounding step in each embodiment.

In the configuration in which the upper corner portion is rounded, the depth Htop of the channel impurity concentration adjusting region is measured from the uppermost position of the semiconductor layer. In the configuration in which the lower corner portion of the semiconductor layer 3 on the buried insulating layer is rounded, the height Htop 2 of the channel impurity concentration adjusting region provided in the lower part of the semiconductor layer is measured from the lowermost position of the semiconductor layer.

(Gate Insulating Film 4)

The gate insulating film 4 may be formed by thermal oxidization of silicon, or may be a SiO₂ film formed by some other method. For example, a SiO₂ film formed by radical oxidization may be used. The gate insulating film may be replaced with a film of an insulating material other than SiO₂. The gate insulating film may be replaced with a multilayered film of SiO₂ and other insulating films, or a multilayered film of insulating films other than SiO₂. The gate insulating film may be replaced with a material having a high dielectric constant, such as HfO₂ or HfSiO₄.

The equivalent oxide thickness of the gate insulating film is typically 1.2 nm to 3 nm. The equivalent oxide thickness is a value obtained by dividing the thickness of an insulating film forming the gate insulating film by the dielectric constant of the gate insulating film and multiplying the resulting quotient by the dielectric constant of SiO₂. When the gate insulating film is a multilayered film, the equivalent oxide thickness is a value obtained by determining the equivalent oxide thickness by the above-mentioned method for each layer and adding up the resulting values. However, in a very small transistor, a gate insulating film having an equivalent oxide thickness of 1.2 nm or less may be used.

(Gate Electrode 5)

The gate electrode 5 may be a polycrystalline semiconductor such as polysilicon, or may be a conductor other than a polycrystalline semiconductor, such as a metal or a metal compound. If the gate electrode 5 is composed of a polycrystalline semiconductor such as polysilicon, an impurity of a first conductivity type which is the same conductivity type as that of a channel is typically introduced into polysilicon of the gate electrode 5. The gate electrode may be formed by a replacement gate process. Specifically, the gate electrode may be formed by a step of forming a shape of a gate electrode with a dummy material on a temporary basis, introducing a first conductivity type impurity in a high concentration into source/drain regions, covering the dummy material with an insulating film, and burying the gate electrode or a gate insulating film and the gate electrode in a cavity obtained by removing the dummy material.

If the gate electrode material is formed with a semiconductor such as polysilicon or a polycrystalline silicon-germanium mixed crystal, introduction of an impurity into a gate may be carried out concurrently with introduction of an impurity into the source/drain. It may be carried out concurrently with deposition of the gate electrode material. It may be carried out before the gate electrode material is deposited and processed into the shape of the gate electrode.

(Source/Drain Regions 6)

The first conductivity impurity is introduced in a high concentration into source/drain regions 6. In this specification, the source/drain regions include all of regions called shallow source/drain regions (also referred to as extension regions) and regions called deep source/drain regions.

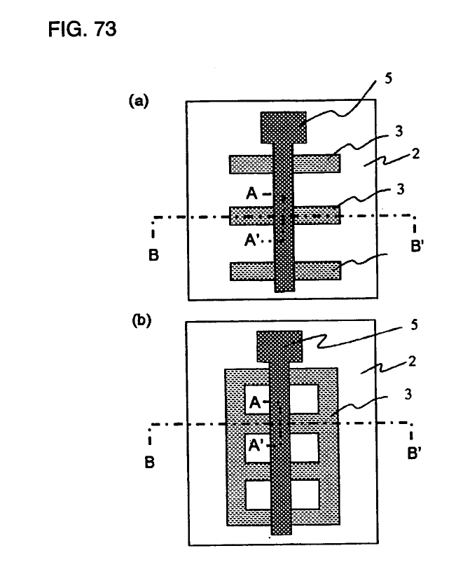

In the FinFET, definitions of the extension region and the deep source/drain region are not generally specified, but include, for example, both of a source/drain region formed on a rectangular region adjacent to the gate in FIG. 73(b) and a region where rectangular regions are mutually connected at a position distant from the gate.

For reducing a parasitic resistance of source/drain regions, a method in which the size of a semiconductor layer forming source/drain regions is increased in an upward or in-plane direction by epitaxially growing a semiconductor such as silicon in a part of source/drain regions may be used in combination.

A part of source/drain regions may extend into a region covered with the gate electrode.

(Channel Forming Region 7)

A low-concentration acceptor or donor impurity is introduced into the channel forming region 7. When the gate electrode is first conductivity type polysilicon, a low-concentration second conductivity type impurity is typically introduced into the channel forming region as it is necessary to set a threshold voltage to an appropriate value, and the channel forming region has a second conductivity type.

A hollow region that is a region into which the second conductivity type impurity is introduced in a concentration slightly higher than that in an area which is covered with the gate electrode and is not adjacent to source/drain regions may be provided on a region of the channel forming region covered with the gate electrode and adjacent to source/drain regions.

Each embodiment has been described taking as an example a FinFET comprising a single channel forming region, but each embodiment may be applied in a FinFET having a plurality of channel forming regions (shown in FIG. 73(a) or 73(b); channel forming regions exist on the semiconductor layer 3 covered with the gate electrode 5). The section A-A′ and the section B-B′ in FIGS. 73(a) and 73(b) corresponds to the section A-A′ and the section B-B′ in each embodiment.

(Cap Insulating Film 8)

The cap insulating film 8 for use in the fourth embodiment may be an insulating film of a single layer such as a SiO₂ film or a Si₃N₄ film, or may be a multilayered film composed of an insulating film such as a SiO₂ film or a Si₃N₄ film. The thickness of the cap insulating film 8 is typically 10 nm to 100 nm, more typically 10 nm to 50 nm, but the thickness may be at least twice as large as the thickness of the gate insulating film, and therefore may be 10 nm or less when the gate insulating film is thin.

(Channel Impurity Concentration Adjusting Region 10)

In each embodiment of the present invention, if the channel impurity concentration adjusting region is provided only in the upper part of the semiconductor layer, the impurity concentration in the channel impurity concentration adjusting region is set so as to satisfy a relationship between Ntop and N in which an increase in electric potential in the upper corner portion of the semiconductor layer can be reduced as compared to a case no channel impurity concentration adjusting region is provided (i.e. case where the impurity concentration in the channel impurity concentration adjusting region is replaced by N). At this time, the amount of reduction of an increase in electric potential in the upper corner portion of the semiconductor layer is preferably 60 mV or more (the amount of reduction of 60 mV corresponds to the condition under which a leak current by a parasitic transistor decreases by an order of magnitude) typically in at least a part of the upper corner portion of the semiconductor layer.

In each embodiment of the present invention, if the channel impurity concentration adjusting region is provided in the lower part of the semiconductor layer, the impurity concentration in the channel impurity concentration adjusting region provided in the lower part of the semiconductor layer is set so that an increase in electric potential in the lower corner portion of the semiconductor layer can be reduced as compared to a case where no channel impurity concentration adjusting region is provided in the lower part of the semiconductor layer (i.e. case where the impurity concentration in the channel impurity concentration adjusting region in the lower part of the semiconductor layer is replaced by N). At this time, the amount of reduction of an increase in electric potential in the lower corner portion of the semiconductor layer is preferably 60 mV or more typically in at least a part of the lower corner portion of the semiconductor layer).

(Gate Side Wall 14)

The gate side wall 14 may be a monolayer insulating film such as a SiO₂ film or a Si₃N₄ film, or may be a multilayered film composed of an insulating film such as a SiO₂ film or a Si₃N₄ film. The gate side wall 14 may be formed with a material having a dielectric constant lower than SiO₂. The thickness of the gate side wall 14 is normally 20 nm to 150 nm, but may be 20 nm or less when miniaturization of the element is required.

(Silicide Layer 15)

The silicide layer 15 is composed of a material such as titanium silicide, cobalt silicide, nickel suicide or platinum silicide, but silicide other than these types of silicide may be used. The silicide layer 15 is formed by, for example, depositing a metal such as titanium, cobalt, nickel or platinum on source/drain regions by a deposition technique such as a sputtering method, and causing a silicide formation reaction to occur between the metal and the silicon layer by carrying out a heat treatment.

(Contact 17 and Interconnect 18)

The contact 17 and the interconnect 18 are formed by a normal contact formation step and a normal interconnect step. The contact 17 and the interconnect 18 are normally formed with a metal such as aluminum or copper, and other conductive materials such as TiN are combined as appropriate.

(Semiconductor Layer 38)

It is preferable that the semiconductor layer 38 is monocrystalline in terms of improvement of an on-current and inhibition of an off-current, but the on-current in a required specification is low or the off-current in a required specification is high, a material such as amorphous or polycrystalline other than monocrystalline materials may be used.

The semiconductor layer 38 may be replaced with a semiconductor layer other than silicon. The semiconductor layer 38 may be replaced with a combination of two or more types of semiconductors.

(Introduction of Impurity)

For the type and concentration of the impurity introduced by ion implantation, a donor impurity or acceptor impurity having in a concentration of 5×10¹⁸ cm⁻³ to 1×10²¹ cm⁻³ is typically introduced in high-concentration regions such as source/drain regions and the gate electrode. More typically, a donor impurity or acceptor impurity having in a concentration of 3×10¹⁹ cm⁻³ to 1×10²⁰ cm⁻³ is introduced. Introduction of the impurity is carried out by, for example, ion implantation or gas phase diffusion. The typical douse amount during ion implantation is 1×10¹⁴ cm⁻¹² to 3×10¹⁵ cm⁻², more typically 3×10¹⁴ cm⁻¹² to 1×10¹⁵ cm⁻².

The net impurity concentration (the absolute value of a difference between the concentration of the first conductivity type impurity and the concentration of the second conductivity type impurity) in a low-concentration region such as the channel forming region excepting the channel impurity concentration adjusting region is typically 5×10¹⁷ cm⁻³ to 1×10¹⁹ cm⁻³, more typically 1×10¹⁸ cm⁻³ to 5×10¹⁸ cm⁻³.

However, even in a transistor having these typical impurity concentrations in main areas of the regions, these typical values may be exceeded locally depending on the condition of ion implantation.

For the first conductivity type impurity introduced into the source/drain regions and the first conductivity type impurity introduced into the gate electrode, a donor impurity having an n-type conductivity may be selected for the n-channel transistor and an acceptor impurity having a p-type conductivity may be selected for the p-channel transistor.

For the second conductivity type impurity introduced into the hollow region, an acceptor impurity having a p-type conductivity may be selected for the n-channel transistor and a donor impurity having an n-type conductivity may be selected for the p-channel transistor.

Typical examples of the n-type impurity include arsenic, phosphorous and antimony. Typical examples of the p-type impurity include boron and indium.

Activation of an ion-implanted impurity is performed by a heating treatment such as annealing by a normal electric oven or lamp annealing after ion implantation. A heat treatment for activating ions implanted into the channel region may be carried out just after ion implantation, or may be combined with a heat treatment for activating an impurity introduced into the source/drain regions.

For introduction of the impurity into the source/drain regions, a method in which the impurity is introduced into a region which is not covered with the gate electrode after formation of the gate electrode may be used, or a method in which the impurity is introduced into a region on which the source/drain regions are to be formed before formation of the gate electrode may be used.

(Arrangement of Source/Drain Regions 6, Contact 17 and Interconnect 18)

The arrangement of portions forming a semiconductor device, such as the source/drain regions 6, the interlayer insulating film 16, the contact 17 and the interconnect 18 in each embodiment, is similar to that in a normal FinFET. For example, an arrangement same as the arrangement shown in FIGS. 4(a) and 4(b) and FIG. 5 for explaining the first embodiment is employed.

(Channel Type)

Each embodiment has been described mainly for the n-channel transistor, but the present invention is applied to both the n-channel transistor and the p-channel transistor. In the p-channel transistor, the same discussions hold if the polarity is reversed (for example, an increase in electric potential in the n-channel transistor is replaced by a decrease in electric potential in the p-channel transistor, a decrease in threshold voltage in the n-channel transistor is replaced by an increase in threshold voltage in the p-channel transistor, the description of “high voltage and electric potential” is replaced by the description of “low voltage and electric potential”, and the sign of an applied voltage such as a drain voltage is reversed).

1. A field effect transistor comprising:
a semiconductor layer projecting upward from the plane of a base;
a gate electrode provided on opposite side surfaces of the semiconductor layer;
a gate insulating film interposed between the gate electrode and the side surface of said semiconductor layer; and
source/drain regions where a first conductivity type impurity is introduced in said semiconductor layer,
wherein said semiconductor layer has a channel forming region in a portion sandwiched between said source/drain regions, and has on the upper part of the semiconductor layer in the channel forming region a channel impurity concentration adjusting region of which the concentration of a second conductivity type impurity is higher than that of the lower part of the semiconductor layer, and in the channel impurity concentration adjusting region, a channel is formed on a side surface portion of the semiconductor layer in the channel impurity concentration adjusting region, which faces said gate insulating film, in a state of operation in which a signal voltage is applied to said gate electrode.

2. A field effect transistor comprising:
a semiconductor layer projecting upward from the plane of a base;
a gate electrode extending from the upper part of the semiconductor layer to facing opposite side surfaces so as to straddle the semiconductor layer;
a gate insulating film interposed between the gate electrode and said semiconductor layer; and
source/drain regions where a first conductivity type impurity is introduced in said semiconductor layer,
wherein said semiconductor layer has a channel forming region in a portion sandwiched between said source/drain regions, and has on the upper part of the semiconductor layer in the channel forming region a channel impurity concentration adjusting region of which the concentration of a second conductivity type impurity is higher than that of the lower part of the semiconductor layer, and
in the channel impurity concentration adjusting region, a channel is formed on upper surface and side surface portions of the semiconductor layer in the channel impurity concentration adjusting region, which face said gate insulating film, in a state of operation in which a signal voltage is applied to said gate electrode.

3. The field effect transistor according to claim 1, wherein when having in the upper part of the semiconductor layer a concentration of the second conductivity type impurity which is same as that in the lower part of the semiconductor layer, said channel impurity concentration adjusting region has an impurity concentration with which
an electric potential increasing in a corner portion of the upper part of the semiconductor layer can be reduced for an n-channel transistor; and
a reduction in electric potential in the corner portion of the upper part of the semiconductor layer can be downscaled for a p-channel transistor.

4. The field effect transistor according to claim 1, wherein said channel impurity concentration adjusting region has an impurity concentration with which
an electric potential increasing in the corner portion of the upper part of the semiconductor layer can be reduced by 60 mV or more for the n-channel transistor; and
a reduction in electric potential in the corner portion of the upper part of the semiconductor layer can be downscaled by 60 mV or more for the p-channel transistor.

5. The field effect transistor according to claim 1, wherein the average value of the net concentration of the second conductivity type impurity in said channel impurity concentration adjusting region is in a range from 1.3 times or more to 4 times or less as large as the average value of the net concentration of the second conductivity type impurity in other regions below the channel impurity concentration adjusting region.

6. The field effect transistor according to claim 1, wherein the average value of the net concentration of the second conductivity type impurity in said channel impurity concentration adjusting region is in a range from 1.5 times or more to 3 times or less as large as the average value of the net concentration of the second conductivity type impurity in other regions below the channel impurity concentration adjusting region.

7. The field effect transistor according to claim 1, wherein in said channel impurity concentration adjusting region, a depth Htop extending downward from the upper end of said semiconductor layer is 0.7 times or less as large as a width Wfin of the semiconductor layer parallel to the plane of the base and vertical to the longitudinal direction of the channel.

8. The field effect transistor according to claim 1, wherein in said channel impurity concentration adjusting region, a depth Htop extending downward from the upper end of said semiconductor layer is 7/40 times or more as large as a width Wfin of the semiconductor layer parallel to the plane of the base and vertical to the longitudinal direction of the channel.

9. The field effect transistor according to claim 1, wherein in said channel impurity concentration adjusting region, the depth Htop extending downward from the upper end of said semiconductor layer is in a range from 5 to 24.5 nm.

10. The field effect transistor according to claim 1, wherein the average value of the net concentration of the second conductivity type impurity in said channel forming region excepting said channel impurity concentration adjusting region is 1×10¹⁸ cm⁻³ or more.

11. The field effect transistor according to claim 1, wherein said channel impurity concentration adjusting region is provided along an entire in-plane direction parallel to the plane of the base in the upper part of the semiconductor layer in said channel forming region.

12. The field effect transistor according to claim 1, wherein the field effect transistor has as said channel impurity concentration adjusting region the channel impurity concentration adjusting region so as to include at least a part of the corner portion of the semiconductor layer, in the upper part of the semiconductor layer in said channel forming region, and further has a portion which does not have the channel impurity concentration adjusting region in a section parallel to the plane of the base, which includes the channel impurity concentration adjusting region.

13. The field effect transistor according to claim 12, wherein the field effect transistor has a first channel impurity concentration adjusting region provided seamlessly along the longitudinal direction of the channel so as to include one corner portion and establish a link between a pair of source/drain regions and a second channel impurity concentration adjusting region provided seamlessly along the longitudinal direction of the channel so as to include the other corner portion and establish a link between a pair of source/drain regions, in the upper part of the semiconductor layer in said channel forming region, and further has between the first channel impurity concentration adjusting region and the second channel impurity concentration adjusting region a portion which does not have these channel impurity concentration adjusting regions over an area between a pair of source/drain regions so that these channel impurity concentration adjusting regions are mutually separated.

14. The field effect transistor according to claim 12, wherein the field effect transistor has a first channel impurity concentration adjusting region provided seamlessly from one corner portion to the other corner portion so as to contact one source/drain region and a second channel impurity concentration adjusting region provided seamlessly from one corner to the other corner so as to contact the other source/drain region, in the upper part of the semiconductor layer in said channel forming region, and further has between the first channel impurity concentration adjusting region and the second channel impurity concentration adjusting region a portion which does not have these channel impurity concentration adjusting regions over an area between a pair of corner portions so that these channel impurity concentration adjusting regions are mutually separated.

15. The field effect transistor according to claim 12, wherein the field effect transistor has a channel impurity concentration adjusting region provided seamlessly from one corner portion to the other corner portion so as to contact one source/drain region, in the upper part of the semiconductor layer in said channel forming region, and has no channel impurity concentration adjusting region between said channel impurity concentration adjusting region and the other source/drain region.

16. The field effect transistor according to claim 12, wherein the field effect transistor has a first channel impurity concentration adjusting region contacting one source/drain region and including a part of a first corner portion, a second impurity concentration adjusting region contacting the other source/drain region and including a part of the first corner portion, a third channel impurity concentration adjusting region contacting one source/drain region and including a part of a second corner portion facing the first corner portion, and a fourth channel impurity concentration adjusting region contacting the other source/drain region and including a part of the second corner portion facing the first corner portion, in the upper part of the semiconductor layer in said channel forming region, and further has a portion which does not have these channel impurity concentration adjusting regions over an area between a pair of source/drain regions and an area between a pair of first/second corner portions so that these channel impurity concentration adjusting regions are mutually separated.

17. The field effect transistor according to claim 12, wherein the field effect transistor has a first channel impurity concentration adjusting region contacting a first source/drain region and including a part of a first corner portion and a second channel impurity concentration adjusting region contacting said first source/drain region and including a part of a second corner portion facing the first corner portion, in the upper part of the semiconductor layer in said channel forming region,
has a portion having no channel impurity concentration adjusting region between said first channel impurity concentration adjusting region and said second channel impurity concentration adjusting region, and
has no channel impurity concentration adjusting region in the vicinity of a second source/drain region facing the first source/drain region.

18. A field effect transistor having an impurity concentration comprising:
a semiconductor layer projecting upward from the plane of a base;
a gate electrode provided on opposite side surfaces of the semiconductor layer;
a gate insulating film interposed between the gate electrode and the side surface of said semiconductor layer; and
source/drain regions where a first conductivity type impurity is introduced in said semiconductor layer,
wherein said semiconductor layer has a channel forming region in a portion sandwiched between said source/drain regions, has in the upper part of the semiconductor layer in the portion sandwiched between the source/drain regions a channel impurity concentration adjusting region of which the concentration of a second conductivity type impurity is higher than that in the lower part of the semiconductor layer, so as to include at least a part of a corner portion of the semiconductor layer, and further has a portion which does not have the channel impurity concentration adjusting region in a section parallel to the plane of the base, which includes the channel impurity concentration adjusting region.

19. A field effect transistor having an impurity concentration comprising:
a semiconductor layer projecting upward from the plane of a base;
a gate electrode extending from the upper part of the semiconductor layer to facing opposite side surfaces so as to straddle the semiconductor layer;
a gate insulating film interposed between the gate electrode and said semiconductor layer; and
source/drain regions where a first conductivity type impurity in said semiconductor layer,
wherein said semiconductor layer has a channel forming region in a portion sandwiched between said source/drain regions, has in the upper part of the semiconductor layer in the portion sandwiched between the source/drain regions a channel impurity concentration adjusting region of which the concentration of a second conductivity type impurity is higher than that in the lower part of the semiconductor layer, so as to include at least a part of a corner portion of the semiconductor layer, and further has a portion which does not have the channel impurity concentration adjusting region in a section parallel to the plane of the base, which includes the channel impurity concentration adjusting region.

20. The field effect transistor according to claim 18, wherein the field effect transistor has a first channel impurity concentration adjusting region provided seamlessly along the longitudinal direction of a channel so as to include one corner portion and establish a link between a pair of source/drain regions and a second channel impurity concentration adjusting region provided seamlessly along the longitudinal direction of the channel so as to include the other corner portion and establish a link between a pair of source/drain regions, in the upper part of the semiconductor layer in the portion sandwiched between said source/drain regions, and further has between the first channel impurity concentration adjusting region and the second channel impurity concentration adjusting region a portion which does not have these channel impurity concentration adjusting regions over an area between a pair of source/drain regions so that these channel impurity concentration adjusting regions are mutually separated.

21. The field effect transistor according to claim 18, wherein the field effect transistor has a first channel impurity concentration adjusting region provided seamlessly from one corner portion to the other corner portion so as to contact one source/drain region and second channel impurity concentration adjusting region provided seamlessly from one corner portion to the other corner portion so as to contact the other source/drain region, in the upper part of the semiconductor layer in the portion sandwiched between said source/drain regions, and further has between the first channel impurity concentration adjusting region and the second channel impurity concentration adjusting region a portion which does not have these channel impurity concentration adjusting regions over an area between a pair of corner portions so that these channel impurity concentration adjusting regions are mutually separated.

22. The field effect transistor according to claim 18, wherein the field effect transistor has a channel impurity concentration adjusting region provided seamlessly from one corner portion to the other corner portion so as to contact one source/drain region in the upper part of the semiconductor layer in the portion sandwiched between said source/drain regions, and
has no channel impurity concentration adjusting region between said channel impurity concentration adjusting region and the other source/drain region.

23. The field effect transistor according to claim 18, wherein the field effect transistor has a first channel impurity concentration adjusting region contacting one source/drain region and including a part of a first corner portion, a second impurity concentration adjusting region contacting the other source/drain region and including a part of the first corner portion, a third channel impurity concentration adjusting region contacting one source/drain region and including a part of a second corner portion facing the first corner portion, and a fourth channel impurity concentration adjusting region contacting the other source/drain region and including a part of the second corner portion facing the first corner portion, in the upper part of the semiconductor layer in the portion sandwiched between said source/drain regions, and further has a portion which does not have these channel impurity concentration adjusting regions over an area between a pair of source/drain regions and an area between a pair of first/second corner portions so that these channel impurity concentration adjusting regions are mutually separated.

24. The field effect transistor according to claim 18, wherein the field effect transistor has a first channel impurity concentration adjusting region contacting a first source/drain region and including a part of a first corner portion and a second channel impurity concentration adjusting region contacting said first source/drain region and including a part of a second corner portion facing the first corner portion, in the upper part of the semiconductor layer in the portion sandwiched between said source/drain regions,
has a portion having no channel impurity concentration adjusting region between said first channel impurity concentration adjusting region and said second channel impurity concentration adjusting region, and
has no channel impurity concentration adjusting region in the vicinity of a second source/drain region facing the first source/drain region.

25. The field effect transistor according to claim 18, wherein in said channel impurity concentration adjusting region, the average value of the net concentration of the second conductivity type impurity in the channel impurity concentration adjusting region is in a range from 1.3 times or more to 4 times or less as large as the average value of the net concentration of the second conductivity type impurity in other regions below the channel impurity concentration adjusting region, in a section vertical to the plane of the base, which includes the channel impurity concentration adjusting region.

26. The field effect transistor according to claim 18, wherein in said channel impurity concentration adjusting region, the average value of the net concentration of the second conductivity type impurity in the channel impurity concentration adjusting region is in a range from 1.5 times or more to 3 times or less as large as the average value of the net concentration of the second conductivity type impurity in other regions below the channel impurity concentration adjusting region, in a section vertical to the plane of the base, which includes the channel impurity concentration adjusting region.

27. The field effect transistor according to claim 18, wherein said channel impurity concentration adjusting region has a concentration distribution in which the average value of the net concentration of the second conductivity type impurity in the channel impurity concentration adjusting region is in a range from 1.3 times or more to 4 times or less as large as the average value of the net concentration of the second conductivity type impurity in other regions below the channel impurity concentration adjusting region, on a line vertical to the plane of the base in the semiconductor layer in the portion sandwiched between said source/drain regions.

28. The field effect transistor according to claim 18, wherein said channel impurity concentration adjusting region has a concentration distribution in which the average value of the net concentration of the second conductivity type impurity in the channel impurity concentration adjusting region is in a range from 1.5 times or more to 3 times or less as large as the average value of the net concentration of the second conductivity type impurity in other regions below the channel impurity concentration adjusting region, on a line vertical to the plane of the base in the semiconductor layer in the portion sandwiched between said source/drain regions.

29. The field effect transistor according to claim 18, wherein in said channel impurity concentration adjusting region, a depth Htop extending downward from the upper end of said semiconductor layer is 0.7 times or less as large as a width Wfin of the semiconductor layer parallel to the plane of the base and vertical to the longitudinal direction of the channel.

30. The field effect transistor according to claim 18, wherein in said channel impurity concentration adjusting region, a depth Htop extending downward from the upper end of said semiconductor layer is 7/40 times or more as large as a width Wfin of the semiconductor layer parallel to the plane of the base and vertical to the longitudinal direction of the channel.

31. The field effect transistor according to claim 18, wherein in said channel impurity concentration adjusting region, the depth Htop extending downward from the upper end of said semiconductor layer is in a range from 5 to 24.5 nm.

32. The field effect transistor according to claim 18, wherein the average value of the net concentration of the second conductivity type impurity in said channel forming region excepting said channel impurity concentration adjusting region is 1×10¹⁸ cm⁻³ or more.

33. The field effect transistor according to claim 1, wherein said semiconductor layer has an upper channel impurity concentration adjusting region which is said channel impurity concentration adjusting region provided in the upper part of the semiconductor layer, a middle channel forming region which is provided below the upper channel impurity concentration adjusting region and of which the concentration of the second conductivity type impurity is lower than that in the upper channel impurity concentration adjusting region, and a lower channel impurity concentration adjusting region which is provided in the lower part of the semiconductor layer below the middle channel forming region and of which the concentration of the second conductivity type impurity is higher than that in the middle channel forming region.

34. The field effect transistor according to claim 33, wherein said lower channel impurity concentration adjusting region has a channel formed in a side surface portion of the semiconductor layer in the lower channel impurity concentration adjusting region, which faces said gate insulating film, in a state of operation in which a signal voltage is applied to said gate electrode.

35. The field effect transistor according to claim 33, wherein said lower channel impurity concentration adjusting region has an impurity concentration with which an electric potential increasing in the corner portion of the lower part of the semiconductor layer can be reduced when said lower channel impurity concentration adjusting region has a concentration of the second conductivity type impurity which is same as that in said middle channel forming region.

36. The field effect transistor according to claim 33, wherein the average value of the net concentration of the second conductivity type impurity in said lower channel impurity concentration adjusting region is 1.3 times or more and 4 times or less as large as the average value of the net concentration of the second conductivity type impurity in said middle channel forming region.

37. The field effect transistor according to claim 36, wherein the average value of the net concentration of the second conductivity type impurity in said upper channel impurity concentration adjusting region is 1.3 times or more and 4 times or less as large as the average value of the net concentration of the second conductivity type impurity in said middle channel forming region.

38. The field effect transistor according to claim 33, wherein the average value of the net concentration of the second conductivity type impurity in said lower channel impurity concentration adjusting region is 1.5 times or more and 3 times or less as large as the average value of the net concentration of the second conductivity type impurity in said middle channel region.

39. The field effect transistor according to claim 38, wherein the average value of the net concentration of the second conductivity type impurity in said upper channel impurity concentration adjusting region is 1.5 times or more and 3 times or less as large as the average value of the net concentration of the second conductivity type impurity in said middle channel forming region.

40. The field effect transistor according to claim 33, wherein in said lower channel impurity concentration adjusting region, a height Htop2 extending upward from the lower end of said semiconductor layer is 0.7 times or less as large as a width Wfin of said semiconductor layer parallel to the plane of the base and vertical to the longitudinal direction of the channel.

41. The field effect transistor according to claim 40, wherein in said upper channel impurity concentration adjusting region, the height Htop extending downward from the upper end of said semiconductor layer is 0.7 times or less as large as the width Wfin of said semiconductor layer parallel to the plane of the base and vertical to the longitudinal direction of the channel.

42. The field effect transistor according to claim 33, wherein in said lower channel impurity concentration adjusting region, the height Htop2 extending upward from the lower end of said semiconductor layer is 7/40 times or more as large as the width Wfin of the semiconductor layer parallel to the plane of the base and vertical to the longitudinal direction of the channel.

43. The field effect transistor according to claim 42, wherein in said upper channel impurity concentration adjusting region, the height Htop extending downward from the upper end of said semiconductor layer is 7/40 times or more as large as a width Wfin of the semiconductor layer parallel to the plane of the base and vertical to the longitudinal direction of the channel.

44. The field effect transistor according to claim 33, wherein in said lower channel impurity concentration adjusting region, the height Htop2 extending upward from the lower end of said semiconductor layer is in a range from 5 to 24.5 nm.

45. The field effect transistor according to claim 44, wherein in said upper channel impurity concentration adjusting region, the height Htop extending downward from the upper end of said semiconductor layer is in a range from 5 to 24.5 nm.

46. The field effect transistor according to claim 33, wherein said lower channel impurity concentration adjusting region is provided along an entire in-plane direction parallel to the plane of the base in the lower part of the semiconductor layer in the portion sandwiched between source/drain regions.

47. The field effect transistor according to claim 33, wherein the field effect transistor has as said lower channel impurity concentration adjusting region the channel impurity concentration adjusting region so as to include at least a part of the corner portion of the semiconductor layer in the lower part of the semiconductor layer in the portion sandwiched between said source/drain regions, and further has a portion which does not have the lower channel impurity concentration adjusting region in a section parallel to the plane of the base, which includes the lower channel impurity concentration adjusting region.

48. The field effect transistor according to claim 33, wherein the average value of the net concentration of the second conductivity type impurity in said channel forming region excepting said upper channel impurity concentration adjusting region and said lower channel impurity concentration adjusting region is 1×10¹⁸ cm⁻³ or more.

49. The field effect transistor according to claim 1, wherein a cap insulating film thicker than said gate insulating film is provided between the upper part of said semiconductor layer and said gate electrode so that no channel is formed on the upper surface of the semiconductor layer.

50. The field effect transistor according to claim 1, wherein the field effect transistor has a support substrate under said projecting semiconductor layer, and the semiconductor layer is connected integrally to the support substrate.

51. The field effect transistor according to claim 1, wherein the field effect transistor has a support substrate under said projecting semiconductor layer, and the semiconductor layer is provided on the support substrate via a buried insulating film.

52. The field effect transistor according to claim 1, wherein in said channel forming region excepting said channel impurity concentration adjusting region, an electric potential on the side surface of the semiconductor layer increases by 120 mV or more for the n-channel transistor and decreases by 120 mV or more for the p-channel transistor with respect to an electric potential at the central portion of the semiconductor layer.

53. A method for producing the field effect transistor of claim 1, comprising the steps of:
patterning a semiconductor layer to form a semiconductor layer projecting from the plane of a base;
forming a gate electrode via an insulating film so as to straddle the projecting semiconductor layer; and
ion-implanting a second conductivity type impurity slantingly to the plane of the base from opposite sides of the gate electrode using the gate electrode as a mask to form a channel impurity concentration adjusting region on the upper part of the semiconductor layer under the gate electrode.

54. The method for producing the field effect transistor according to claim 53, wherein in the step of ion-implanting a second conductivity type impurity slantingly to the plane of the base from opposite sides of the gate electrode using the gate electrode as a mask, said ion implantation is carried out at an angle of 10 degrees or less to a plane vertical to the plane of the base and parallel to the longitudinal direction of a channel.

55. The method for producing the field effect transistor according to claim 53, wherein in the step of ion-implanting a second conductivity type impurity slantingly to the plane of the base from opposite sides of the gate electrode using the gate electrode as a mask, said ion implantation is carried out parallel to a plane vertical to the plane of the base and parallel to the longitudinal direction of a channel.

56. A method for producing the field effect transistor of claim 1, comprising:
a step of patterning a semiconductor layer to form a semiconductor layer projecting from the surface of a base;
a step of forming a gate electrode via an insulating film so as to straddle the projecting semiconductor layer;
a first slanting ion implantation step of ion-implanting a second conductivity type impurity slantingly to the plane of the base from opposite sides of the gate electrode using said gate electrode as a mask; and
a second slanting ion implantation step of ion-implanting the second conductivity type impurity slantingly to the plane of the base from opposite sides of the gate electrode, and at an angle greater than that in said first slanting ion implantation step to a plane vertical to the plane of the base and parallel to the longitudinal direction of a channel, for each of opposite side surfaces of the semiconductor layer, using said gate electrode as a mask.

57. The method for producing the field effect transistor according to claim 56, wherein said first slanting ion implantation step is carried out at an angle of 10 degrees or less to a plane vertical to the plane of the base and parallel to the longitudinal direction of the channel.

58. The method for producing the field effect transistor according to claim 56, wherein said first slanting ion implantation step is carried out parallel to a plane vertical to the plane of the base and parallel to the longitudinal direction of the channel.

59. A method for producing the field effect transistor of claim 1, comprising the steps of:
patterning a semiconductor layer to form a semiconductor layer projecting from the plane of a base;
forming a dummy gate electrode so as to straddle the semiconductor layer;
ion-implanting a second conductivity type impurity slantingly to the plane of the base from opposite sides of the dummy gate electrode using said dummy gate electrode as a mask to form a channel impurity concentration adjusting region on the upper part of the semiconductor layer under the dummy gate electrode;
introducing a first conductivity type impurity into the semiconductor layer using said dummy gate electrode as a mask to form source/drain regions;
forming a thick insulating film so as to bury said dummy electrode; and
removing said dummy gate electrode and burying a conductive material in a formed air gap via a gate insulating film to form a gate electrode.

60. A method for producing the field effect transistor of claim 1, comprising the steps of:
patterning a semiconductor layer to form a semiconductor layer projecting from the plane of a base;
introducing a second conductivity type impurity into the upper part of the projecting semiconductor layer to form said channel impurity concentration adjusting region; and
forming a gate electrode on the side surface of the projecting semiconductor layer via a gate insulating film.

61. A method for producing the field effect transistor of claim 1, comprising the steps of:
introducing a second conductivity type impurity into a semiconductor layer to form on the upper part of the semiconductor layer a channel impurity concentration adjusting region of which the concentration of the second conductivity type impurity is higher than that in the lower part of the semiconductor layer;
patterning said semiconductor layer to form a semiconductor layer projecting from the plane of a base and having said channel impurity concentration adjusting region for the second conductivity type impurity in the upper part; and
forming a gate electrode on the side surface of the projecting semiconductor layer via a gate insulating film.

62. A method for producing the field effect transistor of claim 20, comprising the steps of:
forming a mask pattern on a semiconductor layer;
ion-implanting a second conductivity type impurity slantingly to the plane of a base from opposite sides of the mask pattern using said mask pattern as a mask to introduce the second conductivity type impurity into the part of the semiconductor layer under the mask pattern in the vicinity of peripheral edge of the mask pattern;
patterning the semiconductor layer using said mask pattern as a mask to form a semiconductor layer projecting from the plane of a base, and having in the upper part first and second channel impurity concentration adjusting regions which are respectively composed of a region of said second conductivity type impurity; and
forming a gate electrode on the side surface of the projecting semiconductor layer via a gate insulating film.

63. A method for producing the field effect transistor of claim 21, comprising the steps of:
patterning a semiconductor layer to form a semiconductor layer projecting from the plane of a base;
forming a gate electrode via an insulating film so as to straddle the projecting semiconductor layer; and
ion-implanting a second conductivity type impurity slantingly to the plane of the base from opposite sides of the gate electrode using said gate electrode as a mask to form first and second channel impurity concentration adjusting regions mutually separated along a pair of sides of the gate electrode on the upper part of the semiconductor layer under the gate electrode.

64. The method for producing the field effect transistor according to claim 63, wherein in the step of ion-implanting a second conductivity type impurity slantingly to the plane of the base from opposite sides of the gate electrode using the gate electrode as a mask, said ion implantation is carried out at an angle of 10 degrees or less to a plane vertical to the plane of the base and parallel to the longitudinal direction of a channel.

65. The method for producing the field effect transistor according to claim 63, wherein in the step of ion-implanting a second conductivity type impurity slantingly to the plane of the base from opposite sides of the gate electrode using the gate electrode as a mask, said ion implantation is carried out parallel to a plane vertical to the plane of the base and parallel to the longitudinal direction of a channel.

66. A method for producing the field effect transistor of claim 23, comprising:
a step of patterning a semiconductor layer to form a semiconductor layer projecting from the plane of a base;
a step of forming a gate electrode via an insulating film so as to straddle the projecting semiconductor layer;
a first slanting ion implantation step of ion-implanting a second conductivity type impurity slantingly to the plane of the base from opposite sides of the gate electrode using said gate electrode as a mask; and
a second slanting ion implantation step of ion-implanting the second conductivity type impurity slantingly to the plane of the base from opposite sides of the gate electrode, and at an angle greater than that in said first slanting ion implantation step to a plane vertical to the plane of the base and parallel to the longitudinal direction of a channel, for each of opposite side surfaces of the semiconductor layer, using said gate electrode as a mask.

67. The method for producing the field effect transistor according to claim 66, wherein said first slanting ion implantation step is carried out at an angle of 10 degrees or less to a plane vertical to the plane of the base and parallel to the longitudinal direction of the channel.

68. The method for producing the field effect transistor according to claim 66, wherein said first slanting ion implantation step is carried out parallel to a plane vertical to the plane of the base and parallel to the longitudinal direction of the channel.

69. A method for producing the field effect transistor of claim 33, comprising the steps of:
introducing a second conductivity type impurity into a semiconductor layer to form a second conductivity type impurity layer;
epitaxially growing a semiconductor layer having a second conductivity type impurity concentration lower than that of said second conductivity type impurity layer on said semiconductor layer; and
patterning the epitaxially grown semiconductor layer and said second conductivity type impurity layer to form a semiconductor layer projecting from the plane of a base, and having a lower channel impurity concentration adjusting region composed of the second conductivity type impurity layer.

70. The field effect transistor according to claim 18, wherein said semiconductor layer has an upper channel impurity concentration adjusting region which is said channel impurity concentration adjusting region provided in the upper part of the semiconductor layer, a middle channel forming region which is provided below the upper channel impurity concentration adjusting region and of which the concentration of the second conductivity type impurity is lower than that in the upper channel impurity concentration adjusting region, and a lower channel impurity concentration adjusting region which is provided in the lower part of the semiconductor layer below the middle channel forming region and of which the concentration of the second conductivity type impurity is higher than that in the middle channel forming region.

71. The field effect transistor according to claim 70, wherein said lower channel impurity concentration adjusting region has a channel formed in a side surface portion of the semiconductor layer in the lower channel impurity concentration adjusting region, which faces said gate insulating film, in a state of operation in which a signal voltage is applied to said gate electrode.

72. The field effect transistor according to claim 70, wherein said lower channel impurity concentration adjusting region has an impurity concentration with which an electric potential increasing in the corner portion of the lower part of the semiconductor layer can be reduced when said lower channel impurity concentration adjusting region has a concentration of the second conductivity type impurity which is same as that in said middle channel forming region.

73. The field effect transistor according to claim 70, wherein the average value of the net concentration of the second conductivity type impurity in said lower channel impurity concentration adjusting region is 1.3 times or more and 4 times or less as large as the average value of the net concentration of the second conductivity type impurity in said middle channel forming region.

74. The field effect transistor according to claim 73, wherein the average value of the net concentration of the second conductivity type impurity in said upper channel impurity concentration adjusting region is 1.3 times or more and 4 times or less as large as the average value of the net concentration of the second conductivity type impurity in said middle channel forming region.

75. The field effect transistor according to claim 70, wherein the average value of the net concentration of the second conductivity type impurity in said lower channel impurity concentration adjusting region is 1.5 times or more and 3 times or less as large as the average value of the net concentration of the second conductivity type impurity in said middle channel region.

76. The field effect transistor according to claim 75, wherein the average value of the net concentration of the second conductivity type impurity in said upper channel impurity concentration adjusting region is 1.5 times or more and 3 times or less as large as the average value of the net concentration of the second conductivity type impurity in said middle channel forming region.

77. The field effect transistor according to 70, wherein in said lower channel impurity concentration adjusting region, a height Htop2 extending upward from the lower end of said semiconductor layer is 0.7 times or less as large as a width Wfin of said semiconductor layer parallel to the plane of the base and vertical to the longitudinal direction of the channel.

78. The field effect transistor according to claim 77, wherein in said upper channel impurity concentration adjusting region, the height Htop extending downward from the upper end of said semiconductor layer is 0.7 times or less as large as the width Wfin of said semiconductor layer parallel to the plane of the base and vertical to the longitudinal direction of the channel.

79. The field effect transistor according to claim 70, wherein in said lower channel impurity concentration adjusting region, the height Htop2 extending upward from the lower end of said semiconductor layer is 7/40 times or more as large as the width Wfin of the semiconductor layer parallel to the plane of the base and vertical to the longitudinal direction of the channel.

80. The field effect transistor according to claim 79, wherein in said upper channel impurity concentration adjusting region, the height Htop extending downward from the upper end of said semiconductor layer is 7/40 times or more as large as a width Wfin of the semiconductor layer parallel to the plane of the base and vertical to the longitudinal direction of the channel.

81. The field effect transistor according to claim 70, wherein in said lower channel impurity concentration adjusting region, the height Htop2 extending upward from the lower end of said semiconductor layer is in a range from 5 to 24.5 nm.

82. The field effect transistor according to claim 81, wherein in said upper channel impurity concentration adjusting region, the height Htop extending downward from the upper end of said semiconductor layer is in a range from 5 to 24.5 nm.

83. The field effect transistor according to claim 70, wherein said lower channel impurity concentration adjusting region is provided along an entire in-plane direction parallel to the plane of the base in the lower part of the semiconductor layer in the portion sandwiched between source/drain regions.

84. The field effect transistor according to claim 70, wherein the field effect transistor has as said lower channel impurity concentration adjusting region the channel impurity concentration adjusting region so as to include at least a part of the corner portion of the semiconductor layer in the lower part of the semiconductor layer in the portion sandwiched between said source/drain regions, and further has a portion which does not have the lower channel impurity concentration adjusting region in a section parallel to the plane of the base, which includes the lower channel impurity concentration adjusting region.

85. The field effect transistor according to claim 70, wherein the average value of the net concentration of the second conductivity type impurity in said channel forming region excepting said upper channel impurity concentration adjusting region and said lower channel impurity concentration adjusting region is 1×10¹⁸ cm⁻³ or more.

86. The field effect transistor according to claim 18, wherein a cap insulating film thicker than said gate insulating film is provided between the upper part of said semiconductor layer and said gate electrode so that no channel is formed on the upper surface of the semiconductor layer.

87. The field effect transistor according to claim 18, wherein the field effect transistor has a support substrate under said projecting semiconductor layer, and the semiconductor layer is connected integrally to the support substrate.

88. The field effect transistor according to claim 18, wherein the field effect transistor has a support substrate under said projecting semiconductor layer, and the semiconductor layer is provided on the support substrate via a buried insulating film.

89. The field effect transistor according to claim 18, wherein in said channel forming region excepting said channel impurity concentration adjusting region, an electric potential on the side surface of the semiconductor layer increases by 120 mV or more for the n-channel transistor and decreases by 120 mV or more for the p-channel transistor with respect to an electric potential at the central portion of the semiconductor layer.
